(19) United States
(12) Patent Application Publication
(10) Pub. No.: US 2026/0165213 A1
(43) Pub. Date: Jun. 11, 2026

(54) ONE OR MORE STACKED MEMORY DEVICES AND A SEMICONDUCTOR SYSTEM

(71) Applicant: SK hynix Inc., Icheon-si Gyeonggi-do (KR)

(72) Inventors: Joon Yong CHOI, Icheon-si Gyeonggi-do (KR); Choung Ki SONG, Icheon-si Gyeonggi-do (KR); Jong Moo LEE, Icheon-si Gyeonggi-do (KR)

(73) Assignee: SK hynix Inc., Icheon-si Gyeonggi-do (KR)

(21) Appl. No.: 19/384,749

(22) Filed: Nov. 10, 2025

Related U.S. Application Data
(63) Continuation-in-part of application No. 19/383,452, filed on Nov. 7, 2025.
Application No. 19/383,452 is a continuation-in-part of application No. 19/382,036, filed on Nov. 6, 2025.
Application No. 19/382,036 is a continuation-in-part of application No. 19/317,348, filed on Sep. 3, 2025.
(63) Continuation-in-part of application No. 19/381,928, filed on Nov. 6, 2025.
(60) Provisional application No. 63/720,380, filed on Nov. 14, 2024.
(60) Provisional application No. 63/728,952, filed on Dec. 6, 2024.
(60) Provisional application No. 63/826,717, filed on Jun. 19, 2025.
(60) Provisional application No. 63/826,691, filed on Jun. 19, 2025.
(60) Provisional application No. 63/828,634, filed on Jun. 23, 2025.

(51) Int. Cl. H10W 90/15; H10B 80/00; H10D 80/30; H10W 70/60; H10W 90/00; H10W 90/20; H10W 90/26

(52) U.S. Cl. CPC H10W 90/155; H10B 80/00; H10D 80/30; H10W 70/611; H10W 90/26; H10W 90/275; H10W 90/722; H10W 90/724; H10W 90/7295

(57) ABSTRACT

A semiconductor system includes a first HBM device including first to third areas are formed and comprising a first physical area disposed in the first area and a second physical area disposed in the third area, a second HBM device including fourth to sixth areas are formed and comprising a third physical area disposed in the fourth area and a fourth physical area disposed in the sixth area and a process circuit electrically connected to the first physical area, wherein the second physical area of the first HBM device and the third physical area of the second HBM device are electrically connected, the fourth physical area is deactivated, a first predetermined area is formed vertically to the first area, a third predetermined area is formed vertically to the third area, and a fourth predetermined area is formed vertically to the fourth area.

### CROSS-REFERENCE TO RELATED APPLICATIONS

The present application is a continuation-in-part application of U.S. patent application Ser. No. 19/383,452 filed on Nov. 7, 2025, which is a continuation-in-part application of U.S. patent application Ser. No. 19/382,036 filed on Nov. 6, 2025, which claims the benefit of priority under 35 U.S.C. § 119(e) to U.S. Patent Provisional Application 63/826,717 filed on Jun. 19, 2025, and U.S. Patent Provisional Application 63/728,952 filed on Dec. 6, 2024, and which application is also a continuation-in-part application of U.S. patent application Ser. No. 19/317,348 filed on Sep. 3, 2025, which claims the benefit of priority under 35 U.S.C. § 119(e) to U.S. Patent Provisional Application 63/828,634 filed on Jun. 23, 2025, and U.S. Patent Provisional Application 63/720,380 filed on Nov. 14, 2024, and the present application is a continuation-in-part application of U.S. patent application Ser. No. 19/381,928 filed on Nov. 6, 2025, which claims the benefit of priority under 35 U.S.C. § 119(e) to U.S. Patent Provisional Application 63/826,691 filed on Jun. 19, 2025, the entire contents of all of the above applications are incorporated herein by reference in their entirety.

### BACKGROUND

### 1. Technical Field

The present disclosure generally relates to a semiconductor system, and more particularly, to one or more stacked memory devices and a semiconductor system.

### 2. Related Art

Recently, stacked memory systems such as high bandwidth memory (HBM) devices are used in a wide range of applications due to their high bandwidths and energy efficiency. Unlike conventional memory systems that use parallel data buses, the stacked memory system includes a stacked memory device including a base chip and a plurality of memory chips interconnected by through silicon vias (TSVs). The stacked memory device includes a physical interface, such as a physical layer to communicate with a processor. The physical layer is designed for high-speed data transmission and efficient communication.

### SUMMARY

In an embodiment, a semiconductor system includes a first HBM device whereby first to third areas are formed and includes a first physical area disposed in the first area and a second physical area disposed in the third area. The semiconductor system includes a second HBM device whereby fourth to sixth areas are formed and includes a third physical area disposed in the fourth area and a fourth physical area disposed in the sixth area and a process circuit electrically connected to the first physical area. The second physical area of the first HBM device and the third physical area of the second HBM device are electrically connected, and the fourth physical area is deactivated. A first predetermined area is formed vertically to the first area, a third predetermined area is formed vertically to the third area, and a fourth predetermined area is formed vertically to the fourth area.

In an embodiment, a semiconductor system includes a first HBM device whereby first to third areas are formed and includes a first physical area including a first group of physical layers and a second group of physical layers. The semiconductor system includes a second physical area including a third group of physical layers and a fourth group of physical layers. The semiconductor system includes a second HBM device whereby fourth to sixth areas are formed and includes a third physical area including a fifth group of physical layers and a sixth group of physical layers. The semiconductor system includes a fourth physical area comprising a seventh group of physical layers and an eighth group of physical layers. The semiconductor device includes a process circuit electrically connected to the first physical area. The first to eighth groups of physical layers are selectively activated, a first predetermined area is formed vertically to the first area, and a third predetermined area is formed vertically to the third area. A fourth predetermined area is formed vertically to the fourth area, and a sixth predetermined area is formed vertically to the sixth area.

### BRIEF DESCRIPTION OF THE DRAWINGS

FIG. 1 illustrates a stacked memory device according to an embodiment of the present disclosure.

FIG. 2 illustrates an example of the arrangement of areas included in a base die.

FIG. 3 illustrates a stacked memory device according to an embodiment of the present disclosure.

FIG. 4 illustrates a stacked memory device according to an embodiment of the present disclosure.

FIGS. 5, 6, 7, and 8 illustrate examples of the arrangement of areas included in base dies.

FIG. 9 illustrates a stacked memory system according to an embodiment of the present disclosure.

FIG. 10 illustrates a semiconductor system according to an embodiment of the present disclosure.

FIG. 11 illustrates a control device according to an embodiment of the present disclosure.

FIG. 12 illustrates first and second memory devices according to an embodiment of the present disclosure.

FIG. 13 illustrates the control device according to an embodiment of the present disclosure.

FIG. 14 illustrates the first and second memory devices according to an embodiment of the present disclosure.

FIG. 15 illustrates the control device according to an embodiment of the present disclosure.

FIG. 16 illustrates the first and second memory devices according to an embodiment of the present disclosure.

FIG. 17 illustrates a semiconductor system according to an embodiment of the present disclosure.

FIGS. 18 and 19 are block diagrams illustrating constructions of semiconductor systems according to an embodiment of the present disclosure.

FIG. 20 is a block diagram illustrating a construction of an HMB device according to an embodiment of the present disclosure.

FIG. 21 is a block diagram illustrating a construction of a control device according to an embodiment of the present disclosure.

FIG. 22 is a block diagram illustrating a construction of a control device according to an embodiment of the present disclosure.

FIG. 23 is a block diagram illustrating a construction of a memory device according to an embodiment of the present disclosure.

FIG. 24 is a block diagram illustrating a construction of a control device according to an embodiment of the present disclosure.

FIG. 25 is a block diagram illustrating a construction of a control device according to an embodiment of the present disclosure.

FIG. 26 is a block diagram illustrating a construction of a memory device according to an embodiment of the present disclosure.

FIG. 27 is a block diagram illustrating a construction of a control device according to an embodiment of the present disclosure.

FIG. 28 is a block diagram illustrating a construction of a control device according to an embodiment of the present disclosure.

FIG. 29 is a block diagram illustrating a construction of a memory device according to an embodiment of the present disclosure.

FIG. 30 is a block diagram illustrating a construction of a semiconductor system according to an embodiment of the present disclosure.

FIG. 31 is a block diagram illustrating a construction of first and second HBM devices according to an embodiment of the present disclosure.

FIG. 32 is a block diagram illustrating a construction of first and second memory devices according to an embodiment of the present disclosure.

FIG. 33 is a diagram for describing operations of the first and second HBM devices according to an embodiment of the present disclosure.

FIG. 34 is a diagram for describing operations of the first and second HBM devices according to an embodiment of the present disclosure.

FIG. 35 is a diagram for describing operations of the first and second HBM devices according to an embodiment of the present disclosure.

FIG. 36 is a diagram for describing operations of the first and second HBM devices according to an embodiment of the present disclosure.

FIG. 37 is a diagram for describing operations of the first and second HBM devices according to an embodiment of the present disclosure.

### DETAILED DESCRIPTION

Terms such as “first” and “second” are used to distinguish between various elements and do not imply size, order, priority, quantity, or importance of the elements. For example, a first element may be named as a second element in one example, and the second element may be named as a first element in other examples.

When one component is identified as “connected” to another component, the components may be connected directly or through an intervening component between the components. When two components are identified as “directly connected,” one component is directly connected to the other component without an intervening component between the two components. When one component is referred to as being on another component, it should be understood that the components may be directly on each other or on each other through another component interposed therebetween. In contrast, when one component is referred to as being directly on another component, it should be understood that the components are directly on each other without another component interposed therebetween. Cross-hatching throughout the figures illustrates deactivated physical areas within the figures rather than indicating the materials for the physical areas.

Embodiments of the present disclosure are described below with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

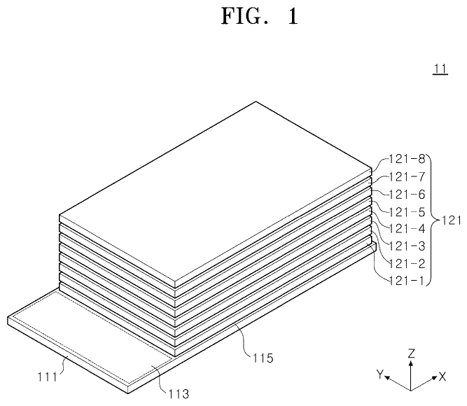

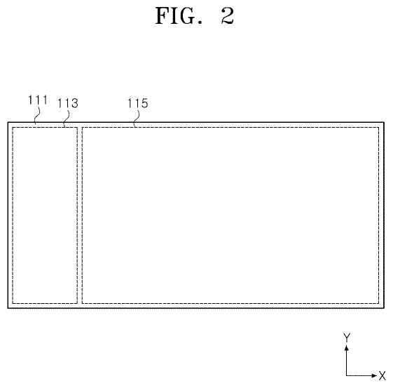

FIG. 1 illustrates a stacked memory device 11 according to an embodiment of the present disclosure, and FIG. 2 illustrates an example of the arrangement of a first area 113 and a second area 115 included in a base die 111.

As illustrated in FIG. 1, the stacked memory device 11 includes the base die 111 and a core die group 121. As illustrated in FIGS. 1 and 2, the first area 113 and the second area 115 refer to areas on the XY plane of the base die 111. The first area 113 and the second area 115 are sequentially arranged adjacent to each other in the X direction.

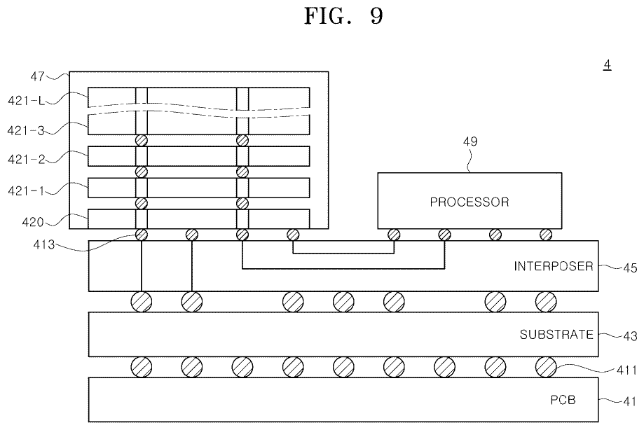

A physical layer that controls the transmission of signals (e.g., data, commands, and addresses) through a plurality of channels between the core die group 121 and a processor (e.g., a processor 49 in FIG. 9) may be disposed beneath the first area 113 of the base die 111. According to embodiments, circuits that operate in a high-temperature state due to the frequent input/output of signals among internal circuits included in the base die 111 may be disposed beneath the first area 113 of the base die 111. No structure that dissipates heat is stacked in the Z direction from the first area 113 of the base die 111. That is, an empty space is provided in the Z direction from the first area 113 of the base die 111. Thus, in an embodiment, heat generated when the internal circuits, located beneath the first area 113 of the base die 111, operate can be dissipated in the Z direction from the first area 113.

A plurality of core dies 121-1 to 121-8 of the core group 121 is stacked in the Z direction from the second area 115. The core group 121 includes a first core die 121-1, a second core die 121-2, a third core die 121-3, a fourth core die 121-4, a fifth core die 121-5, a sixth core die 121-6, a seventh core die 121-7, and an eighth core die 121-8. The first core die 121-1 is stacked in the Z direction from the second area 115, the second core die 121-2 is stacked in the Z direction from the first core die 121-1, the third core die 121-3 is stacked in the Z direction from the second core die 121-2, the fourth core die 121-4 is stacked in the Z direction from the third core die 121-3, the fifth core die 121-5 is stacked in the Z direction from the fourth core die 121-4, the sixth core die 121-6 is stacked in the Z direction from the fifth core die 121-5, the seventh core die 121-7 is stacked in the Z direction from the sixth core die 121-6, and the eight core die 121-8 is stacked in the Z direction from the seventh core die 121-7.

Various control circuits that control the core die group 121 may be disposed beneath the second area 115 of the base die 111. The control circuits disposed beneath the second area 115 may include write control circuits (not shown) that store data in the core die group 121 and read control circuits (not shown) that output data from the core die group 121.

As described above, an empty space is provided in the Z direction from the first area 113 of the base die 111, and heat generated due to an operation of the internal circuits located beneath the first area 113 is dissipated in the Z direction from the first area 113. An embodiment of this configuration helps prevent or mitigate the internal temperature of the base die 111 from rising excessively.

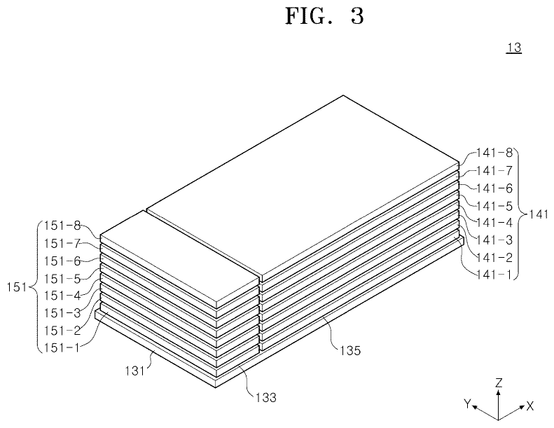

FIG. 3 illustrates a stacked memory device 13 according to an embodiment of the present disclosure.

As illustrated in FIG. 3, the stacked memory device 13 includes a base die 131 and a core die group 141. As in an embodiment described in relation to FIG. 2, the base die 131 includes a first area 133 and a second area 135 on the XY plane.

A physical layer that controls the transmission of signals (e.g., data, commands, and addresses) through a plurality of channels between the core die group 141 and a processor (e.g., a processor 49 in FIG. 9) may be disposed beneath the first area 133 of the base die 131. According to embodiments, circuits that operate in a high-temperature state due to the frequent input/output of signals, among internal circuits included in the base die 131, may be disposed beneath the first area 133 of the base die 131. In an embodiment, a plurality of dummy dies 151-1 to 151-8 of a dummy die group 151 is stacked to dissipate heat in the Z direction from the first area 133 of the base die 131. The dummy die group 151 includes a first dummy die 151-1, a second dummy die 151-2, a third dummy die 151-3, a fourth dummy die 151-4, a fifth dummy die 151-5, a sixth dummy die 151-6, a seventh dummy die 151-7, and an eighth dummy die 151-8. The first dummy die 151-1 is stacked in the Z direction from the first area 133, the second dummy die 151-2 is stacked in the Z direction from the first dummy die 151-2, the third dummy die 151-3 is stacked in the Z direction from the second dummy die 151-2, the fourth dummy die 151-4 is stacked in the Z direction from the third dummy die 151-3, the fifth dummy die 151-5 is stacked in the Z direction from the fourth dummy die 151-4, the sixth dummy die 151-6 is stacked in the Z direction from the fifth dummy die 151-5, the seventh dummy die 151-7 is stacked in the Z direction from the sixth dummy die 151-6, and the eighth dummy die 151-8 is stacked in the Z direction from the seventh dummy die 151-7. In an embodiment, the dummy dies 151-1 to 151-8 of the dummy die group 151 are stacked in the Z direction from the first area 133 of the base die 131, and thus, heat generated from the internal circuits located beneath the first area 133 of the base die 131 during operation can be dissipated in the Z direction from the first area 133 through the dummy die group 151. In an embodiment, the first dummy die 151-1, the second dummy die 151-2, the third dummy die 151-3, the fourth dummy die 151-4, the fifth dummy die 151-5, the sixth dummy die 151-6, the seventh dummy die 151-7, and the eighth dummy die 151-8 are connected through a plurality of through vias and a plurality of micro-bump pads to each other to facilitate heat dissipation.

A plurality of core dies 141-1 to 141-8 of the core die group 141 is stacked in the Z direction from the second area 135. The core die group 141 includes a first core die 141-1, a second core die 141-2, a third core die 141-3, a fourth core die 141-4, a fifth core die 141-5, a sixth core die 141-6, a seventh core die 141-7, and an eighth core die 141-8. The first core die 141-1 is stacked in the Z direction from the second area 135, the second core die 141-2 is stacked in the Z direction from the first core die 141-1, the third core die 141-3 is stacked in the Z direction from the second core die 141-2, the fourth core die 141-4 is stacked in the Z direction from the third core die 141-3, the fifth core die 141-5 is stacked in the Z direction from the fourth core die 141-4, the sixth core die 141-6 is stacked in the Z direction from the fifth core die 141-5, the seventh core die 141-7 is stacked in the Z direction from the sixth core die 141-6, and the eighth core die 141-8 is stacked in the Z direction from the seventh core die 141-7.

Various control circuits that control the core die group 141 may be disposed beneath the second area 135 of the base die 131. The control circuits disposed beneath the second area 135 may include write control circuits (not shown) that store data in the core die group 141 and read control circuits (not shown) that output data from the core die group 141.

As described above, in an embodiment, the dummy dies of the dummy die group 151 are stacked in the Z direction from the first area 133 of the base die 131, and thus, the heat generated during operation of the internal circuits located beneath the first area 133 can be dissipated through the dummy die group 151 in the Z direction from the first area 133. In an embodiment, this configuration helps prevent or mitigate the internal temperature of the base die 131 from rising excessively.

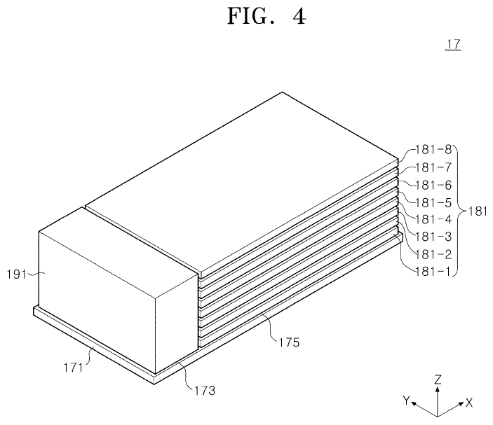

FIG. 4 illustrates a stacked memory device 17 according to an embodiment of the present disclosure.

As illustrated in FIG. 4, the stacked memory device 17 includes a base die 171 and a core die group 181. As in an embodiment illustrated in FIG. 2, the base die 171 includes a first area 173 and a second area 175 on the XY plane of the base die 171.

A physical layer that controls the transmission of signals (e.g., data, commands, and addresses) through a plurality of channels between the core die group 181 and a processor (e.g., a processor 49 in FIG. 9) may be disposed beneath the first area 173 of the base die 171. According to embodiments, circuits that operate in a high-temperature state due to the frequent input/output of signals, among internal circuits included in the base die 171, may be disposed beneath the first area 173 of the base die 171. A dummy die 191 is disposed to dissipate heat in the Z direction from the first area 173 of the base die 171.

A plurality of core dies 181-1 to 181-8 of the core die group 181 is stacked in the Z direction from the second area 175. The core die group 181 includes a first core die 181-1, a second core die 181-2, a third core die 181-3, a fourth core die 181-4, a fifth core die 181-5, a sixth core die 181-6, a seventh core die 181-7, and an eighth core die 181-8. The first core die 181-1 is stacked in the Z direction from the second area 175. The second core die 181-2 is stacked in the Z direction from the first core die 181-1, the third core die 181-3 is stacked in the Z direction from the second core die 181-2, the fourth core die 181-4 is stacked in the Z direction from the third core die 181-3, the fifth core die 181-5 is stacked in the Z direction from the fourth core die 181-4, the sixth core die 181-6 is stacked in the Z direction from the fifth core die 181-5, the seventh core die 181-7 is stacked in the Z direction from the sixth core die 181-6, and the eighth core die 181-8 is stacked in the Z direction from the seventh core die 181-7.

Various control circuits that control the core die group 181 may be disposed beneath the second area 175 of the base die 171. The control circuits disposed beneath the second area 175 may include write control circuits (not shown) that store data in the core die group 181 and read control circuits (not shown) that output data from the core die group 181.

As discussed above, in an embodiment, the dummy die 191 is disposed in the Z direction from the first area 173 of the base die 171, and thus, the heat generated from the internal circuits located beneath the first area 173 during operation can be dissipated through the dummy die 191 in the Z direction from the first area 173. In an embodiment, this configuration helps prevent or mitigate the internal temperature of the base die 171 from rising excessively.

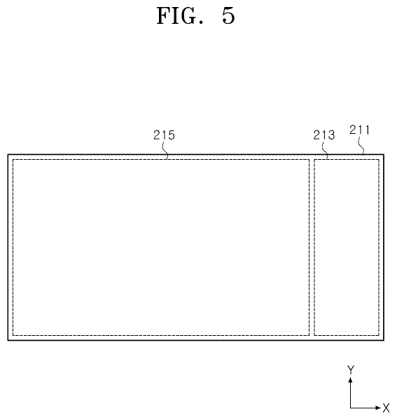

FIGS. 5 to 8 illustrate examples of the arrangement of areas included in a base die.

As illustrated in FIG. 5, a base die 211 includes a first area 213 and a second area 215 on the XY plane. The first area 213 and the second area 215 are sequentially arranged adjacent to each other in the X direction. The first area 213 may correspond to the first area 113 as illustrated in FIGS. 1 and 2 and may correspond to the first area 133 as illustrated in FIG. 3 and the first area 133 as illustrated in FIG. 3. Accordingly, in an embodiment, a physical layer that controls the transmission of signals (e.g., data, commands, and addresses) through a plurality of channels may be disposed beneath the first area 213, and an empty space may be provided on the first area 213 or at least one dummy die may be disposed on the first area 213, thereby dissipating the heat generated in internal circuits beneath the first area 213.

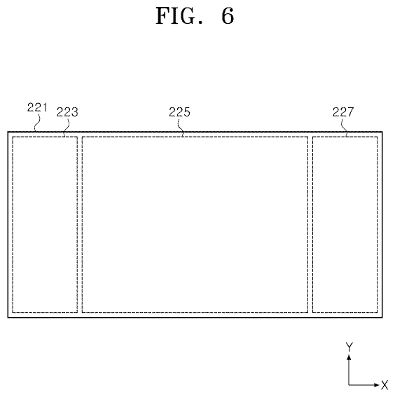

As illustrated in FIG. 6, a first area 223, a second area 225, and a third area 227 are arranged on the XY plane of a base die 221. The first area 223, the second area 225, and the third area 227 are arranged to be adjacent to each other in the X direction. The first area 223 and the third area 227 may correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 223 and the third area 227, and an empty space may be provided on the first area 223 and the third area 227 or at least one dummy die may be disposed on the first area 223 and the third area 227, thereby, in an embodiment, dissipating the heat generated in the internal circuits beneath the first area 223 and the third area 227.

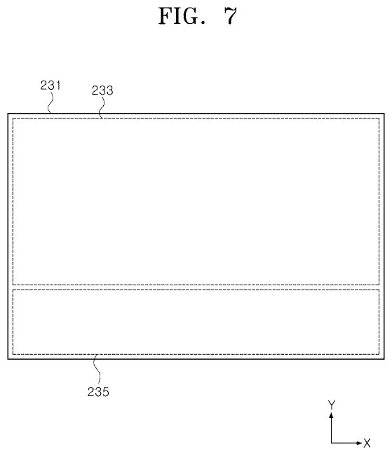

As illustrated in FIG. 7, a first area 235 and a second area 233 are arranged on the XY plane of a base die 231. The first area 235 and the second area 233 are arranged to be adjacent in the Y direction. The first area 235 may correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 235, and an empty space may be provided on the first area 235 or at least one dummy die may be disposed on the first area 235, thereby, in an embodiment, dissipating the heat generated in the internal circuits beneath the first area 235.

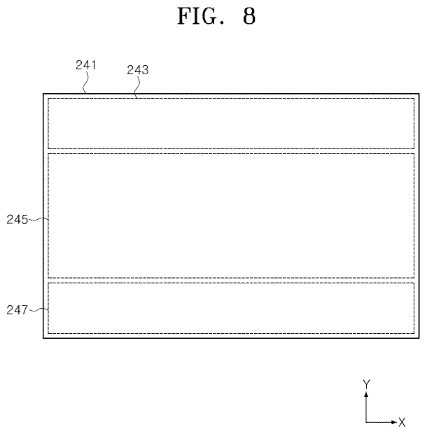

As illustrated in FIG. 8, a first area 243, a second area 245, and a third area 247 are arranged on the XY plane of a base die 241. The third area 247, the second area 245, and the first area 243 are sequentially arranged in the Y direction. The first area 243 and the third area 247 may respectively correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 243 and the third area 247, and empty spaces may be provided on the first area 243 and the third area 247 or at least one dummy die may be disposed on the first area 243 and the third area 247, thereby, in an embodiment, dissipating the heat generated in the internal circuits beneath the first area 243 and the third area 247.

FIG. 9 illustrates a memory system 4 according to an embodiment of the present disclosure.

As illustrated in FIG. 9, the memory system 4 includes a printed circuit board (PCB) 41, a substrate 43, an interposer 45, a memory device 47, and a processor 49.

The printed circuit board 41 connects various electronic components to form electronic circuits. The electronic circuits include the memory system 4. A copper (Cu) layer, a solder mask, a silk screen, and so forth are formed on the printed circuit board 41. Circuit paths that transmit or transfer signals or power are formed in the copper (Cu) layer. In an embodiment, the solder mask prevents or mitigates damage to the circuits and protects a specific area in which components are soldered. The silk screen indicates a location or information for the electronic components as characters or symbols printed on a surface of the printed circuit board 41.

The substrate 43 is disposed over the printed circuit board 41 with bump pads (e.g., bump pads 411) therebetween and mechanically supports the interposer 45, the memory device 47, and the processor 49. The substrate 43 functions as a physical base for the printed circuit board 41 and is an insulator. The substrate 43 may include materials, such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 45 is disposed over the substrate 43 with bump pads therebetween and includes wiring that connects electronic components (e.g., the memory device 47 and the processor 49) that have form factors or pin arrangements that do not match or have different spacing. The interposer 45 converts signals from different interfaces, such as DDR, HBM, and PCIe.

The memory device 47 is disposed over the interposer 45 with pads (e.g., micro bump pads 413) therebetween. The memory device 47 stores data received from the processor 49 or outputs data stored therein to the processor 49 under the control of the processor 49. The memory device 47 includes a base die 420 and a plurality of core dies 421-1 to 421-L, where L is an integer greater than 1. The core dies 421-1 to 421-L are stacked over the base die 420 with micro bump pads in between. The base die 420 and the core dies 421-1 to 421-L are vertically connected to each other using through vias and micro bump pads. The base die 420 controls efficient data transmission between the processor 49 and the core dies 421-1 to 421-L. The base die 420 receives input/output power voltage (voltage drain for IO also referred to as output stage drain power voltage) VDDQ as an operating voltage utilized during the operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 to 421-L use a peripheral voltage VPERI as an operating voltage during the operation of the internal circuits included in the core dies 421-1 to 421-L. The core dies 421-1 to 421-L generate the peripheral voltage VPERI from the input/output power voltage VDDQ received through the base die 420. The core dies 421-1 to 421-L generate the peripheral voltage VPERI at a voltage level lower than the level of the input/output power voltage VDDQ and use the peripheral voltage VPERI as an operating voltage. The core dies 421-1 to 421-L include, respectively, a plurality of channel areas, for example, eight channel areas or forty-six channel areas that operate independently. The plurality of channel areas are allocated, respectively, with a channel operating independently to receive or transmit data. The number L of core dies 421-1 to 421-L may be four, eight, thirty-two, forty-six, and so forth. For example, when each of the core dies 421-1 to 421-12 has eight channels, the core dies 421-1 to 421-4, the core dies 421-5 to 421-8, and the core dies 421-9 through 421-12 each include thirty-two channel areas and transmit and receive data with the processor 49 in units of a rank including thirty-two channels.

The memory device 47 may be implemented with the stacked memory device 11 as illustrated in FIG. 1, the stacked memory device 13 as illustrated in FIG. 3, and stacked memory device 17 as illustrated in FIG. 4. The base die 420 may be implemented with the base die 111 as illustrated in FIGS. 1 and 2, the base die 131 as illustrated in FIG. 3, the base die 171 as illustrated in FIG. 4, the base die 211 as illustrated in FIG. 5, the base die 221 as illustrated in FIG. 6, the base die 231 as illustrated in FIG. 7, and the base die 241 as illustrated in FIG. 8.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

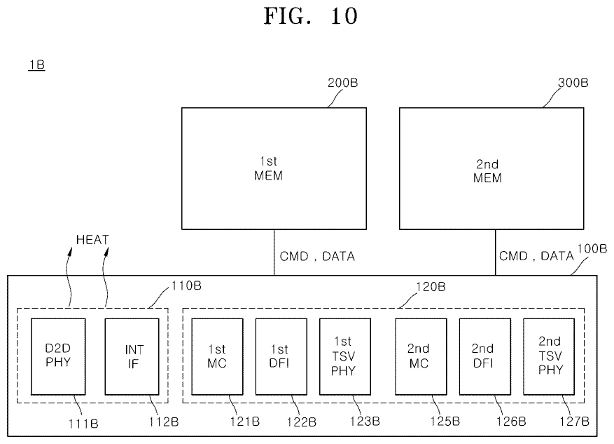

FIG. 10 illustrates a semiconductor system 1B according to an embodiment of the present disclosure. As illustrated in FIG. 10, the semiconductor system 1B may include a control device 100B, a first memory device (1st MEM) 200B, and a second memory device (2nd MEM) 300B. The control device 100B may be implemented with the base die 111 of FIGS. 1 and 2. The control device 100B may be implemented with the base die 131 of FIG. 3. The control device 100B may be implemented with the base die 171 of FIG. 4.

The control device 100B may generate a command CMD and data DATA. The control device 100B may output the command CMD and the data DATA to the first memory device 200B and the second memory device 300B. The control device 100B may receive the data DATA from the first memory device 200B and the second memory device 300B. The control device 100B may be a base chip or a controller that controls operations of the first memory device 200B and the second memory device 300B.

The control device 100B may include a first area 110B and a second area 120B. The first area 110B may be set as an area where the command CMD and the data DATA are generated. The first area 110B may be set as an area from where heat is generated when the command CMD and the data DATA are generated. The second area 120B is an area where the command CMD and the data DATA are received from the first area 110B. The second area 120B is an area from where the command CMD and the data DATA are output and transmitted to the first memory device 200B and the second memory device 300B. The upper part of the first area 110B can be set as a first predetermined area.

The first area 110B may include a physical area (D2D PHY) 111B and an internal interface area (INT IF) 112B.

The physical area 111B may generate the command CMD and the data DATA based on a signal that is received from an external device (e.g., various devices, such as a host, a processor, and a test device). The physical area 111B may output the command CMD and the data DATA to the internal interface area 112B. The physical area 111B may be a physical layer (PHY) that is responsible for the generation, transmission, reception, and physical connection of signals and data between the external device and the control device 100B.

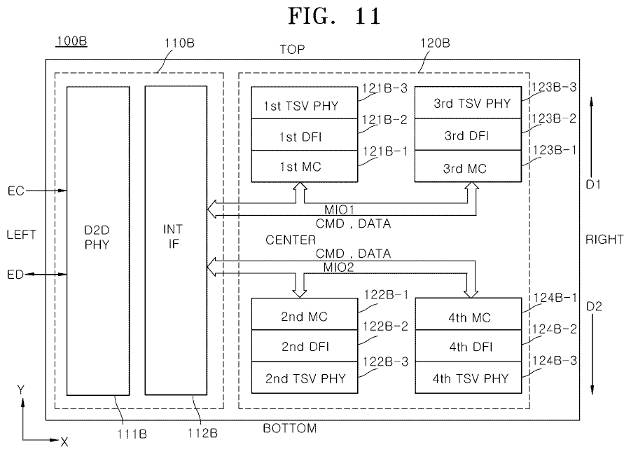

The internal interface area 112B may receive the command CMD and the data DATA from the physical area 111B. The internal interface area 112B may output the command CMD and the data DATA to internal input and output lines (MIO1 and MIO2 in FIG. 11) by adjusting the input and output sequence of the command CMD and the data DATA. The internal interface area 112B may be an interface whereby the timing and sequence of signals that are transmitted between a physical layer (PHY) and internal circuits are defined and the signals are input and output. The internal interface area 112B and the internal input and output lines (MIO1 and MIO2 in FIG. 11) may be implemented in a network-on-chip (NoC). The NoC may be set as a transmission path that connects various internal circuits within a chip.

The second area 120B may include a first memory controller (1st MC) 121B, a first base interface area (1st DFI) 122B, a first base TSV area (1st TSV PHY) 123B, a second memory controller (2nd MC) 125B, a second base interface area (2nd DFI) 126B, a second base TSV area (2nd TSV PHY) 127B.

The first memory controller 121B may receive the command CMD and the data DATA through the internal input and output lines (MIO1 and MIO2 in FIG. 11). The first memory controller 121B may output the command CMD and the data DATA that control an operation of the first memory device 200B.

The first base interface area 122B may receive the command CMD and the data DATA from the first memory controller 121B. The first base interface area 122B may output the command CMD and the data DATA to the first base TSV area 123B by adjusting the input and output sequence of the command CMD and the data DATA.

The first base TSV area 123B may receive the command CMD and the data DATA from the first base interface area 122B. The first base TSV area 123B may output the command CMD and the data DATA to the first memory device 200B through a plurality of TSVs.

The second memory controller 125B may receive the command CMD and the data DATA through the internal input and output lines (MIO1 and MIO2 in FIG. 11). The second memory controller 125B may output the command CMD and the data DATA that control an operation of the second memory device 300B.

The second base interface area 126B may receive the command CMD and the data DATA from the second memory controller 125B. The second base interface area 126B may output the command CMD and the data DATA to the second base TSV area 127B by adjusting the input and output sequence of the command CMD and the data DATA.

The second base TSV area 127B may receive the command CMD and the data DATA from the second base interface area 126B. The second base TSV area 127B may output the command CMD and the data DATA to the second memory device 300B through a plurality of TSVs.

The first memory device 200B may receive the command CMD and the data DATA from the first base TSV area 123B. The first memory device 200B may perform an internal operation based on the command CMD and the data DATA. The first memory device 200B may store the data DATA based on the command CMD after the start of a write operation. The first memory device 200B may output the data DATA that are stored based on the command CMD after the start of a read operation. The first memory device 200B may be a memory device wherein a plurality of core chips is stacked.

The second memory device 300B may receive the command CMD and the data DATA from the second base TSV area 127B. The second memory device 300B may perform an internal operation based on the command CMD and the data DATA. The second memory device 300B may store the data DATA based on the command CMD after the start of a write operation. The second memory device 300B may output the data DATA that are stored based on the command CMD after the start of a read operation. The second memory device 300B may be a memory device wherein a plurality of core chips is stacked.

The first memory device 200B and the second memory device 300B may be disposed on the second area 120B of the control device 100B. The first memory device 200B and the second memory device 300B may be vertically stacked on the second area 120B of the control device 100B. For example, the first memory device 200B and the second memory device 300B may be on the control device 100B through another component interposed therebetween. For example, the first memory device 200B and the second memory device 300B may be located vertically over the control device 100B, at least partially, and connected to the control device 100B through another component interposed therebetween. For example, the first memory device 200B and the second memory device 300B may be directly on the control device 100B without another component interposed therebetween. For example, the first memory device 200B and the second memory device 300B may be located vertically on the control device 100B, at least partially, without another component interposed therebetween. The first memory device 200B and the second memory device 300B may be horizontally disposed on the second area 120B of the control device 100B. The first memory device 200B and the second memory device 300B are connected to the control device 100B in common, and may input and output the data DATA having the same bandwidth. The bandwidth may be set as the amount of data that are input and output for a preset time.

The sum of the lengths of first memory device 200B and the second memory device 300B may be shorter than the length of the second area 120B of the control device 100B. The control device 100B may have a length that is longer than the sum of the lengths of first memory device 200B and the second memory device 300B by the first area 110B.

As described above, the semiconductor system 1B according to an embodiment of the present disclosure can increase the bandwidth because the first memory device 200B and the second memory device 300B are connected to the control device 100B in common and input and output the data DATA. The semiconductor system 1B, in an embodiment, can prevent or mitigate heat, caused from an area in which the command CMD and the data DATA are generated, from being diffused to a memory device because a memory device (e.g., 200B, 300B) is not stacked above the area in which the command CMD and the data DATA are generated.

FIG. 11 illustrates the control device 100B according to an embodiment of the present disclosure. As illustrated in FIG. 11, the control device 100B may include the first area 110B and the second area 120B.

The first area 110B may include the physical area 111B and the internal interface area 112B.

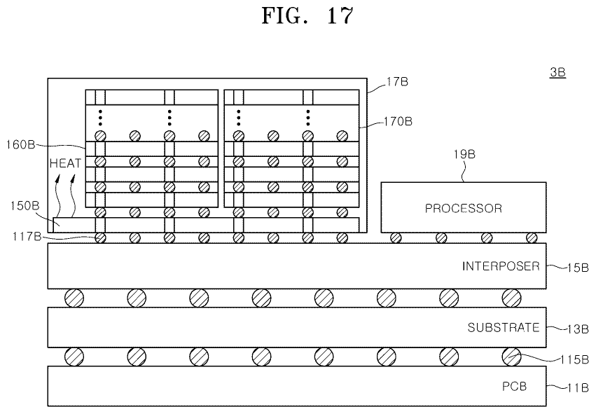

The physical area 111B may generate the command CMD by receiving an external command EC from an external device (e.g., a processor in FIG. 17). The physical area 111B may generate the command CMD by buffering or decoding the external command EC. The external command EC and the command CMD each have been illustrated as one signal, but may each include a plurality of bits. The physical area 111B may generate the data DATA by receiving external data ED from an external device (e.g., the processor in FIG. 17). The physical area 111B may generate the external data ED by receiving data DATA from the internal interface area 112B. The physical area 111B may output the external data ED to the external device (e.g., the processor in FIG. 17). The external data ED and the data DATA each have been illustrated as one signal but may include a plurality of bits. In an embodiment, the external command EC and the external data ED are received externally from the first and second areas.

The internal interface area 112B may receive the command CMD and the data DATA from the physical area 111B. The internal interface area 112B may output the command CMD and the data DATA to the first internal input and output line MIO1 by adjusting the input and output sequence of the command CMD that controls operations of the first memory device 200B and the second memory device 300B and the data DATA. The internal interface area 112B may output the command CMD and the data DATA to the second internal input and output line MIO2 by adjusting the input and output sequence of the command CMD that controls operations of the first memory device 200B and the second memory device 300B and the data DATA. The first internal input and output line MIO1 and the second internal input and output line MIO2 may be disposed in a central area CENTER of the control device 100B.

The first area 110B may be set as an area in which the command CMD and the data DATA are generated. The first area 110B may be set as an area in which heat is generated when the command CMD and the data DATA are generated. The first area 110B may be disposed in a left area LEFT of the control device 100B in an X axis.

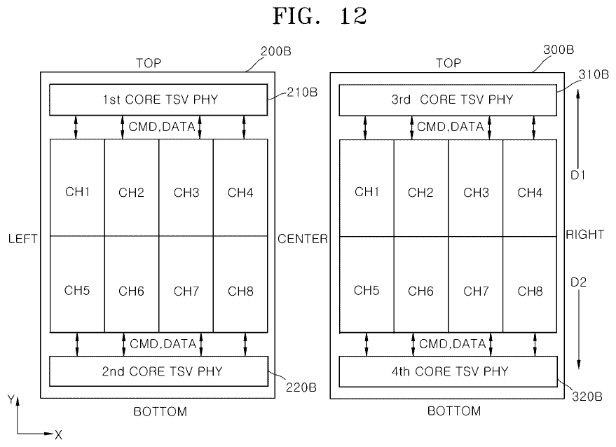

The second area 120B may include a first memory controller (1st MC) 121B-1, a first base interface area (1st DFI) 121B-2, a first base TSV area (1st TSV PHY) 121B-3, a second memory controller (2nd MC) 122B-1, a second base interface area (2nd DFI) 122B-2, and a second base TSV area (2nd TSV PHY) 122B-3 that control an operation of the first memory device 200B. The first memory controller 121B-1, the first base interface area 121B-2, and the first base TSV area 121B-3 may be components that control an operation of a first group of channels (CH1 to CH4 in FIG. 12) included in the first memory device 200B. The second memory controller 122B-1, the second base interface area 122B-2, and the second base TSV area 122B-3 may be components that control an operation of a second group of channels (CH5 to CH8 in FIG. 12) included in the first memory device 200B. Each of the first memory controller 121B-1, the first base interface area 121B-2, and the first base TSV area 121B-3 and the second memory controller 122B-1, the second base interface area 122B-2, and the second base TSV area 122B-3 may be the first memory controller 121B-1, the first base interface area 122B, and the first base TSV area 123B illustrated in FIG. 10.

The first memory controller 121B-1, the first base interface area 121B-2, and the first base TSV area 121B-3 may be arranged in the horizontal direction of the control device 100B. The second memory controller 122B-1, the second base interface area 122B-2, and the second base TSV area 122B-3 may be arranged in the horizontal direction of the control device 100B.

The first memory controller 121B-1 may be electrically connected to the first internal input and output line MIO1. The first memory controller 121B-1 may receive the command CMD and the data DATA that control an operation of the first group of channels (CH1 to CH4 in FIG. 12) included in the first memory device 200B through the first internal input and output line MIO1. The first memory controller 121B-1 may output the command CMD and the data DATA that control an operation of the first group of channels (CH1 to CH4 in FIG. 12) included in the first memory device 200B.

The first base interface area 121B-2 may be electrically connected to the first memory controller 121B-1. The first base interface area 121B-2 may receive the command CMD and the data DATA from the first memory controller 121B-1. The first base interface area 121B-2 may output the command CMD and the data DATA to the first base TSV area 121B-3 by adjusting the input and output sequence of the command CMD and the data DATA.

The first base TSV area 121B-3 may be electrically connected to the first base interface area 121B-2. The first base TSV area 121B-3 may receive the command CMD and the data DATA from the first base interface area 121B-2. The first base TSV area 121B-3 may output the command CMD and the data DATA to a first core TSV area (1st CORE TSV PHY) (210B in FIG. 12) included in the first memory device 200B through a plurality of TSVs.

The first memory controller 121B-1, the first base interface area 121B-2, and the first base TSV area 121B-3 may be sequentially disposed in a first direction D1 from the central area CENTER of the control device 100B. The first direction D1 may be set as a direction from the central area CENTER to a first edge area TOP. The first edge area TOP may be set as an upper area of the control device 100B in a Y axis. The first edge area TOP may be placed in an outward direction from the central area CENTER.

The second memory controller 122B-1 may be electrically connected to the second internal input and output line MIO2. The second memory controller 122B-1 may receive the command CMD and the data DATA that control an operation of the second group of channels (CH5 to CH8 in FIG. 12) included in the first memory device 200B through the second internal input and output line MIO2. The second memory controller 122B-1 may output the command CMD and the data DATA that control an operation of the second group of channels (CH5 to CH8 in FIG. 12) included in the first memory device 200B.

The second base interface area 122B-2 may be electrically connected to the second memory controller 122B-1. The second base interface area 122B-2 may receive the command CMD and the data DATA from the second memory controller 122B-1. The second base interface area 122B-2 may output the command CMD and the data DATA to the second base TSV area 122B-3 by adjusting the input and output sequence of the command CMD and the data DATA.

The second base TSV area 122B-3 may be electrically connected to the second base interface area 122B-2. The second base TSV area 122B-3 may receive the command CMD and the data DATA from the second base interface area 122B-2. The second base TSV area 122B-3 may output the command CMD and the data DATA to a second core TSV area (2nd CORE TSV PHY) (220B in FIG. 12) included in the first memory device 200B through a plurality of TSVs.

The second memory controller 122B-1, the second base interface area 122B-2, and the second base TSV area 122B-3 may be sequentially disposed in a second direction D2 from the central area CENTER of the control device 100B. The second direction D2 may be set as a direction from the central area CENTER to a second edge area BOTTOM. The second edge area BOTTOM may be set as a lower area of the control device 100B in the Y axis. The second edge area BOTTOM may be placed in an outward direction from the central area CENTER. The first edge area TOP and the second edge area BOTTOM may be placed in opposite directions from the central area CENTER.

The second area 120B may include a third memory controller (3rd MC) 123B-1, a third base interface area (3rd DFI) 123B-2, a third base TSV area (3rd TSV PHY) 123B-3, a fourth memory controller (4th MC) 124B-1, a fourth base interface area (4th DFI) 124B-2, and a fourth base TSV area (4th TSV PHY) 124B-3 that controls an operation of the second memory device 300B. The third memory controller 123B-1, the third base interface area 123B-2, and the third base TSV area 123B-3 may be components that control an operation of a first group of channels (CH1 to CH4 in FIG. 12) included in the second memory device 300B. The fourth memory controller 124B-1, the fourth base interface area 124B-2, and the fourth base TSV area 124B-3 may be components that control an operation of a second group of channels (CH5 to CH8 in FIG. 12) included in the second memory device 300B. Each of the third memory controller 123B-1, the third base interface area 123B-2, and the third base TSV area 123B-3, and the fourth memory controller 124BB-1, the fourth base interface area 124B-2, and the fourth base TSV area 124B-3 may be the second memory controller 125B, the second base interface area 126B, and the second base TSV area 127B illustrated in FIG. 10.

The third memory controller 123B-1, the third base interface area 123B-2, and the third base TSV area 123B-3 may be arranged in the horizontal direction of the control device 100B. The fourth memory controller 124B-1, the fourth base interface area 124B-2, and the fourth base TSV area 124B-3 may be arranged in the horizontal direction of the control device 100B.

The third memory controller 123B-1 may be electrically connected to the first internal input and output line MIO1. The third memory controller 123B-1 may receive the command CMD and the data DATA that control an operation of the first group of channels (CH1 to CH4 in FIG. 12) included in the second memory device 300B through the first internal input and output line MIO1. The third memory controller 123B-1 may output the command CMD and the data DATA that control an operation of the first group of channels (CH1 to CH4 in FIG. 12) included in the second memory device 300B.

The third base interface area 123B-2 may be electrically connected to the third memory controller 123B-1. The third base interface area 123B-2 may receive the command CMD and the data DATA from the third memory controller 123B-1. The third base interface area 123B-2 may output the command CMD and the data DATA to the third base TSV area 123B-3 by adjusting the input and output sequence of the command CMD and the data DATA.

The third base TSV area 123B-3 may be electrically connected to the third base interface area 123B-2. The third base TSV area 123B-3 may receive the command CMD and the data DATA from the third base interface area 123B-2. The third base TSV area 123B-3 may output the command CMD and the data DATA to a third core TSV area (3rd CORE TSV PHY) (310B in FIG. 12) included in the second memory device 300B through a plurality of TSVs.

The third memory controller 123B-1, the third base interface area 123B-2, and the third base TSV area 123B-3 may be sequentially disposed in the first direction D1 from the central area CENTER of the control device 100B.

The fourth memory controller 124B-1 may be electrically connected to the second internal input and output line MIO2. The fourth memory controller 124B-1 may receive the command CMD and the data DATA that control an operation of the second group of channels (CH5 to CH8 in FIG. 12) included in the second memory device 300B through the second internal input and output line MIO2. The fourth memory controller 124B-1 may output the command CMD and the data DATA that control an operation of the second group of channels (CH5 to CH8 in FIG. 12) included in the second memory device 300B.

The fourth base interface area 124B-2 may be electrically connected to the fourth memory controller 124B-1. The fourth base interface area 124B-2 may receive the command CMD and the data DATA from the fourth memory controller 124B-1. The fourth base interface area 124B-2 may output the command CMD and the data DATA to the fourth base TSV area 124B-3 by adjusting the input and output sequence of the command CMD and the data DATA.

The fourth base TSV area 124B-3 may be electrically connected to the fourth base interface area 124B-2. The fourth base TSV area 124B-3 may receive the command CMD and the data DATA from the fourth base interface area 124B-2. The fourth base TSV area 124B-3 may output the command CMD and the data DATA to a fourth core TSV area (4th CORE TSV PHY) (320B in FIG. 12) included in the second memory device 300 through a plurality of TSVs.

The fourth memory controller 124B-1, the fourth base interface area 124B-2, and the fourth base TSV area 124B-3 may be sequentially disposed in the second direction D2 from the central area CENTER of the control device 100B.

The second area 120B may be set as an area wherein the command CMD and the data DATA are received from the first area 110B and output to the first memory device 200B and the second memory device 300B. The second area 120B may be disposed in a right area RIGHT of the control device 100B in the X axis.

FIG. 12 illustrates the first memory device 200B and the second memory device 300B according to an embodiment of the present disclosure.

The first memory device 200B may include first to eighth channels CH1 to CH8, the first core TSV area 210B, and the second core TSV area 220B.

The first core TSV area 210B and the second core TSV area 220B may be arranged in the horizontal direction of the first memory device 200B.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the first core TSV area 210B. The first to fourth channels CH1 to CH4 may receive the command CMD and the data DATA from the first core TSV area 210B. The first to fourth channels CH1 to CH4 may output the data DATA to the first core TSV area 210B. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B. The fifth to eighth channels CH5 to CH8 may receive a command CMD and data DATA from the second core TSV area 220B. The fifth to eighth channels CH5 to CH8 may output the data DATA to the second core TSV area 220B. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The first to fourth channels CH1 to CH4 may be set as the first group of channels. The fifth to eighth channels CH5 to CH8 may be set as the second group of channels.

The first to fourth channels CH1 to CH4 may be disposed in the central area CENTER of the first memory device 200B. The fifth to eighth channels CH5 to CH8 may be disposed in the central area CENTER of the first memory device 200B.

The first core TSV area 210B may be electrically connected to the first base TSV area 121B-3 of the control device 100B. The first core TSV area 210B may receive the command CMD and the data DATA from the first base TSV area 121B-3. The first core TSV area 210B may receive the command CMD and the data DATA through the plurality of TSVs. The first core TSV area 210B may output the command CMD and the data DATA to the first to fourth channels CH1 to CH4. The first core TSV area 210B may receive the data DATA from the first to fourth channels CH1 to CH4 and output the data DATA to the first base TSV area 121B-3. The first core TSV area 210B may be disposed in the first direction D1 from the central area CENTER. The first direction D1 may be set as a direction from the central area CENTER to the first edge area TOP. The first edge area TOP may be set as an upper area of the first memory device 200B in the Y axis. The first edge area TOP may be placed in an outward direction from the central area CENTER.

The second core TSV area 220B may be electrically connected to the second base TSV area 122B-3 of the control device 100B. The second core TSV area 220B may receive the command CMD and the data DATA from the second base TSV area 122B-3. The second core TSV area 220B may receive the command CMD and the data DATA through the plurality of TSVs. The second core TSV area 220B may output the command CMD and the data DATA to the fifth to eighth channels CH5 to CH8. The second core TSV area 220B may receive the data DATA from the fifth to eighth channels CH5 to CH8 and output the data DATA to the second base TSV area 122B-3. The second core TSV area 220B may be disposed in the second direction D2 from the central area CENTER. The second direction D2 may be set as a direction from the central area CENTER to the second edge area BOTTOM. The second edge area BOTTOM may be set as a lower area of the first memory device 200B in the Y axis. The second edge area BOTTOM may be placed in an outward direction from the central area CENTER. The first edge area TOP and the second edge area BOTTOM may be placed in opposite directions from the central area CENTER.

The first memory device 200B may be disposed in the left area LEFT of the X axis.

The second memory device 300B may include the first to eighth channels CH1 to CH8, the third core TSV area 310B, and the fourth core TSV area 320B.

The third core TSV area 310B and the fourth core TSV area 320B may be arranged in the horizontal direction of the second memory device 300B.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the third core TSV area 310B. The first to fourth channels CH1 to CH4 may receive the command CMD and the data DATA from the third core TSV area 310B. The first to fourth channels CH1 to CH4 may output the data DATA to the third core TSV area 310B. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B. The fifth to eighth channels CH5 to CH8 may receive a command CMD and data DATA from the fourth core TSV area 320B. The fifth to eighth channels CH5 to CH8 may output the data DATA to the fourth core TSV area 320B. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to eighth channels CH1 to CH8 may be disposed in the central area CENTER of the second memory device 300B.

The third core TSV area 310B may be electrically connected to the third base TSV area 123B-3 of the control device 100B. The third core TSV area 310B may receive the command CMD and the data DATA from the third base TSV area 123B-3. The third core TSV area 310B may receive the command CMD and the data DATA through the plurality of TSVs. The third core TSV area 310B may output the command CMD and the data DATA to the first to fourth channels CH1 to CH4. The third core TSV area 310B may receive the data DATA from the first to fourth channels CH1 to CH4 and output the data DATA to the third base TSV area 123B-3. The third core TSV area 310B may be disposed in the first direction D1 from the central area CENTER.

The fourth core TSV area 320B may be electrically connected to the fourth base TSV area 124B-3 of the control device 100B. The fourth core TSV area 320B may receive the command CMD and the data DATA from the fourth base TSV area 124B-3. The fourth core TSV area 320B may receive the command CMD and the data DATA through the plurality of TSVs. The fourth core TSV area 320B may output the command CMD and the data DATA to the fifth to eighth channels CH5 to CH8. The fourth core TSV area 320B may receive the data DATA from the fifth to eighth channels CH5 to CH8 and output the data DATA to the fourth base TSV area 124B-3. The fourth core TSV area 320B may be disposed in the second direction D2 from the central area CENTER.

The second memory device 300B may be disposed in the right area RIGHT of the X axis.

As described above, the semiconductor system 1B according to an embodiment of the present disclosure can increase the bandwidth because the first memory device 200B and the second memory device 300B are connected to the control device 100B in common and input and output the data DATA. In an embodiment, the semiconductor system 1B can prevent or reduce heat from an area in which the command CMD and the data DATA are generated from being diffused to a memory device because a memory device (e.g., 200B, 300B) is not stacked above the area in which the command CMD and the data DATA are generated.

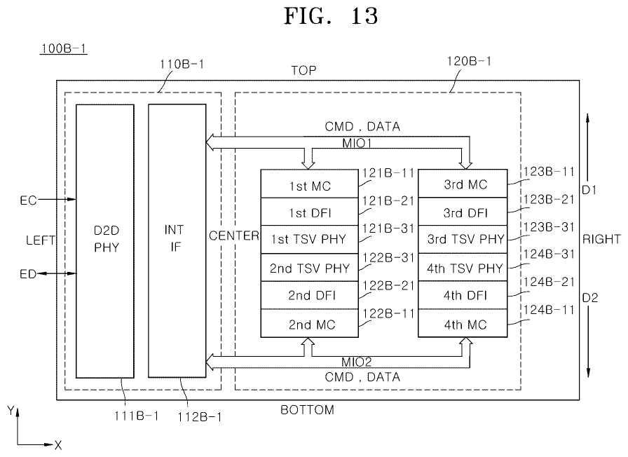

FIG. 13 illustrates a control device according to an embodiment of the present disclosure. In an embodiment, the control device 100B-1 represents the control device 100B illustrated in FIG. 10. As illustrated in FIG. 13, the control device 100B-1 may include a first area 110B-1 and a second area 120B-1.

The first area 110B-1 may include a physical area (D2D PHY) 111B-1 and an internal interface area (INT IF) 112B-1.

The physical area 111B-1 may generate a command CMD based on an external command EC from an external device (e.g., the processor in FIG. 17). The physical area 111B-1 may generate the command CMD by buffering or decoding the external command EC. The external command EC and the command CMD each have been illustrated as one signal, but may each include a plurality of bits. The physical area 111B-1 may generate data DATA by receiving external data ED from an external device (e.g., the processor in FIG. 17). The physical area 111B-1 may generate the external data ED by receiving data DATA from the internal interface area 112B-1. The external data ED and the data DATA each have been illustrated as one signal, but may each include a plurality of bits.

The internal interface area 112B-1 may receive the command CMD and the data DATA from the physical area 111B-1. The internal interface area 112B-1 may output the command CMD and the data DATA to a first internal input and output line MIO1 by adjusting the input and output sequence of the command CMD and the data DATA that control operations of a first memory device 200B-1 and a second memory device 300B-1. The internal interface area 112B-1 may output the command CMD and the data DATA to a second internal input and output line MIO2 by adjusting the input and output sequence of the command CMD that controls operations of the first memory device 200B-1 and the second memory device 300B-1 and the data DATA. The first internal input and output line MIO1 may be disposed in a first edge area TOP of the control device 100B-1. The second internal input and output line MIO2 may be disposed in a second edge area BOTTOM of the control device 100B-1.

The first area 110B-1 may be set as an area in which the command CMD and the data DATA are generated. The first area 110B-1 may be set as an area in which heat is generated when the command CMD and the data DATA are generated. The first area 110B-1 may be disposed in a left area LEFT of the control device 100B-1 in an X axis.

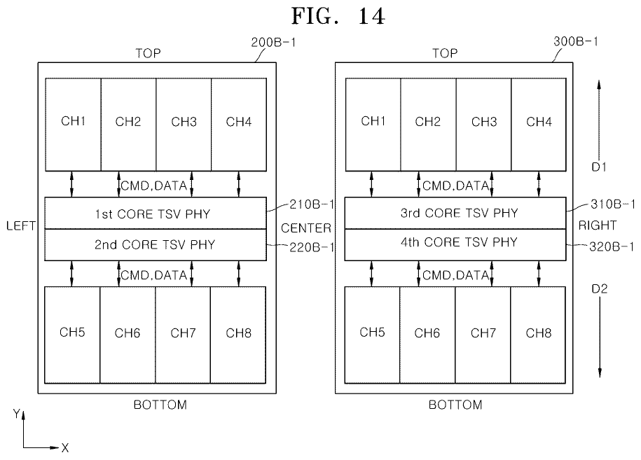

The second area 120B-1 may include a first memory controller (1st MC) 121B-11, a first base interface area (1st DFI) 121B-21, a first base TSV area (1st TSV PHY) 121B-31, a second memory controller (2nd MC) 122B-11, a second base interface area (2nd DFI) 122B-21, and a second base TSV area (2nd TSV PHY) 122B-31 that control an operation of the first memory device 200B-1. The first memory controller 121B-11, the first base interface area 121B-21, and the first base TSV area 121B-31 may be components that control an operation of a first group of channels (CH1 to CH4 in FIG. 14) included in the first memory device 200B-1. The second memory controller 122B-11, the second base interface area 122B-21, and the second base TSV area 122B-31 may be components that control an operation of a second group of channels (CH5 to CH8 in FIG. 14) included in the first memory device 200B-1.

The first memory controller 121B-11, the first base interface area 121B-21, and the first base TSV area 121B-31 may be arranged in the horizontal direction of the control device 100B-1. The second memory controller 122B-11, the second base interface area 122B-21, and the second base TSV area 122B-31 may be arranged in the horizontal direction of the control device 100B-1.

The first memory controller 121B-11 may be electrically connected to the first internal input and output line MIO1. The first memory controller 121B-11 may receive the command CMD and the data DATA that control an operation of the first group of channels (CH1 to CH4 in FIG. 14) included in the first memory device 200B-1 to the first internal input and output line MIO1. The first memory controller 121B-11 may output the command CMD and the data DATA that control an operation of the first group of channels (CH1 to CH4 in FIG. 14) included in the first memory device 200B-1.

The first base interface area 121B-21 may be electrically connected to the first memory controller 121B-11. The first base interface area 121B-21 may receive the command CMD and the data DATA from the first memory controller 121B-11. The first base interface area 121B-21 may output the command CMD and the data DATA to the first base TSV area 121B-31 by adjusting the input and output sequence of the command CMD and the data DATA.

The first base TSV area 121B-31 may be electrically connected to the first base interface area 121B-21. The first base TSV area 121B-31 may receive the command CMD and the data DATA from the first base interface area 121B-21. The first base TSV area 121B-31 may output the command CMD and the data DATA to a first core TSV area (1st CORE TSV PHY) (210B-1 in FIG. 14) included in the first memory device 200B-1 through a plurality of TSVs.

The first memory controller 121B-11, the first base interface area 121B-21, and the first base TSV area 121B-31 may be sequentially disposed in a second direction D2 from the first edge area TOP of the control device 100B-1. The second direction D2 may be set as a direction from the first edge area TOP to a central area CENTER. The first edge area TOP may be set as an upper area of the control device 100B-1 in a Y axis. The first edge area TOP may be placed in an outward direction from the central area CENTER.

The second memory controller 122B-11 may be electrically connected to the second internal input and output line MIO2. The second memory controller 122B-11 may receive the command CMD and the data DATA that control an operation of the second group of channels (CH5 to CH8 in FIG. 14) included in the first memory device 200B-1 through the second internal input and output line MIO2. The second memory controller 122B-11 may output the command CMD and the data DATA that control an operation of the second group of channels (CH5 to CH8 in FIG. 14) included in the first memory device 200B-1.

The second base interface area 122B-21 may be electrically connected to the second memory controller 122B-11. The second base interface area 122B-21 may receive the command CMD and the data DATA from the second memory controller 122B-11. The second base interface area 122B-21 may output the command CMD and the data DATA to the second base TSV area 122B-31 by adjusting the input and output sequence of the command CMD and the data DATA.

The second base TSV area 122B-31 may be electrically connected to the second base interface area 122B-21. The second base TSV area 122B-31 may receive the command CMD and the data DATA from the second base interface area 122B-21. The second base TSV area 122B-31 may output the command CMD and the data DATA to a second core TSV area (2nd CORE TSV PHY) (220B-1 in FIG. 14) included in the first memory device 200B-1 through a plurality of TSVs.

The second memory controller 122B-11, the second base interface area 122B-21, and the second base TSV area 122B-31 may be sequentially disposed in a first direction D1 from the second edge area BOTTOM of the control device 100B-1. The first direction D1 may be set as a direction from the second edge area BOTTOM to the central area CENTER. The second edge area BOTTOM may be set as a lower area of the control device 100B-1 in the Y axis. The second edge area BOTTOM may be placed in an outward direction from the central area CENTER. The first edge area TOP and the second edge area BOTTOM may be placed in opposite directions from the central area CENTER.

The second area 120B-1 may include a third memory controller (3rd MC) 123B-11, a third base interface area (3rd DFI) 123B-21, a third base TSV area (3rd TSV PHY) 123B-31, a fourth memory controller (4th MC) 124B-11, a fourth base interface area (4th DFI) 124B-21, and a fourth base TSV area (4th TSV PHY) 124B-31 that control an operation of the second memory device 300B-1. The third memory controller 123B-11, the third base interface area 123B-21, and the third base TSV area 123B-31 may be components that control an operation of a first group of channels (CH1 to CH4 in FIG. 14) included in the second memory device 300B-1. The fourth memory controller 124B-11, the fourth base interface area 124B-21, and the fourth base TSV area 124B-31 may be components that control an operation of a second group of channels (CH5 to CH8 in FIG. 14) included in the second memory device 300B-1.

The third memory controller 123B-11, the third base interface area 123B-21, and the third base TSV area 123B-31 may be arranged in the horizontal direction of the control device 100B-1. The fourth memory controller 124B-11, the fourth base interface area 124B-21, and the fourth base TSV area 124B-31 may be arranged in the horizontal direction of the control device 100B-1.

The third memory controller 123B-11 may be electrically connected to the first internal input and output line MIO1. The third memory controller 123B-11 may receive the command CMD and the data DATA that control an operation of the first group of channels (CH1 to CH4 in FIG. 14) included in the second memory device 300B-1 through the first internal input and output line MIO1. The third memory controller 123B-11 may output the command CMD and the data DATA that control an operation of the first group of channels (CH1 to CH4 in FIG. 14) included in the second memory device 300B-1.

The third base interface area 123B-21 may be electrically connected to the third memory controller 123B-11. The third base interface area 123B-21 may receive the command CMD and the data DATA from the third memory controller 123B-11. The third base interface area 123B-21 may output the command CMD and the data DATA to the third base TSV area 123B-31 by adjusting the input and output sequence of the command CMD and the data DATA.

The third base TSV area 123B-31 may be electrically connected to the third base interface area 123B-21. The third base TSV area 123B-31 may receive the command CMD and the data DATA from the third base interface area 123B-21. The third base TSV area 123B-31 may output the command CMD and the data DATA to a third core TSV area (3rd CORE TSV PHY) (310B-1 in FIG. 14) included in the second memory device 300B-1 through a plurality of TSVs.

The third memory controller 123B-11, the third base interface area 123B-21, and the third base TSV area 123B-31 may be sequentially disposed in the second direction D2 from the first edge area TOP of the control device 100A.

The fourth memory controller 124B-11 may be electrically connected to the second internal input and output line MIO2. The fourth memory controller 124B-11 may receive the command CMD and the data DATA through that control an operation of the second group of channels (CH5 to CH8 in FIG. 14) included in the second memory device 300B-1 the second internal input and output line MIO2. The fourth memory controller 124B-11 may output the command CMD and the data DATA that control an operation of the second group of channels (CH5 to CH8 in FIG. 14) included in the second memory device 300B-1.

The fourth base interface area 124B-21 may be electrically connected to the fourth memory controller 124B-11. The fourth base interface area 124B-21 may receive the command CMD and the data DATA from the fourth memory controller 124B-11. The fourth base interface area 124B-21 may output the command CMD and the data DATA to the fourth base TSV area 124B-31 by adjusting the input and output sequence of the command CMD and the data DATA.

The fourth base TSV area 124B-31 may be electrically connected to the fourth base interface area 124B-21. The fourth base TSV area 124B-31 may receive the command CMD and the data DATA from the fourth base interface area 124B-21. The fourth base TSV area 124B-31 may output the command CMD and the data DATA to a fourth core TSV area (4th CORE TSV PHY) (320B-1 in FIG. 14) included in the second memory device 300B-1 through a plurality of TSVs.

The fourth memory controller 124B-11, the fourth base interface area 124B-21, and the fourth base TSV area 124B-31 may be sequentially disposed in the first direction D1 from the second edge area BOTTOM of the control device 100B-1.

The second area 120B-1 may be set as an area in which the command CMD and the data DATA are received from the first area 110B-1 and output to the first memory device 200B-1 and the second memory device 300B-1. The second area 120B-1 may be disposed in a right area RIGHT in the X axis of the control device 100B-1.

FIG. 14 illustrates the first memory device 200B-1 and the second memory device 300B-1 according to an embodiment of the present disclosure.

The first memory device 200B-1 may include the first to eighth channels CH1 to CH8, the first core TSV area 210B-1, and the second core TSV area 220B-1.

The first core TSV area 210B-1 and the second core TSV area 220B-1 may be arranged in the horizontal direction of the first memory device 200B-1.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the first core TSV area 210B-1. The first to fourth channels CH1 to CH4 may receive the command CMD and the data DATA from the first core TSV area 210B-1. The first to fourth channels CH1 to CH4 may output the data DATA to the first core TSV area 210B-1. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B-1. The fifth to eighth channels CH5 to CH8 may receive a command CMD and data DATA from the second core TSV area 220B-1. The fifth to eighth channels CH5 to CH8 may output the data DATA to the second core TSV area 220B-1. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to fourth channels CH1 to CH4 may be disposed in the first edge area TOP of the first memory device 200B-1. The fifth to eighth channels CH5 to CH8 may be disposed in the second edge area BOTTOM of the first memory device 200B-1.

The first core TSV area 210B-1 may be electrically connected to the first base TSV area 121B-31 of the control device 100B-1. The first core TSV area 210B-1 may receive the command CMD and the data DATA from the first base TSV area 121B-31. The first core TSV area 210B-1 may receive the command CMD and the data DATA through the plurality of TSVs. The first core TSV area 210B-1 may output the command CMD and the data DATA to the first to fourth channels CH1 to CH4. The first core TSV area 210B-1 may receive the data DATA from the first to fourth channels CH1 to CH4 and output the data DATA to the first base TSV area 121B-31. The first core TSV area 210B-1 may be disposed in the central area CENTER. The first core TSV area 210B-1 may be disposed in the second direction D2 from the first edge area TOP. The second direction D2 may be set as a direction from the first edge area TOP to the central area CENTER. The first edge area TOP may be set as an upper area of the first memory device 200B-1 in the Y axis. The first edge area TOP may be placed in an outward direction from the central area CENTER.

The second core TSV area 220B-1 may be electrically connected to the second base TSV area 122B-31 of the control device 100B-1. The second core TSV area 220B-1 may receive the command CMD and the data DATA from the second base TSV area 122B-31. The second core TSV area 220B-1 may receive the command CMD and the data DATA through the plurality of TSVs. The second core TSV area 220B-1 may output the command CMD and the data DATA to the fifth to eighth channels CH5 to CH8. The second core TSV area 220B-1 may receive the data DATA from the fifth to eighth channels CH5 to CH8 and output the data DATA to the second base TSV area 122B-31. The second core TSV area 220B-1 may be disposed in the central area CENTER. The second core TSV area 220B-1 may be disposed in the first direction D1 from the second edge area BOTTOM. The first direction D1 may be set as a direction from the second edge area BOTTOM to the central area CENTER. The second edge area BOTTOM may be set as a lower area of the first memory device 200B-1 in the Y axis. The second edge area BOTTOM may be placed in an outward direction from the central area CENTER. The first edge area TOP and the second edge area BOTTOM may be placed in opposite directions from the central area CENTER.

The first memory device 200B-1 may be disposed in the left area LEFT of the X axis.

The second memory device 300B-1 may include the first to eighth channels CH1 to CH8, the third core TSV area 310B-1, and the fourth core TSV area 320B-1.

The third core TSV area 310B-1 and the fourth core TSV area 320B-1 may be arranged in the horizontal direction of the second memory device 300B-1.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the third core TSV area 310B-1. The first to fourth channels CH1 to CH4 may receive the command CMD and the data DATA from the third core TSV area 310B-1. The first to fourth channels CH1 to CH4 may output the data DATA to the third core TSV area 310B-1. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B-1. The fifth to eighth channels CH5 to CH8 may receive a command CMD and data DATA from the fourth core TSV area 320B-1. The fifth to eighth channels CH5 to CH8 may output the data DATA to the fourth core TSV area 320B-1. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to eighth channels CH1 to CH8 may be disposed in the first edge area TOP of the second memory device 300B-1.

The third core TSV area 310B-1 may be electrically connected to the third base TSV area 123B-31 of the control device 100B-1. The third core TSV area 310B-1 may receive the command CMD and the data DATA from the third base TSV area 123B-31. The third core TSV area 310B-1 may receive the command CMD and the data DATA through the plurality of TSVs. The third core TSV area 310B-1 may output the command CMD and the data DATA to the first to fourth channels CH1 to CH4. The third core TSV area 310B-1 may receive the data DATA from the first to fourth channels CH1 to CH4 and output the data DATA to the third base TSV area 123B-31. The third core TSV area 310B-1 may be disposed in the central area CENTER. The third core TSV area 310B-1 may be disposed in the second direction D2 from the first edge area TOP.

The fourth core TSV area 320B-1 may be electrically connected to the fourth base TSV area 124B-31 of the control device 100B-1. The fourth core TSV area 320B-1 may receive the command CMD and the data DATA from the fourth base TSV area 124B-31. The fourth core TSV area 320B-1 may receive the command CMD and the data DATA through the plurality of TSVs. The fourth core TSV area 320B-1 may output the command CMD and the data DATA to the fifth to eighth channels CH5 to CH8. The fourth core TSV area 320B-1 may receive the data DATA from the fifth to eighth channels CH5 to CH8 and output the data DATA to the fourth base TSV area 124B-31. The fourth core TSV area 320B-1 may be disposed in the central area CENTER. The fourth core TSV area 320B-1 may be disposed in the first direction D1 from the second edge area BOTTOM.

The second memory device 300B-1 may be disposed in the right area RIGHT of the X axis.

As described above, the semiconductor system 1B according to an embodiment of the present disclosure can increase the bandwidth because the first memory device 200B-1 and the second memory device 300B-1 are connected to the control device 100B-1 in common and input and output the data DATA. In an embodiment, the semiconductor system 1B can prevent or reduce heat from an area in which the command CMD and the data DATA are generated from being diffused to a memory device because a memory device (e.g., 200B-1, 300B-1) is not stacked above the area in which the command CMD and the data DATA are generated.

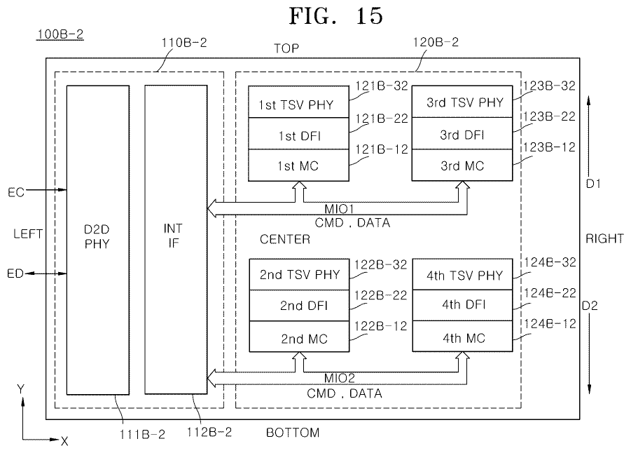

FIG. 15 illustrates the control device 100B according to an embodiment of the present disclosure. As illustrated in FIG. 15, a control device 100B-2 may include a first area 110B-2 and a second area 120B-2.

The first area 110B-2 may include a physical area (D2D PHY) 111B-2 and an internal interface area (INT IF) 112B-2.

The physical area 111B-2 may generate the command CMD based on an external command EC from an external device (e.g., the processor in FIG. 17). The physical area 111B-2 may generate the command CMD by buffering or decoding the external command EC. The external command EC and the command CMD each have been illustrated as one signal, but may each include a plurality of bits. The physical area 111B-2 may generate the data DATA by receiving external data ED from an external device (e.g., the processor in FIG. 17). The physical area 111B-2 may generate the external data ED by receiving data DATA from the internal interface area 112B-2. The physical area 111B-2 may output the external data ED to an external device (e.g., the processor in FIG. 17). The external data ED and the data DATA each have been illustrated as one signal, but may each include a plurality of bits.

The internal interface area 112B-2 may receive the command CMD and the data DATA from the physical area 111B-2. The internal interface area 112B-2 may output the command CMD and the data DATA to a first internal input and output line MIO1 by adjusting the input and output sequence of the command CMD and the data DATA that control operations of a first memory device 200B-2 and a second memory device 300B-2. The internal interface area 112B-2 may output the command CMD and the data DATA to a second internal input and output line MIO2 by adjusting the input and output sequence of the command CMD and the data DATA that control operations of the first memory device 200B-2 and the second memory device 300B-2. The first internal input and output line MIO1 may be disposed in a central area CENTER of the control device 100B-2. The second internal input and output line MIO2 may be disposed in a second edge area BOTTOM of the control device 100B-2.

The first area 110B-2 may be set as an area in which the command CMD and the data DATA are generated. The first area 110B-2 may be set as an area in which heat is generated when the command CMD and the data DATA are generated. The first area 110B-2 may be disposed in a left area LEFT of the control device 100B-2 in an X axis.

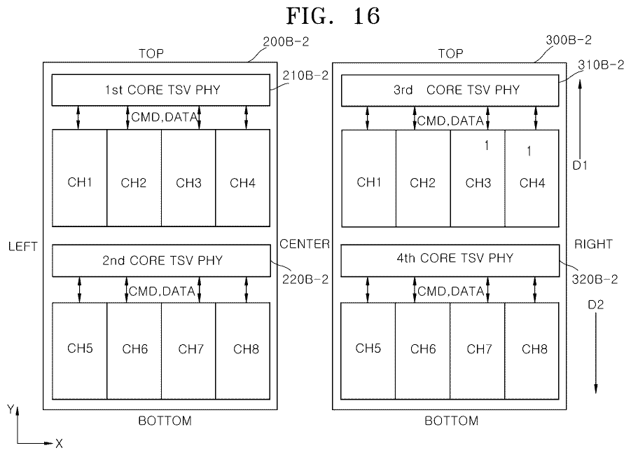

The second area 120B-2 may include a first memory controller (1st MC) 121B-12, a first base interface area (1st DFI) 121B-22, a first base TSV area (1st TSV PHY) 121B-32, a second memory controller (2nd MC) 122B-12, a second base interface area (2nd DFI) 122B-22, and a second base TSV area (2nd TSV PHY) 122B-32 that control an operations of the first memory device 200B-2. The first memory controller 121B-12, the first base interface area 121B-22, and the first base TSV area 121B-32 may be components that control an operation of a first group of channels (CH1 to CH4 in FIG. 16) included in the first memory device 200B-2. The second memory controller 122B-12, the second base interface area 122B-22, and the second base TSV area 122B-32 may be components that control an operation of a second group of channels (CH5 to CH8 in FIG. 16) included in the first memory device 200B-2.

The first memory controller 121B-12, the first base interface area 121B-22, and the first base TSV area 121B-32 may be arranged in the horizontal direction of the control device 100B-2. The second memory controller 122B-12, the second base interface area 122B-22, and a second base TSV area 122B-32 may be arranged in the horizontal direction of the control device 100B-2.

The first memory controller 121B-12 may be electrically connected to the first internal input and output line MIO1. The first memory controller 121B-12 may receive the command CMD and the data DATA that control an operation of the first group of channels (CH1 to CH4 in FIG. 16) included in the first memory device 200B-2 through the first internal input and output line MIO1. The first memory controller 121B-12 may output the command CMD and the data DATA that control an operation of the first group of channels (CH1 to CH4 in FIG. 16) included in the first memory device 200B-2.

The first base interface area 121B-22 may be electrically connected to the first memory controller 121B-12. The first base interface area 121B-22 may receive the command CMD and the data DATA from the first memory controller 121B-12. The first base interface area 121B-22 may output the command CMD and the data DATA to the first base TSV area 121B-32 by adjusting the input and output sequence of the command CMD and the data DATA.

The first base TSV area 121B-32 may be electrically connected to the first base interface area 121B-22. The first base TSV area 121B-32 may receive the command CMD and the data DATA from the first base interface area 121B-22. The first base TSV area 121B-32 may output the command CMD and the data DATA to a first core TSV area (1st CORE TSV PHY) (210B-2 in FIG. 16) included in the first memory device 200B-2 through a plurality of TSVs.

The first memory controller 121B-12, the first base interface area 121B-22, and the first base TSV area 121B-32 may be sequentially disposed in a first direction D1 from the central area CENTER of the control device 100B-2. The first direction D1 may be set as a direction from the central area CENTER to a first edge area TOP. The first edge area TOP may be set as an upper area of the control device 100B-2 in a Y axis. The first edge area TOP may be placed in an outward direction from the central area CENTER.

The second memory controller 122B-12 may be electrically connected to the second internal input and output line MIO2. The second memory controller 122B-12 may receive the command CMD and the data DATA that control an operation of the second group of channels (CH5 to CH8 in FIG. 16) included in the first memory device 200B-2 through the second internal input and output line MIO2. The second memory controller 122B-12 may output the command CMD and the data DATA that control an operation of the second group of channels (CH5 to CH8 in FIG. 16) included in the first memory device 200B-2.

The second base interface area 122B-22 may be electrically connected to the second memory controller 122B-12. The second base interface area 122B-22 may receive the command CMD and the data DATA from the second memory controller 122B-12. The second base interface area 122B-22 may output the command CMD and the data DATA to the second base TSV area 122B-32 by adjusting the input and output sequence of the command CMD and the data DATA.

The second base TSV area 122B-32 may be electrically connected to the second base interface area 122B-22. The second base TSV area 122B-32 may receive the command CMD and the data DATA from the second base interface area 122B-22. The second base TSV area 122B-32 may output the command CMD and the data DATA to a second core TSV area (2nd CORE TSV PHY) (220B-2 in FIG. 16) included in the first memory device 200B-2 through a plurality of TSVs.

The second memory controller 122B-12, the second base interface area 122B-22, and the second base TSV area 122B-32 may be sequentially disposed in the first direction D1 from the second edge area BOTTOM of the control device 100B-2. The first direction D1 may be set as a direction from the second edge area BOTTOM to the central area CENTER. The second edge area BOTTOM may be set as a lower area of the control device 100B-2 in the Y axis. The second edge area BOTTOM may be placed in an outward direction from the central area CENTER. The first edge area TOP and the second edge area BOTTOM may be placed in opposite directions from the central area CENTER.

The second area 120B-2 may include a third memory controller (3rd MC) 123B-12, a third base interface area (3rd DFI) 123B-22, a third base TSV area (3rd TSV PHY) 123B-32, a fourth memory controller (4th MC) 124B-12, a fourth base interface area (4th DFI) 124B-22, and a fourth base TSV area (4th TSV PHY) 124B-32 that control an operation of the second memory device 300B-2. The third memory controller 123B-12, the third base interface area 123B-22 and the third base TSV area 123B-32 may be components that control an operation of a first group of channels (CH1 to CH4 in FIG. 16) included in the second memory device 300B-2. The fourth memory controller 124B-12, the fourth base interface area 124B-22, and the fourth base TSV area 124B-32 may be components that control an operation of a second group of channels (CH5 to CH8 in FIG. 16) included in the second memory device 300B-2.

The third memory controller 123B-12, the third base interface area 123B-22, and the third base TSV area 123B-32 may be arranged in the horizontal direction of the control device 100B-2. The fourth memory controller 124B-12, the fourth base interface area 124B-22, and the fourth base TSV area 124B-32 may be arranged in the horizontal direction of the control device 100B-2.

The third memory controller 123B-12 may be electrically connected to the first internal input and output line MIO1. The third memory controller 123B-12 may receive the command CMD and the data DATA that control an operation of the first group of channels (CH1 to CH4 in FIG. 16) included in the second memory device 300B-2 through the first internal input and output line MIO1. The third memory controller 123B-12 may output the command CMD and the data DATA that control an operation of the first group of channels (CH1 to CH4 in FIG. 16) included in the second memory device 300B-2.

The third base interface area 123B-22 may be electrically connected to the third memory controller 123B-12. The third base interface area 123B-22 may receive the command CMD and the data DATA from the third memory controller 123B-12. The third base interface area 123B-22 may output the command CMD and the data DATA to the third base TSV area 123B-32 by adjusting the input and output sequence of the command CMD and the data DATA.

The third base TSV area 123B-32 may be electrically connected to the third base interface area 123B-22. The third base TSV area 123B-32 may receive the command CMD and the data DATA from the third base interface area 123B-22. The third base TSV area 123B-32 may output the command CMD and the data DATA to a third core TSV area (3rd CORE TSV PHY) (310B-2 in FIG. 16) included in the second memory device 300B-2 through a plurality of TSVs.

The third memory controller 123B-12, the third base interface area 123B-22, and the third base TSV area 123B-32 may be sequentially disposed in the first direction D1 from the central area CENTER of the control device 100B-2.

The fourth memory controller 124B-12 may be electrically connected to the second internal input and output line MIO2. The fourth memory controller 124B-12 may receive the command CMD and the data DATA that control an operation of the second group of channels (CH5 to CH8 in FIG. 16) included in the second memory device 300B-2 through the second internal input and output line MIO2. The fourth memory controller 124B-12 may output the command CMD and the data DATA that control an operation of the second group of channels (CH5 to CH8 in FIG. 16) included in the second memory device 300B-2.

The fourth base interface area 124B-22 may be electrically connected to the fourth memory controller 124B-12. The fourth base interface area 124B-22 may receive the command CMD and the data DATA from the fourth memory controller 124B-12. The fourth base interface area 124B-22 may output the command CMD and the data DATA to the fourth base TSV area 124B-32 by adjusting the input and output sequence of the command CMD and the data DATA.

The fourth base TSV area 124B-32 may be electrically connected to the fourth base interface area 124B-22. The fourth base TSV area 124B-32 may receive the command CMD and the data DATA from the fourth base interface area 124B-22. The fourth base TSV area 124B-32 may output the command CMD and the data DATA to a fourth core TSV area (4th CORE TSV PHY) (320B-2 in FIG. 16) included in the second memory device 300B-2 through a plurality of TSVs.

The fourth memory controller 124B-12, the fourth base interface area 124B-22, and the fourth base TSV area 124B-32 may be sequentially disposed in the first direction D1 from the second edge area BOTTOM of the control device 100B-2.

The second area 120B-2 may be set as an area in which the command CMD and the data DATA are received from the first area 110B-2 and output to the first memory device 200B-2 and the second memory device 300B-2. The second area 120B-2 may be disposed in a right area RIGHT of the control device 100B-2 in the X axis.

FIG. 16 illustrates the first memory device 200B-2 and the second memory device 300B-2 according to an embodiment of the present disclosure.

The first memory device 200B-2 may include the first to eighth channels CH1 to CH8, the first core TSV area 210B-2, and the second core TSV area 220B-2.

The first core TSV area 210B-2, and the second core TSV area 220B-2 may be arranged in the horizontal direction of the first memory device 200B-2.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the first core TSV area 210B-2. The first to fourth channels CH1 to CH4 may receive the command CMD and the data DATA from the first core TSV area 210B-2. The first to fourth channels CH1 to CH4 may output the data DATA to the first core TSV area 210B-2. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B-2. The fifth to eighth channels CH5 to CH8 may receive a command CMD and data DATA from the second core TSV area 220B-2. The fifth to eighth channels CH5 to CH8 may output the data DATA to the second core TSV area 220B-2. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the first memory device 200B-2. The fifth to eighth channels CH5 to CH8 may be disposed in a second edge area BOTTOM of the first memory device 200B-2.

The first core TSV area 210B-2 may be electrically connected to the first base TSV area 121B-32 of the control device 100B-2. The first core TSV area 210B-2 may receive the command CMD and the data DATA from the first base TSV area 121B-32. The first core TSV area 210B-2 may receive the command CMD and the data DATA through a plurality of TSVs. The first core TSV area 210B-2 may output the command CMD and the data DATA to the first to fourth channels CH1 to CH4. The first core TSV area 210B-2 may receive the data DATA from the first to fourth channels CH1 to CH4 and output the data DATA to the first base TSV area 121B-32. The first core TSV area 210B-2 may be disposed in a first direction D1 from the central area CENTER. The first direction D1 may be set as a direction from the central area CENTER to a first edge area TOP. The first edge area TOP may be set as an upper area of the first memory device 200B-2 in the Y axis. The first edge area TOP may be placed in an outward direction from the central area CENTER.

The second core TSV area 220B-2 may be electrically connected to the second base TSV area 122B-32 of the control device 100B-2. The second core TSV area 220B-2 may receive the command CMD and the data DATA from the second base TSV area 122B-32. The second core TSV area 220B-2 may receive the command CMD and the data DATA through the plurality of TSVs. The second core TSV area 220B-2 may output the command CMD and the data DATA to the fifth to eighth channels CH5 to CH8. The second core TSV area 220B-2 may receive the data DATA from the fifth to eighth channels CH5 to CH8 and output the data DATA to the second base TSV area 122B-32. The second core TSV area 220B-2 may be disposed in the central area CENTER. The second core TSV area 220B-2 may be disposed in the first direction D1 from the second edge area BOTTOM. The first direction D1 may be set as a direction from the second edge area BOTTOM to the central area CENTER. The second edge area BOTTOM may be set as a lower area of the first memory device 200B-2 in a Y axis. The second edge area BOTTOM may be placed in an outward direction from the central area CENTER. The first edge area TOP and the second edge area BOTTOM may be placed in opposite directions from the central area CENTER.

The first memory device 200B-2 may be disposed of in a left area LEFT of the first memory device 200B-2 in an X axis.

The second memory device 300B-2 may include the first to eighth channels CH1 to CH8, the third core TSV area 310B-2, and the fourth core TSV area 320B-2.

The third core TSV area 310B-2, and the fourth core TSV area 320B-2 may be arranged in the horizontal direction of the second memory device 300B-2.

The first to eighth channels CH1 to CH8 may receive the command CMD and the data DATA by independently performing internal operations. The first to eighth channels CH1 to CH8 may respectively store data DATA based on the command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the third core TSV area 310B-2. The first to fourth channels CH1 to CH4 may receive the command CMD and the data DATA from the third core TSV area 310B-2. The first to fourth channels CH1 to CH4 may output the data DATA to the third core TSV area 310B-2. The first to fourth channels CH1 to CH4 may respectively store data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B-2. The fifth to eighth channels CH5 to CH8 may receive a command CMD and data DATA from the fourth core TSV area 320B-2. The fifth to eighth channels CH5 to CH8 may output the data DATA to the fourth core TSV area 320B-2. The fifth to eighth channels CH5 to CH8 may respectively store data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to fourth channels CH1 to CH4 may be disposed in the central area CENTER of the second memory device 300B-2. The fifth to eighth channels CH5 to CH8 may be disposed in the second edge area BOTTOM of the second memory device 300B-2.

The third core TSV area 310B-2 may be electrically connected to the third base TSV area 123B-32 of the control device 100B-2. The third core TSV area 310B-2 may receive the command CMD and the data DATA from the third base TSV area 123B-32. The third core TSV area 310B-2 may receive the command CMD and the data DATA through a plurality of TSVs. The third core TSV area 310B-2 may output the command CMD and the data DATA to the first to fourth channels CH1 to CH4. The third core TSV area 310B-2 may receive the data DATA from the first to fourth channels CH1 to CH4 and output the data DATA to the third base TSV area 123B-32. The third core TSV area 310B-2 may be disposed in the first edge area TOP. The third core TSV area 310B-2 may be disposed in the first direction D1 from the central area center.

The fourth core TSV area 320B-2 may be electrically connected to the fourth base TSV area 124B-31 of the control device 100B-2. The fourth core TSV area 320B-2 may receive the command CMD and the data DATA from the fourth base TSV area 124B-32. The fourth core TSV area 320B-2 may receive the command CMD and the data DATA through a plurality of TSVs. The fourth core TSV area 320B-2 may output the command CMD and the data DATA to the fifth to eighth channels CH5 to CH8. The fourth core TSV area 320B-2 may receive the data DATA from the fifth to eighth channels CH5 to CH8 and output the data DATA to the fourth base TSV area 124B-32. The fourth core TSV area 320B-2 may be disposed in the central area CENTER. The fourth core TSV area 320B-2 may be disposed in the first direction D1 from the second edge area BOTTOM.

The second memory device 300B-2 may be disposed in the right area RIGHT in the X axis.

As described above, the semiconductor system 1B according to an embodiment of the present disclosure can increase the bandwidth because the first memory device 200B-2 and the second memory device 300B-2 are connected to the control device 100B-2 in common and input and output the data DATA. In an embodiment, the semiconductor system 1B can prevent or reduce heat from an area in which the command CMD and the data DATA are generated from being diffused to a memory device because a memory device (i.e., 200B-2, 300B-2) is not stacked above the area in which the command CMD and the data DATA are generated. Interfaces that are connected to the TSVs of the control device 100B, 100B-1, 100B-2 and the memory devices 200B, 200B-1, 200B-2, 300B, 300B-1, 300B-2 may be variously disposed in the semiconductor system 1B.

FIG. 17 illustrates a semiconductor device 3B according to an embodiment of the present disclosure. As illustrated in FIG. 17, the semiconductor device 3B may include a PCB 11B, a substrate 13B, an interposer 15B, an HBM device 17B, and the processor 19B.

The PCB 11B connects several electronic components in order to form an electronic circuit (not illustrated). A copper layer, a solder mask and a silk screen may be formed on the PCB 11B. A circuit path that transmits a signal or power may be formed in the copper layer. In an embodiment, the solder mask prevents or mitigates damage to the circuit and protects a specific area in which components may be soldered. Furthermore, in an embodiment, the silk screen indicates a position or information of an electronic component in the form of characters or symbols printed on a surface of the PCB 11B.

The substrate 13B is formed over the PCB 11B through bump pads (e.g., 115B), and may mechanically support the interposer 15B, the HBM device 17B, and the processor 19B. The substrate 13B may be used as an insulator as a material, that is, a physical base for the PCB 11B, in general. The material of the substrate 13B include FR4, that is, an insulator made of glass fiber and epoxy resin, ceramics that can withstand a high temperature and can be used in a high frequency circuit or a high temperature environment due to its thermal conductivity, and polyimide that is used as a base material for a flexible PCB due to its flexible characteristic.

The interposer 15B is formed over the substrate 13B through bump pads, and may include wires that connect electronic components (e.g., the HBM device 17B and the processor 19B) with unmatched foam factors or pin arrangements. The interposer 15B may convert signals in different interfaces.

The HBM device 17B may be formed over the interposer 15B to micro bump pads (e.g., 117B). The HBM device 17B may store data applied by the processor 19B or output data stored in the HBM device 17B to the processor 19B, under the control of the processor 19B. The HBM device 17B may include a control device 150B, a first memory device 160B, and a second memory device 170B. The first memory device 160B and the second memory device 170B may be stacked on the control device 150B through micro bump pads. The first memory device 160B and the second memory device 170B may respectively be implemented with a plurality of core chips that is vertically stacked through micro bump pads. The control device 150B and the first memory device 160B and the second memory device 170B may be vertically stacked through TSVs.

The control device 150B may generate the command CMD by receiving the external command EC from the processor 19B, and may generate the data DATA by receiving the external data ED from the processor 19B. The control device 150B may include the first area (110B, 110B-1, and 110B-2 illustrated in FIGS. 1, 2, 4, and 6) in which the command CMD and the data DATA are generated. The first area may be set as an area in which heat is generated when the command CMD and the data DATA are generated. The control device 150B may output the command CMD and the data DATA to the first memory device 160B and the second memory device 170B. The control device 150B may include the second area (120B, 120B-1, and 120B-2 illustrated in FIGS. 1, 2, 4, and 6) in which the command CMD and the data DATA are received from the first area and output to the first memory device 160B and the second memory device 170B. The memory device is not stacked on the first area. The first memory device 160B and the second memory device 170B may be disposed on the second area of the control device 150B.

The first memory device 160B and the second memory device 170B may respectively store data DATA by performing an internal operation and output the data DATA in their respective memory device based on the command CMD. The first memory device 160B and the second memory device 170B may respectively include the plurality of channels (CH1 to CH8 in FIGS. 3, 5, and 7) that independently operates. The plurality of channels (CH1 to CH8 in FIGS. 3, 5, and 7) may respectively store or output the data DATA by independently operating.

In an embodiment, the HBM device 17B can increase the bandwidth because the first memory device 160B and the second memory device 170B are connected to the control device 150B in common and input and output the data DATA. In an embodiment, the HBM device 17B can prevent or reduce heat from an area in which the command CMD and the data DATA are generated from being diffused to a memory device because the memory device is not stacked above the area in which the command CMD and the data DATA are generated. Interfaces that are connected to the TSVs of the control device 150B, the first memory device 160B, and the second memory device 170B may be various disposed of in the HBM device 17B.

The processor 19B may transmit the command CMD and the data DATA to the control device 150B through a wire formed within the interposer 15B, and may receive the data DATA from the control device 150B. The processor 19B may transmit various commands and signals that control internal operations of the control device 150B, the first memory device 160B, and the second memory device 170B, and may receive the results of the internal operations.

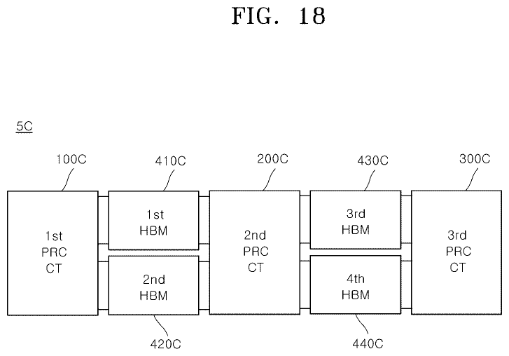

FIG. 18 is a block diagram illustrating a construction of semiconductor systems 5C according to an embodiment of the present disclosure. As illustrated in FIG. 18, the semiconductor system 5C may include a first process circuit (1st PRC CT) 100C, a second process circuit (2nd PRC CT) 200C, a third process circuit (3rd PRC CT) 300C, a first HBM device (1st HBM) 410C, a second HBM device (2nd HBM) 420C, a third HBM device (3rd HBM) 430C, and a fourth HBM device (4th HBM) 440C.

The first process circuit 100C may be electrically connected to the first HBM device 410C and the second HBM device 420C. The first process circuit 100C may be electrically connected to the first HBM device 410C and the second HBM device 420C through the interposer 15 illustrated in FIG. 17. The first process circuit 100C may control operations of the first HBM device 410C and the second HBM device 420C. The first process circuit 100C may perform an arithmetic operation by receiving data DATA from the first HBM device 410C and the second HBM device 420C.

The second process circuit 200C may be electrically connected to the first HBM device 410C and the second HBM device 420C. The second process circuit 200C may be electrically connected to the first HBM device 410C and the second HBM device 420C through the interposer 15 illustrated in FIG. 8. The second process circuit 200C may control operations of the first HBM device 410C and the second HBM device 420C. The second process circuit 200C may perform an arithmetic operation by receiving the data DATA from the first HBM device 410C and the second HBM device 420C. The second process circuit 200C may be electrically connected to the third HBM device 430C and the fourth HBM device 440C. The second process circuit 200C may be electrically connected to the third HBM device 430C and the fourth HBM device 440C through the interposer 15 illustrated in FIG. 17. The second process circuit 200C may control operations of the third HBM device 430C and the fourth HBM device 440C. The second process circuit 200C may perform an arithmetic operation by receiving data DATA from the third HBM device 430C and the fourth HBM device 440C. The second process circuit 200C may perform an arithmetic operation by receiving the data DATA from at least one of the first HBM device 410C, the second HBM device 420C, the third HBM device 430C, and the fourth HBM device 440C.

The third process circuit 300C may be electrically connected to the third HBM device 430C and the fourth HBM device 440C. The third process circuit 300C may be electrically connected to the third HBM device 430C and the fourth HBM device 440C through the interposer 15 illustrated in FIG. 17. The third process circuit 300C may control operations of the third HBM device 430C and the fourth HBM device 440C. The third process circuit 300C may perform an arithmetic operation by receiving the data DATA from the third HBM device 430C and the fourth HBM device 440C.

The first process circuit 100C, the second process circuit 200C, and the third process circuit 300C may respectively be implemented with a graphics processing unit (GPU) device and a neural processing unit (NPU) device.

The arithmetic operation may include a training operation and an inference operation. The training operation may be set as an operation of an artificial intelligence (AI) model learning a rule, a pattern, or a relation by optimizing weights and parameters from given data DATA. The inference operation may be set as an operation of an artificial intelligence (AI) model rapidly deriving results from new data by using weights learnt during the training operation.

The first HBM device 410C, the second HBM device 420C, the third HBM device 430C, and the fourth HBM device 440C may respectively include the control device 100B, the first memory device 200B, and the second memory device 300B illustrated in FIGS. 10 to 17. The first HBM device 410C, the second HBM device 420C, the third HBM device 430C, and the fourth HBM device 440C may respectively store data DATA and output the data DATA stored in the respective HBM device.

The physical area D2D PHY (111B, 111B-1, or 111B-2) illustrated in FIGS. 10, 11, 13, and 15 may be respectively disposed at the boundary of the first HBM device 410C, the second HBM device 420C, the third HBM device 430C, and the fourth HBM device 440C. The first HBM device 410C, the second HBM device 420C, the third HBM device 430C, and the fourth HBM device 440C may be electrically connected to the first process circuit 100C, the second process circuit 200C, and the third process circuit 300C through the physical area D2D PHY. The first HBM device 410C, the second HBM device 420C, the third HBM device 430C, and the fourth HBM device 440C may be shared by the first process circuit 100C, the second process circuit 200C, and the third process circuit 300C through the physical area D2D PHY.

The semiconductor system 5C according to an embodiment of the present disclosure has a plurality of HBM devices electrically connected to a plurality of process circuits, and can extend the capacity of data that is used in an arithmetic operation of the process circuit. The semiconductor system 5C has a plurality of HBM devices shared by a plurality of process circuits, and can extend the number of process circuits used in an arithmetic operation. The semiconductor system 5C can rapidly perform an arithmetic operation because a plurality of HBM devices is electrically connected to a plurality of process circuits to perform the arithmetic operation.

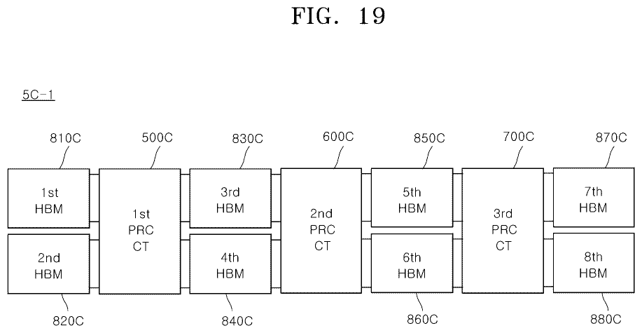

FIG. 19 is a block diagram illustrating a construction of a semiconductor system 5C-1 according to an embodiment of the present disclosure. As illustrated in FIG. 19, the semiconductor system 5C-1 may include a first process circuit (1st PRC CT) 500C, a second process circuit (2nd PRC CT) 600C, a third process circuit (3rd PRC CT) 700C, a first HBM device (1st HBM) 810C, a second HBM device (2nd HBM) 820C, a third HBM device (3rd HBM) 830C, a fourth HBM device (4th HBM) 840C, a fifth HBM device (5th HBM) 850C, a sixth HBM device (6th HBM) 860C, a seventh HBM device (7th HBM) 870C, and an eighth HBM Device (8th HBM) 880C.

The first process circuit 500C may be electrically connected to the first HBM device 810C and the second HBM device 820C. The first process circuit 500C may be electrically connected to the first HBM device 810C and the second HBM device 820C through the interposer 15 illustrated in FIG. 17. The first process circuit 500C may control operations of the first HBM device 810C and the second HBM device 820C. The first process circuit 500C may perform an arithmetic operation by receiving data DATA from the first HBM device 810C and the second HBM device 820C. The first process circuit 500C may be electrically connected to the third HBM device 830C and the fourth HBM device 840C. The first process circuit 500C may be electrically connected to the third HBM device 830C and the fourth HBM device 840C through the interposer 15 illustrated in FIG. 17. The first process circuit 500C may control operations of the third HBM device 830C and the fourth HBM device 840C. The first process circuit 500C may perform an arithmetic operation by receiving data DATA from the third HBM device 830C and the fourth HBM device 840C. The first process circuit 500C may perform an arithmetic operation by receiving the data DATA from at least any one of the first HBM device 810C, the second HBM device 820C, the third HBM device 830C, and the fourth HBM device 840C.

The second process circuit 600C may be electrically connected to the third HBM device 830C and the fourth HBM device 840C. The second process circuit 600C may be electrically connected to the third HBM device 830C and the fourth HBM device 840C through the interposer 15 illustrated in FIG. 17. The second process circuit 600C may control operations of the third HBM device 830C and the fourth HBM device 840C. The second process circuit 600C may perform an arithmetic operation by receiving the data DATA from the third HBM device 830C and the fourth HBM device 840C. The second process circuit 600C may be electrically connected to the fifth HBM device 850C and the sixth HBM device 860C. The second process circuit 600C may be electrically connected to the fifth HBM device 850C and the sixth HBM device 860C through the interposer 15 illustrated in FIG. 17. The second process circuit 600C may control operations of the fifth HBM device 850C and the sixth HBM device 860C. The second process circuit 600C may perform an arithmetic operation by receiving data DATA from the fifth HBM device 850C and the sixth HBM device 860C. The second process circuit 600C may perform an arithmetic operation by receiving the data DATA from at least any one of the third HBM device 830C, the fourth HBM device 840C, the fifth HBM device 850C, and the sixth HBM device 860C.

The third process circuit 700C may be electrically connected to the fifth HBM device 850C and the sixth HBM device 860C. The third process circuit 700C may be electrically connected to the fifth HBM device 850C and the sixth HBM device 860C through the interposer 15 illustrated in FIG. 17. The third process circuit 700C may control operations of the fifth HBM device 850C and the sixth HBM device 860C. The third process circuit 700C may perform an arithmetic operation by receiving the data DATA from the fifth HBM device 850C and the sixth HBM device 860C. The third process circuit 700C may be electrically connected to the seventh HBM device 870C and the eighth HBM device 880C. The third process circuit 700C may be electrically connected to the seventh HBM device 870C and the eighth HBM device 880C through the interposer 15 illustrated in FIG. 17. The third process circuit 700C may control operations of the seventh HBM device 870C and the eighth HBM device 880C. The third process circuit 700C may perform an arithmetic operation by receiving data DATA from the seventh HBM device 870C and the eighth HBM device 880C. The third process circuit 700C may perform an arithmetic operation by receiving the data DATA from at least any one of the fifth HBM device 850C, the sixth HBM device 860C, the seventh HBM device 870C, and the eighth HBM device 880C.

The first process circuit 500C, the second process circuit 600C, and the third process circuit 700C may respectively be implemented with a graphics processing unit (GPU) device and a neural processing unit (NPU) device.

The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may respectively include the control device 100B, the first memory device 200B, and the second memory device 300B illustrated in FIGS. 10 to 17. The first HBM device 810C, the second HBM device 820C, the third HBM device 830C, the fourth HBM device 840C, the fifth HBM device 850C, the sixth HBM device 860C, the seventh HBM device 870C,I and the eighth HBM device 880C may respectively store data DATA and output the data DATA stored in the respective HBM device.

The physical area D2D PHY (111B, 111B-1, or 111B-2) illustrated in FIGS. 10, 11, 13, and 15 may be respectively disposed at the boundary of the first HBM device 810C, the second HBM device 820C, the third HBM device 830C, the fourth HBM device 840C, the fifth HBM device 850C, the sixth HBM device 860C, the seventh HBM device 870C, and the eighth HBM device 880C. The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may be electrically connected to the first process circuit 500C, the second process circuit 600C, and the third process circuit 700C through the physical area D2D PHY. The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may be shared by the first process circuit 500C, the second process circuit 600C, and the third process circuit 700C through the physical area D2D PHY.

The semiconductor system 5C-1 according to an embodiment of the present disclosure has a plurality of HBM devices electrically connected to a plurality of process circuits, and can extend the capacity of data that is used in an arithmetic operation of the process circuit. The semiconductor system 5C-1 has a plurality of HBM devices shared by a plurality of process circuits, and can extend the number of process circuits used in an arithmetic operation. The semiconductor system 5C-1 can rapidly perform an arithmetic operation because a plurality of HBM devices is electrically connected to a plurality of process circuits to perform the arithmetic operation.

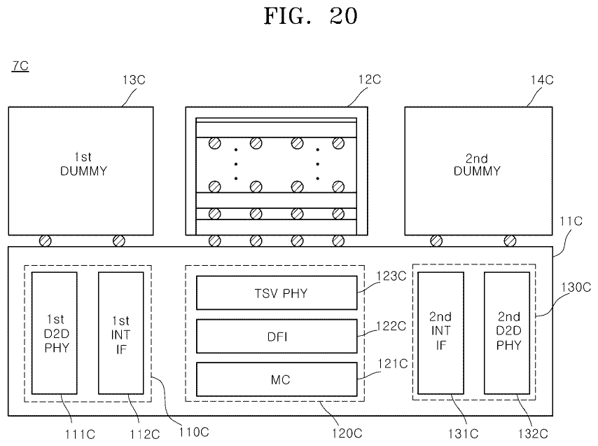

FIG. 20 is a block diagram illustrating a construction of an HBM device 7C according to an embodiment of the present disclosure. As illustrated in FIG. 20, the HBM device 7C may include a control device 11C, a memory device 12C, a first dummy die group (1st DUMMY) 13C, and a second dummy die group (2nd DUMMY) 14C.

The control device 11C may be implemented with the base die 111 of FIGS. 1 and 2. The control device 11C may be implemented with the base die 131 of FIG. 3. The control device 11C may be implemented with the base die 171 of FIG. 4.

The control device 11C may generate a command CMD and data DATA. The control device 11C may output the command CMD and the data DATA to the memory device 12C. The control device 11C may receive data DATA from the memory device 12C. The control device 11C may be implemented with a base chip, a controller, etc. that controls an operation of the memory device 12C.

The control device 11C may include a first area 110C, a second area 120C, and a third area 130C. An upper part of the first area 110C may be set as a first predetermined area. An upper part of the second area 120C may be set as a second predetermined area. An upper part of the third area 130C may be set as a third predetermined area. The first area 110C may be set as an area that generates a command CMD and data DATA and inputs and outputs the command CMD and the data DATA. Heat may be generated when the first area 110 inputs and outputs the command CMD and the data DATA. The second area 120C may be set as an area that receives the command CMD and the data DATA from the first area 110C and outputs the command CMD and the data DATA to the memory device 12C and that receives the data DATA from the memory device 12C and outputs the data DATA to the first area 110C and the third area 130C. The third area 130C may be set as an area that receives the command CMD and the data DATA and inputs and outputs the command CMD and the data DATA. The third area 130C may be set as an area that inputs and outputs the command CMD and the data DATA to and from another HBM device, a process circuit, or an external device. Heat may be generated when the third area 130C inputs and outputs the command CMD and the data DATA.

The first area 110C may include a first physical area (1st D2D PHY) 111C and a first internal interface area (1st INT IF) 112C.

The first physical area 111C may generate a command CMD and data DATA based on a signal that is received from the process circuit (PRC CT in FIGS. 18 and 19). The first physical area 111C may output the command CMD and the data DATA to the first internal interface area 112C. The first physical area 111C may receive the data DATA from the first internal interface area 112C and output the data DATA to the process circuit (PRC CT in FIGS. 18 and 19). The first physical area 111C may be implemented with a physical layer PHY that is responsible for the generation, transmission, reception, and physical connection of signals and data between an external device and the control device 11C.

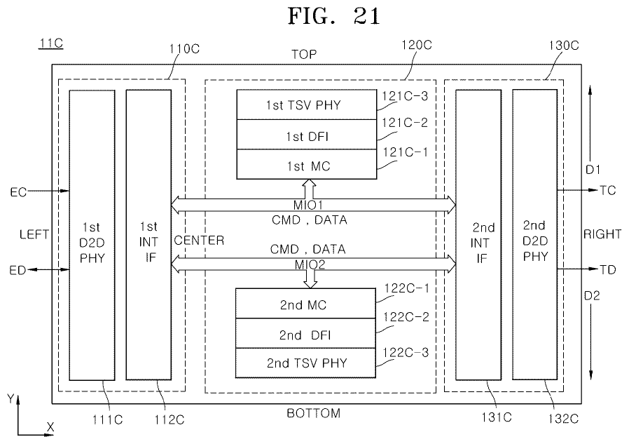

The first internal interface area 112C may receive the command CMD and the data DATA from the first physical area 111C. The first internal interface area 112C may output the command CMD and the data DATA to internal input and output lines (MIO1 and MIO2 in FIG. 21) by adjusting the input and output sequence of the command CMD and the data DATA. The first internal interface area 112C may receive the data DATA from the internal input and output lines (MIO1 and MIO2 in FIG. 21) and output the data DATA to the first physical area 111C. The first internal interface area 112C may output the command CMD and the data DATA to the second area 120C and the third area 130C by adjusting the input and output sequence of the command CMD and the data DATA. The first internal interface area 112C may be implemented with an interface that defines the timing and sequence of signals that are transmitted between the physical layer PHY and internal circuits and that inputs and outputs the signals. The first internal interface area 112C and the internal input and output lines (MIO1 and MIO2 in FIG. 21) may be implemented in a network-on-chip (NoC). The network-on-chip (NoC) may be set as a transmission path that connects several types of internal circuits within a chip. In an embodiment, the first internal interface area 112C may intersect with the internal input and output lines (MIO1 and MIO2) as shown in FIG. 21. The intersection of the input and output lines (MIO1 and MIO2) may intersect with the first internal interface area 112C forming an angle at the intersection. The angle at the intersection, for example, may be a right angle or substantially a right angle. As shown in FIG. 21 the input and output line MIO1 is substantially orthogonal to the first internal interface area 112C and the second internal interface area 131C. The angle at the intersection, for example, may be less than 90 degrees or greater than 90 degrees. In an embodiment, the second internal interface area 131C may intersect with the internal input and output lines (MIO1 and MIO2) as shown in FIG. 21. The intersection of the input and output lines (MIO1 and MIO2) may intersect with the second internal interface area 131C forming an angle at the intersection. The angle at the intersection, for example, may be a right angle or substantially a right angle. The angle at the intersection, for example, may be less than 90 degrees or greater than 90 degrees.

The second area 120C may include a memory controller (MC) 121C, a base interface area (DFI) 122C, and a base TSV area (TSV PHY) 123C.

The memory controller 121C may receive a command CMD and data DATA through the internal input and output lines (MIO1 and MIO2 in FIG. 21). The memory controller 121C may output the command CMD and the data DATA that control an operation of the memory device 12C to the base interface area 122C. The memory controller 121C may receive the data DATA from the base interface area 122C and output the data DATA to the internal input and output lines (MIO1 and MIO2 in FIG. 21).

The base interface area 122C may receive the command CMD and the data DATA from the memory controller 121C. The base interface area 122C may output the command CMD and the data DATA to the base TSV area 123C by adjusting the input and output sequence of the command CMD and the data DATA. The base interface area 122C may receive data DATA from the base TSV area 123C and output the data DATA to the memory controller 121C.

The base TSV area 123C may receive the command CMD and the data DATA from the base interface area 122C. The base TSV area 123C may output the command CMD and the data DATA to the memory device 12C through a plurality of TSVs. The base TSV area 123C may receive the data DATA from the memory device 12C and output the data DATA to the base interface area 122C.

The memory controller 121C, the base interface area 122C, and the base TSV area 123C may be disposed in the horizontal direction of the control device 11C of the control device 11C.

The third area 130C may include a second internal interface area (2nd INT IF) 131C and a second physical area (2nd D2D PHY) 132C.

The second internal interface area 131C may receive the command CMD and the data DATA from the internal input and output lines (MIO1 and MIO2 in FIG. 21). The second internal interface area 131C may output the command CMD and the data DATA to the second physical area 132C by adjusting the input and output sequence of the command CMD and the data DATA. The second internal interface area 131C may be implemented with an interface that defines the timing and sequence of signals that are transmitted between the physical layer PHY and internal circuits and that inputs and outputs the signals. The second internal interface area 131C may be implemented in a network-on-chip (NoC).

The second physical area 132C may receive the command CMD and the data DATA from the second internal interface area 131C. The second physical area 132C may output to the command CMD and the data DATA to another HBM device and the process circuit (PRC CT in FIGS. 18 and 19). The second physical area 132C may be implemented with a physical layer PHY that is responsible for the generation, transmission, reception, and physical connection of signals and data between the external device and the control device 11C.

The memory device 12C may include a plurality of core dies that is vertically stacked. The memory device 12C may be disposed in the second predetermined area. The memory device 12C may receive the command CMD and the data DATA from the base TSV area 123C. The memory device 12C may perform an internal operation based on the command CMD and the data DATA. The memory device 12C may store the data DATA in the plurality of core dies based on the command CMD after the start of a write operation. The memory device 12C may output the data DATA stored in the plurality of core dies to the base TSV area 123C based on the command CMD after the start of a read operation.

The first dummy die group 13C may be vertically stacked on the first area 110C of the control device 11C. The first dummy die group 13C may be disposed in the first predetermined area. The first dummy die group 13C may be implemented with a plurality of dummy dies (not illustrated) that is stacked. The first dummy die group 13C may have the same height as the memory device 12C. The plurality of dummy dies (not illustrated) included in the first dummy die group 13C may have the same height as the plurality of core dies (not illustrated) included in the memory device 12C. The first dummy die group 13C may be one dummy die according to an embodiment. The first predetermined area in which the first dummy die group 13C is formed may be an empty space according to an embodiment. The first dummy die group 13C may discharge heat that is generated from the first area 110C of the control device 11C. The plurality of dummy dies (not illustrated) included in the first dummy die group 13C may be connected through a plurality of TSVs through a plurality of micro bump pads, thus facilitating the discharge of heat.

The second dummy die group 14C may be vertically stacked on the third area 130C of the control device 11C. The second dummy die group 14C may be disposed in the third predetermined area. The second dummy die group 14C may be implemented with a plurality of dummy dies (not illustrated) that is stacked. The second dummy die group 14C may have the same height as the memory device 12C. The plurality of dummy dies (not illustrated) included in the second dummy die group 14C may have the same height as the plurality of core dies (not illustrated) included in the memory device 12C. The second dummy die group 14C may be one dummy die according to an embodiment. The third predetermined area in which the second dummy die group 14C is formed may be an empty space according to an embodiment. The second dummy die group 14C may discharge heat that is generated from the third area 130C of the control device 11C. The plurality of dummy dies (not illustrated) included in the second dummy die group 14C may be connected through a plurality of TSVs through a plurality of micro bump pads, thus facilitating the discharge of heat.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

FIG. 21 is a block diagram illustrating a construction of the control device 11C according to an embodiment of the present disclosure. As illustrated in FIG. 21, the control device 11C may include the first area 110C, the second area 120C, and the third area 130C.

The first area 110C may include the first physical area 111C and the first internal interface area 112C.

The first physical area 111C may generate the command CMD by receiving an external command EC from the process circuit (PRC CT in FIGS. 18 and 19). The first physical area 111C may generate the command CMD by buffering or decoding the external command EC. The external command EC and the command CMD are each illustrated as only one signal, but may respectively include a plurality of bits. The first physical area 111C may generate the data DATA by receiving external data ED from the process circuit (PRC CT in FIGS. 18 and 19). The first physical area 111C may generate the external data ED by receiving data DATA from the first internal interface area 112C. The first physical area 111C may output the external data ED to the process circuit (PRC CT in FIGS. 18 and 19). The external data ED and the data DATA are each illustrated as only one signal, but may respectively include a plurality of bits.

The first internal interface area 112C may receive the command CMD and the data DATA from the first physical area 111C. The first internal interface area 112C may output the command CMD and the data DATA that control an operation of the memory device 12C to the first internal input and output line MIO1 by adjusting the input and output sequence of the command CMD and the data DATA. The first internal interface area 112C may output the command CMD and the data DATA that control an operation of the memory device 12C to the second internal input and output line MIO2 by adjusting the input and output sequence of the command CMD and the data DATA. The first internal input and output line MIO1 and the second internal input and output line MIO2 may be disposed in a central area CENTER of the control device 11C. The first internal interface area 112C, the first internal input and output line MIO1, and the second internal input and output line MIO2 may be implemented in a network-on-chip (NoC).

The first area 110C may be set as an area that generates a command CMD and data DATA and inputs and outputs the command CMD and the data DATA. Heat may be generated when the first area 110C inputs and outputs the command CMD and the data DATA. The first area 110C may be disposed in a left area LEFT of the control device 11C in an X axis.

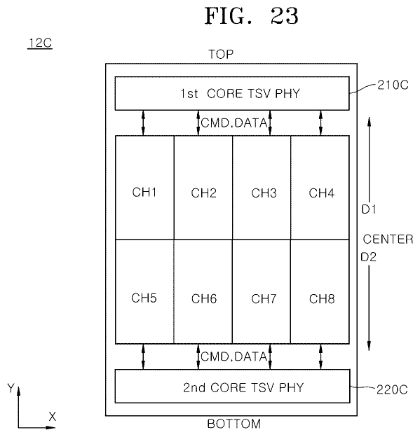

The second area 120C may include a first memory controller (1st MC) 121C-1, a first base interface area (1st DFI) 121C-2, a first base TSV area (1st TSV PHY) 121C-3, a second memory controller (2nd MC) 122C-1, a second base interface area (2nd DFI) 122C-2, and a second base TSV area (2nd TSV PHY) 122C-3 that control an operation of the memory device 12C. The first memory controller 121C-1, the first base interface area 121C-2, and the first base TSV area 121C-3 may be components that control an operation of a first group of channels (CH1 to CH4 in FIG. 23) included in the memory device 12C. The second memory controller 122C-1, the second base interface area 122C-2, and the second base TSV area 122C-3 may be components that control an operation of a second group of channels (CH5 to CH8 in FIG. 23) included in the memory device 12C. The first memory controller 121C-1, the first base interface area 121C-2, and the first base TSV area 121C-3, and the second memory controller 122C-1, the second base interface area 122C-2, and the second base TSV area 122C-3 may be implemented, respectively, with the memory controller 121C-1, the base interface area 122C, and the base TSV area 123C illustrated in FIG. 20.

The first memory controller 121C-1, the first base interface area 121C-2, and the first base TSV area 121C-3, and the second memory controller 122C-1, the second base interface area 122C-2, and the second base TSV area 122C-3 may be disposed in the horizontal direction of the control device 11C.

The first memory controller 121C-1 may be electrically connected to the first internal input and output line MIO1. The first memory controller 121C-1 may receive the command CMD and the data DATA that control an operation of the first group of channels (CH1 to CH4 in FIG. 23) included in the memory device 12C through the first internal input and output line MIO1. The first memory controller 121C-1 may output the command CMD and the data DATA that control an operation of the first group of channels (CH1 to CH4 in FIG. 23) included in the memory device 12C. The first memory controller 121C-1 may receive the data DATA from the first base interface area 121C-2 and output the data DATA to the first internal input and output line MIO1.

The first base interface area 121C-2 may be electrically connected to the first memory controller 121C-1. The first base interface area 121C-2 may receive the command CMD and the data DATA from the first memory controller 121C-1. The first base interface area 121C-2 may output the command CMD and the data DATA to the first base TSV area 121C-3 by adjusting the input and output sequence of the command CMD and the data DATA. The first base interface area 121C-2 may receive the data DATA from the first base TSV area 121C-3 and output the data DATA to the first memory controller 121C-1.

The first base TSV area 121C-3 may be electrically connected to the first base interface area 121C-2. The first base TSV area 121C-3 may receive the command CMD and the data DATA from the first base interface area 121C-2. The first base TSV area 121C-3 may output the command CMD and the data DATA to a first core TSV area (1st CORE TSV PHY) (210C in FIG. 23) included in the memory device 12C through a plurality of TSVs. The first base TSV area 121C-3 may receive the data DATA from the memory device 12C and output the data DATA to the first base interface area 121C-2.

The first memory controller 121C-1, the first base interface area 121C-2, and the first base TSV area 121C-3 may be sequentially disposed in a first direction D1 from the central area CENTER of the control device 11C. The first direction D1 may be set as a direction from the central area CENTER to a first edge area TOP. The first edge area TOP may be set as an upper area of the control device 11C in a Y axis.

The second memory controller 122C-1 may be electrically connected to the second internal input and output line MIO2. The second memory controller 122C-1 may receive the command CMD and the data DATA that control an operation of the second group of channels (CH5 to CH8 in FIG. 23) included in the memory device 12C through the second internal input and output line MIO2. The second memory controller 122C-1 may output the command CMD and the data DATA that control an operation of the second group of channels (CH5 to CH8 in FIG. 23) included in the memory device 12C. The second memory controller 122C-1 may receive the data DATA from the second base interface area 122C-2 and output the data DATA to the second internal input and output line MIO2.

The second base interface area 122C-2 may be electrically connected to the second memory controller 122C-1. The second base interface area 122C-2 may receive the command CMD and the data DATA from the second memory controller 122C-1. The second base interface area 122C-2 may output the command CMD and the data DATA to the second base TSV area 122C-3 by adjusting the input and output sequence of the command CMD and the data DATA. The second base interface area 122C-2 may receive the data DATA from the second base TSV area 122C-3 and output the data DATA to the second memory controller 121C-2.

The second base TSV area 122C-3 may be electrically connected to the second base interface area 122C-2. The second base TSV area 122C-3 may receive the command CMD and the data DATA from the second base interface area 122C-2. The second base TSV area 122C-3 may output the command CMD and the data DATA to a second core TSV area (220C in FIG. 23) included in the memory device 12C through a plurality of TSVs. The second base TSV area 122C-3 may receive the data DATA from the memory device 12C and output the data DATA to the second base interface area 122C-2.

The second memory controller 122C-1, the second base interface area 122C-2, and the second base TSV area 122C-3 may be sequentially disposed in a second direction D2 from the central area CENTER of the control device 11C. The second direction D2 may be set as a direction from the central area CENTER to a second edge area BOTTOM. The second edge area BOTTOM may be set as a lower area of the control device 11C in the Y axis.

The second area 120C may be set as an area that receives the command CMD and the data DATA from the first area 110C and outputs the command CMD and the data DATA to the memory device 12C. The second area 120C may be disposed in the central area CENTER of the control device 11C in the X axis.

The third area 130C may include the second internal interface area 131C and the second physical area 132C.

The second internal interface area 131C may receive the command CMD and the data DATA from the first internal input and output line MIO1. The second internal interface area 131C may output the command CMD and the data DATA received through the first internal input and output line MIO1 to the second physical area 132C by adjusting the input and output sequence of the command CMD and the data DATA. The second internal interface area 131C may receive the command CMD and the data DATA from the second internal input and output line MIO2. The second internal interface area 131C may output the command CMD and the data DATA received through the second internal input and output line MIO2 to the second physical area 132C by adjusting the input and output sequence of the command CMD and the data DATA. The second internal interface area 131C may be implemented in a network-on-chip (NoC).

The second physical area 132C may receive the command CMD and the data DATA from the second internal interface area 131C. The second physical area 132C may output the command CMD that is received as a transfer command TC. The second physical area 132C may output the data DATA that are received as transfer data TD. The second physical area 132C may output the transfer command TC and the transfer data TD to another HBM device and the process circuit (PRC CT in FIGS. 18 and 19).

The third area 130C may be set as an area that receives the command CMD and the data DATA from the second area 120C. The third area 130C may be set as an area that inputs and outputs the transfer command TC and the transfer data TD that are generated from the command CMD and the data DATA that are received. The third area 130C may be set as an area that inputs and outputs the command CMD and the data DATA to and from another HBM device, a process circuit, or an external device. The third area 130C may be disposed in a right area RIGHT of the control device 11C in the X axis.

In FIG. 21, the first internal interface area 112C, the second internal interface area 131C, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C in the X axis direction are disposed between the first internal interface area 112C and the second internal interface area 131C that are implemented in the longitudinal direction of the control device 11C in the Y axis direction.

In the first form, the first memory controller 121C-1, the first base interface area 121C-2, and the first base TSV area 121C-3 may be sequentially disposed in the first direction D1 from the central area CENTER in which the first internal input and output line MIO1 is disposed. In the first form, the second memory controller 122C-1, the second base interface area 122C-2, and the second base TSV area 122C-3 may be sequentially disposed in the second direction D2 from the central area CENTER in which the second internal input and output line MIO2 is disposed.

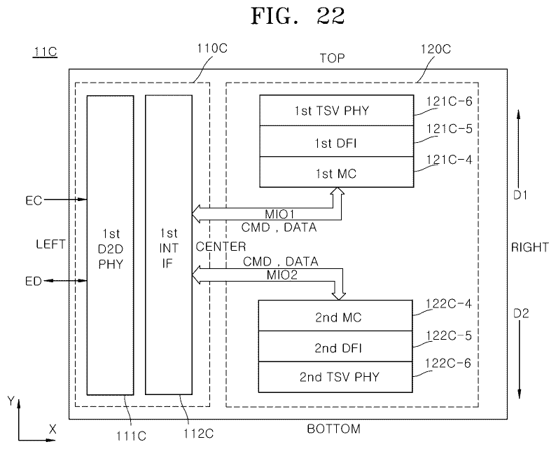

FIG. 22 is a block diagram illustrating a construction of the control device 11C according to an embodiment of the present disclosure. As illustrated in FIG. 22, the control device 11C may include the first area 110C and the second area 120C.

The first area 110C may include the first physical area 111C and the first internal interface area 112C.

The first physical area 111C and the first internal interface area 112C have the same constructions as the first physical area 111C and the first internal interface area 112C illustrated in FIG. 21, and thus detailed descriptions thereof are omitted.

The first internal input and output line MIO1 illustrated in FIG. 22 is connected between the first internal interface area 112C and the first memory controller 121C-4 differently from the first internal input and output line MIO1 illustrated in FIG. 21, and may input and output a command CMD and data DATA. The second internal input and output line MIO2 illustrated in FIG. 22 is connected between the first internal interface area 112C and the second memory controller 122C-4 differently from the second internal input and output line MIO2 illustrated in FIG. 21, and may input and output a command CMD and data DATA. The first internal input and output line MIO1 and the second internal input and output line MIO2 may respectively be implemented with a network-on-chip (NoC).

The first area 110C may be set as an area that generates a command CMD and data DATA and inputs and outputs the command CMD and the data DATA. Heat may be generated when the first area 110C inputs and outputs the command CMD and the data DATA. The first area 110C may be disposed in a left area LEFT of the control device 11C in an X axis.

The second area 120C may include a first memory controller (1st MC) 121C-4, a first base interface area (1st DFI) 121C-5, a first base TSV area (1st TSV PHY) 121C-6, a second memory controller (2nd MC) 122C-4, a second base interface area (2nd DFI) 122C-5, and a second base TSV area (2nd TSV PHY) 122C-6 that control an operation of the memory device 12C.

The first memory controller 121C-4, the first base interface area 121C-5, the first base TSV area 121C-6, the second memory controller 122C-4, the second base interface area 122C-5, and the second base TSV area 122C-6 have the same constructions as the first memory controller 121C-1, the first base interface area 121C-2, the first base TSV area 121C-3, the second memory controller 122C-1, the second base interface area 122C-2, and the second base TSV area 122C-3 illustrated in FIG. 21, and thus detailed descriptions thereof are omitted.

The second area 120C may be set as an area that receives the command CMD and the data DATA from the first area 110C and outputs the command CMD and the data DATA to the memory device 12C. The second area 120C may be disposed in a right area RIGHT of the control device 11C in the X axis.

In FIG. 22, the first internal interface area 112C, the first internal input and output lines MIO1, and the second internal input and output line MIO2 that are implemented in the network-on-chip (NoC) may be implemented in a second form. The second form means a form in which the first internal interface area 112C that is implemented in the longitudinal direction of the control device 11C in a Y axis direction and the first internal input and output line MIO1 and the second internal input and output line MIO2 that are implemented in the transverse direction of the control device 11C in the X axis direction are disposed.

In the second form, the first memory controller 121C-4, the first base interface area 121C-5 and the first base TSV area 121C-6 may be sequentially disposed in the first direction D1 from a central area CENTER in which the first internal input and output line MIO1 are disposed. In the second form, the second memory controller 122C-4, the second base interface area 122C-5, and the second base TSV area 122C-6 may be sequentially disposed in a second direction D2 from the central area CENTER in which the second internal input and output line MIO2 is disposed.

FIG. 23 is a block diagram illustrating a construction of the memory device 12C according to an embodiment of the present disclosure.

The memory device 12C may include the first to eighth channels CH1 to CH8, the first core TSV area 210C, and the second core TSV area 220C.

The first to eighth channels CH1 to CH8 may receive the command CMD and the data DATA by independently performing internal operations. The first to eighth channels CH1 to CH8 may respectively store data DATA based on a command CMD after the start of a write operation of an internal operation. The first to eighth channels CH1 to CH8 may respectively output the data DATA based on the command CMD after the start of a read operation of an internal operation.

The first to fourth channels CH1 to CH4 may be electrically connected to the first core TSV area 210C. The first to fourth channels CH1 to CH4 may receive the command CMD and the data DATA from the first core TSV area 210C. The first to fourth channels CH1 to CH4 may output the data DATA to the first core TSV area 210C. The first to fourth channels CH1 to CH4 may respectively store data DATA based on a command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C. The fifth to eighth channels CH5 to CH8 may receive a command CMD and data DATA from the second core TSV area 220C. The fifth to eighth channels CH5 to CH8 may output the data DATA to the second core TSV area 220C. The fifth to eighth channels CH5 to CH8 may respectively store data DATA based on a command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the memory device 12C. The fifth to eighth channels CH5 to CH8 may be disposed in the central area CENTER of the memory device 12C.

The first core TSV area 210C may be electrically connected to the first base TSV area 121C-3, 121C-6 of the control device 11C. The first core TSV area 210C may receive the command CMD and the data DATA from the first base TSV area 121C-3, 121C-6. The first core TSV area 210C may receive the command CMD and the data DATA through a plurality of TSVs. The first core TSV area 210C may output the command CMD and the data DATA to the first to fourth channels CH1 to CH4. The first core TSV area 210 may receive the data DATA from the first to fourth channels CH1 to CH4 and output the data DATA to the first base TSV area 121C-3, 121C-6. The first core TSV area 210C may be disposed in a first direction D1 from the central area CENTER. The first direction D1 may be set as a direction from the central area CENTER to a first edge area TOP. The first edge area TOP may be set as an upper area of the memory device 12C in a Y axis.

The second core TSV area 220C may be electrically connected to the second base TSV area 122C-3, 122C-6 of the control device 11C. The second core TSV area 220C may receive the command CMD and the data DATA from the second base TSV area 122C-3, 122C-6. The second core TSV area 220C may receive the command CMD and the data DATA through a plurality of TSVs. The second core TSV area 220C may output the command CMD and the data DATA to the fifth to eighth channels CH5 to CH8. The second core TSV area 220C may receive the data DATA from the fifth to eighth channels CH5 to CH8 and output the data DATA to the second base TSV area 122C-3, 122C-6. The second core TSV area 220C may be disposed in a second direction D2 from the central area CENTER. The second direction D2 may be set as a direction from the central area CENTER to a second edge area BOTTOM. The second edge area BOTTOM may be set as a lower area of the memory device 12C in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

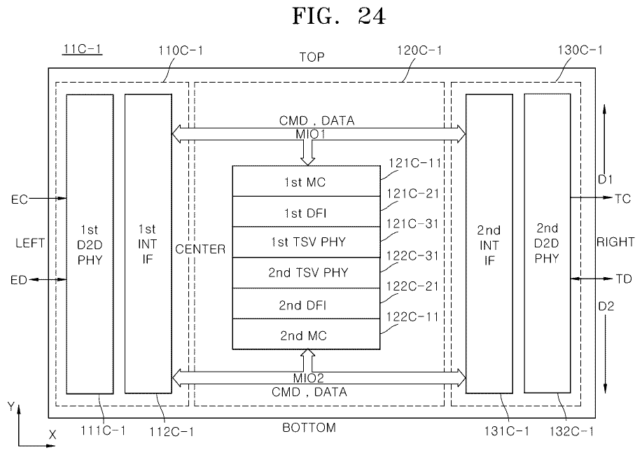

FIG. 24 is a block diagram illustrating a construction of a control device 11C-1 according to an embodiment of the present disclosure. As illustrated in FIG. 24, the control device 11C-1 may include a first area 110C-1, a second area 120C-1, and a third area 130C-1.

The first area 110C-1 may include a first physical area (1st D2D PHY) 111C-1 and a first internal interface area (1st INT IF) 112C-1.

The first physical area 111C-1 may generate a command CMD by receiving an external command EC from the process circuit (PRC CT in FIGS. 18 and 19). The first physical area 111C-1 may generate the command CMD by buffering or decoding the external command EC. The external command EC and the command CMD are respectively illustrated as only one signal, but may respectively include a plurality of bits. The first physical area 111C-1 may generate data DATA by receiving external data ED from the process circuit (PRC CT in FIGS. 18 and 19). The first physical area 111C-1 may generate the external data ED by receiving data DATA from the first internal interface area 112C-1. The first physical area 111C-1 may output the external data ED to the process circuit (PRC CT in FIGS. 18 and 19). The external data ED and the data DATA are each illustrated as only one signal, but may respectively include a plurality of bits.

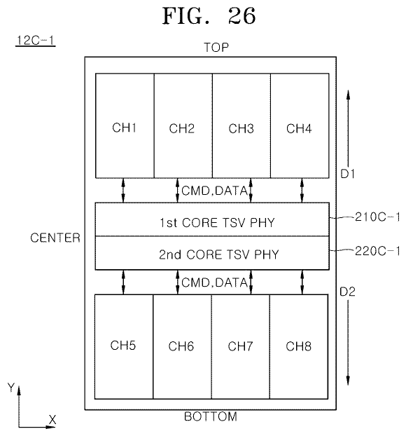

The first internal interface area 112C-1 may receive the command CMD and the data DATA from the first physical area 111C-1. The first internal interface area 112C-1 may output command CMD and the data DATA that control an operation of the memory device (12C-1 in FIG. 26) to a first internal input and output line MIO1 by adjusting the input and output sequence of the command CMD and the data DATA. The first internal interface area 112C-1 may output the command CMD and the data DATA that control an operation of the memory device (12C-1 in FIG. 26) to a second internal input and output line MIO2 by adjusting the input and output sequence of the command CMD and the data DATA. The first internal input and output line MIO1 may be disposed in a first edge area TOP of the control device 11C-1. The second internal input and output line MIO2 may be disposed in a second edge area BOTTOM of the control device 11C-1. The first internal interface area 112C-1, the first internal input and output line MIO1, and the second internal input and output line MIO2 may be implemented in a network-on-chip (NoC).

The first area 110C-1 may be set as an area that generates a command CMD and data DATA and inputs and outputs the command CMD and the data DATA. Heat may be generated when the first area 110C-1 inputs and outputs the command CMD and the data DATA. The first area 110C-1 may be disposed in a left area LEFT of the control device 11C-1 in a X axis.

The second area 120C-1 may include a first memory controller (1st MC) 121C-11, a first base interface area (1st DFI) 121C-21, a first base TSV area (1st TSV PHY) 121C-31, a second memory controller (2nd MC) 122C-11, a second base interface area (2nd DFI) 122C-21, and a second base TSV area (2nd TSV PHY) 122C-31 that control an operation of the memory device 12C. The first memory controller 121C-11, the first base interface area 121C-21, and the first base TSV area 121C-31 may be components that control an operation of a first group of channels (CH1 to CH4 in FIG. 24) included in a memory device (12C-1 in FIG. 26). The second memory controller 122C-11, the second base interface area 122C-21, and the second base TSV area 122C-31 may be components that control an operation of a second group of channels (CH5 to CH8 in FIG. 26) included in the memory device (12C-1 in FIG. 26). The first memory controller 121C-11, the first base interface area 121C-21, and the first base TSV area 121C-31, and the second memory controller 122C-11, the second base interface area 122C-21, and the second base TSV area 122C-31 may be implemented, respectively, with the memory controller 121C, the base interface area 122C, and the base TSV area 123C illustrated in FIG. 20.

The first memory controller 121C-11, the first base interface area 121C-21, the first base TSV area 121C-31, the second memory controller 122C-11, the second base interface area 122C-21, and the second base TSV area 122C-31 may be disposed in the horizontal direction of the control device 11C-1.

The first memory controller 121C-11 may be electrically connected to the first internal input and output line MIO1. The first memory controller 121C-11 may receive the command CMD and the data DATA that control an operation of the first group of channels (CH1 to CH4 in FIG. 26) included in the memory device (12C-1 in FIG. 26) through the first internal input and output line MIO1. The first memory controller 121C-11 may output the command CMD and the data DATA that control an operation of the first group of channels (CH1 to CH4 in FIG. 26) included in the memory device (12C-1 in FIG. 26). The first memory controller 121C-11 may the data DATA from the first base interface area 121C-21 and output the data DATA to the first internal input and output line MIO1.

The first base interface area 121C-21 may be electrically connected to the first memory controller 121C-11. The first base interface area 121C-21 may receive the command CMD and the data DATA from the first memory controller 121C-11. The first base interface area 121C-21 may output the command CMD and the data DATA to the first base TSV area 121C-31 by adjusting the input and output sequence of the command CMD and the data DATA. The first base interface area 121C-21 may receive the data DATA from the first base TSV area 121C-31 and output the data DATA to the first memory controller 121C-11.

The first base TSV area 121C-31 may be electrically connected to the first base interface area 121C-21. The first base TSV area 121C-31 may receive the command CMD and the data DATA from the first base interface area 121C-21. The first base TSV area 121C-31 may output the command CMD and the data DATA to a first core TSV area (210C-1 in FIG. 26) included in the memory device (12C-1 in FIG. 26) through a plurality of TSVs. The first base TSV area 121C-31 may receive data DATA from the memory device (12C-1 in FIG. 26) and output the data DATA to the first base interface area 121C-21.

The first memory controller 121C-11, the first base interface area 121C-21, and the first base TSV area 121C-31 may be sequentially disposed in a second direction D2 from the first edge area TOP of the control device 11C-1. The second direction D2 may be set as a direction from the first edge area TOP to the central area CENTER. The first edge area TOP may be set as an upper area of the control device 11C-1 in a Y axis.

The second memory controller 122C-11 may be electrically connected to the second internal input and output line MIO2. The second memory controller 122C-11 may receive the command CMD and the data DATA that control an operation of the second group of channels (CH5 to CH8 in FIG. 24) included in the memory device (12C-1 in FIG. 26) through the second internal input and output line MIO2. The second memory controller 122C-11 may output the command CMD and the data DATA that control an operation of the second group of channels (CH5 to CH8 in FIG. 26) included in the memory device (12C-1 in FIG. 24). The second memory controller 122C-11 may receive the data DATA from the second base interface area 122C-21 and output the data DATA to the second internal input and output line MIO2.

The second base interface area 122C-21 may be electrically connected to the second memory controller 122C-11. The second base interface area 122C-21 may receive the command CMD and the data DATA from the second memory controller 122C-11. The second base interface area 122C-21 may output the command CMD and the data DATA to the second base TSV area 122C-31 by adjusting the input and output sequence of the command CMD and the data DATA. The second base interface area 122C-21 may receive the data DATA from the second base TSV area 122C-31 and output the data DATA to the second memory controller 121C-21.

The second base TSV area 122C-31 may be electrically connected to the second base interface area 122C-21. The second base TSV area 122C-31 may receive the command CMD and the data DATA from the second base interface area 122C-21. The second base TSV area 122C-31 may output the command CMD and the data DATA to a second core TSV area (220C-1 in FIG. 26) included in the memory device (12C-1 in FIG. 26) through a plurality of TSVs. The second base TSV area 122C-31 may receive the data DATA from the memory device (12C-1 in FIG. 26) and output the data DATA to the second base interface area 122C-21.

The second memory controller 122C-11, the second base interface area 122C-21, and the second base TSV area 122C-31 may be sequentially disposed in a first direction D1 from the second edge area BOTTOM of the control device 11C-1. The first direction D1 may be set as a direction from the second edge area BOTTOM to the central area CENTER. The second edge area BOTTOM may be set as a lower area of the control device 11C-1 in a Y axis.

The second area 120C-1 may be set as an area that receives the command CMD and the data DATA from the first area 110C-1 and outputs the command CMD and the data DATA to the memory device (12C-1 in FIG. 26). The second area 120C-1 may be disposed in the central area CENTER of the control device 11C-1 in the X axis.

The third area 130C-1 may include a second internal interface area (2nd INT IF) 131C-1 and a second physical area (2nd D2D PHY) 132C-1.

The second internal interface area 131C-1 may receive the command CMD and the data DATA from the first internal input and output line MIO1. The second internal interface area 131C-1 may output the command CMD and the data DATA received through the first internal input and output line MIO1 to the second physical area 132C-1 by adjusting the input and output sequence of the command CMD and the data DATA. The second internal interface area 131C-1 may receive the command CMD and the data DATA from the second internal input and output line MIO2. The second internal interface area 131C-1 may output the command CMD and the data DATA received through the second internal input and output line MIO2 to the second physical area 132C-1 by adjusting the input and output sequence of the command CMD and the data DATA. The second internal interface area 131C-1 may be implemented in a network-on-chip (NoC).

The second physical area 132C-1 may receive the command CMD and the data DATA from the second internal interface area 131C-1. The second physical area 132C-1 may output the command CMD that is received as a transfer command TC. The second physical area 132C-1 may output the data DATA that are received as transfer data TD. The second physical area 132C-1 may output the transfer command TC and the transfer data TD to another HBM device and the process circuit (PRC CT in FIGS. 18 and 19).

The third area 130C-1 may be set as an area that receives the command CMD and the data DATA from the second area 120C-1. The third area 130C-1 may be set as an area that inputs and outputs the transfer command TC and the transfer data TD that are generated from the command CMD and the data DATA that are received. The third area 130C-1 may be set as an area that inputs and outputs the command CMD and the data DATA to and from another HBM device, a process circuit, or an external device. The third area 130C-1 may be disposed in a right area RIGHT of the control device 11C-1 in the X axis.

In FIG. 24, the first internal interface area 112C-1, the second internal interface area 131C-1, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C-1 in the X axis direction are disposed between the first internal interface area 112C-1 and the second internal interface area 131C-1 that are implemented in the longitudinal direction of the control device 11C-1 in the Y axis direction.

In the first form, the first memory controller 121C-11, the first base interface area 121C-21, and the first base TSV area 121C-31 may be sequentially disposed in the second direction D2 from the first edge area TOP in which the first internal input and output line MIO1 are disposed. In the first form, the second memory controller 122C-11, the second base interface area 122C-21, and the second base TSV area 122C-31 may be sequentially disposed in the first direction D1 from the second edge area BOTTOM in which the second internal input and output line MIO2 is disposed.

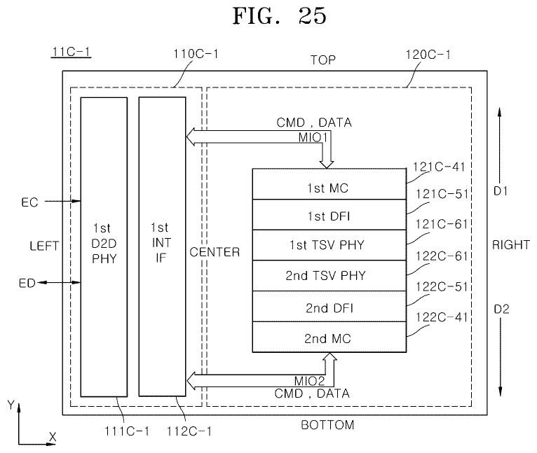

FIG. 25 is a block diagram illustrating a construction of the control device 11C according to an embodiment of the present disclosure. As illustrated in FIG. 25, the control device 11C-1 may include a first area 110C-1 and a second area 120C-1.

The first area 110C-1 may include a first physical area (1st D2D PHY) 111C-1 and a first internal interface area (1st INT IF) 112C-1.

The first physical area 111C-1 and the first internal interface area 112C-1 have the same constructions as the first physical area 111C-1 and the first internal interface area 112C-1 illustrated in FIG. 24, and thus detailed descriptions thereof are omitted.

A first internal input and output line MIO1 illustrated in FIG. 25 is connected between the first internal interface area 112C-1 and a first memory controller (1st MC) 121C-41 differently from the first internal input and output line MIO1 illustrated in FIG. 24, and may input and output a command CMD and data DATA. A second internal input and output line MIO2 illustrated in FIG. 25 is connected between the first internal interface area 112C-1 and a second memory controller (2nd MC) 122C-41 differently from the second internal input and output line MIO2 illustrated in FIG. 24, and may input and output a command CMD and data DATA. The first internal interface area 112C-1, the first internal input and output line MIO1, and the second internal input and output line MIO2 may be implemented in a network-on-chip (NoC).

The first area 110C-1 may be set as an area that generates a command CMD and data DATA and inputs and outputs the command CMD and the data DATA. Heat may be generated when the first area 110C-1 inputs and outputs the command CMD and the data DATA. The first area 110C-1 may be disposed in a left area LEFT of the control device 11C-1 in an X axis.

The second area 120C-1 may include the first memory controller 121C-41, a first base interface area (1st DFI) 121C-51, a first base TSV area (1st TSV PHY) 121C-61, the second memory controller 122C-41, a second base interface area (2nd DFI) 122C-51, and a second base TSV area (2nd TSV PHY) 122C-61 that control an operation of the memory device 12C-1.

The first memory controller 121C-41, the first base interface area 121C-51, the first base TSV area 121C-61, the second memory controller 122C-41, the second base interface area 122C-51, and the second base TSV area 122C-61 have the same constructions as the first memory controller 121C-11, the first base interface area 121C-21, the first base TSV area 121C-31, the second memory controller 122C-11, the second base interface area 122C-21, and the second base TSV area 122C-31 illustrated in FIG. 24, and thus detailed descriptions thereof are omitted.

The second area 120C-1 may be set as an area that receives the command CMD and the data DATA from the first area 110C-1 and outputs the command CMD and the data DATA to the memory device 12C-1. The second area 120C-1 may be disposed in a right area RIGHT of the control device 11C-1 in the X axis.

The first internal interface area 112C-1, the first internal input and output line MIO1, and the second internal input and output line MIO2 that are implemented in the network-on-chip (NoC) illustrated in FIG. 25 may be implemented in a second form. The second form means a form in which the first internal interface area 112C-1 that is implemented in the longitudinal direction of the control device 11C-1 in a Y axis direction and the first internal input and output line MIO1 and the second internal input and output line MIO2 that are implemented in the transverse direction of the control device 11C-1 in the X axis direction are disposed.

In the second form, the first memory controller 121C-41, the first base interface area 121C-51, and the first base TSV area 121C-61 may be sequentially disposed in a second direction D2 from a first edge area TOP in which the first internal input and output line MIO1 is disposed. In the second form, the second memory controller 122C-41, the second base interface area 122C-51, and the second base TSV area 122C-61 may be sequentially disposed in a first direction D1 from a second edge area BOTTOM in which the second internal input and output line MIO2 is disposed.

FIG. 26 is a block diagram illustrating a construction of the memory device 12C-1 according to an embodiment of the present disclosure.

The memory device 12C-1 may include the first to eighth channels CH1 to CH8, the first core TSV area 210C-1, and the second core TSV area 220C-1.

The first to eighth channels CH1 to CH8 may receive a command CMD and data DATA by independently performing internal operations. The first to eighth channels CH1 to CH8 may respectively store data DATA based on a command CMD after the start of a write operation of an internal operation. The first to eighth channels CH1 to CH8 may respectively output the data DATA after the start of a read operation of an internal operation based on the command CMD.

The first to fourth channels CH1 to CH4 may be electrically connected to the first core TSV area 210C-1. The first to fourth channels CH1 to CH4 may receive the command CMD and the data DATA from the first core TSV area 210C-1. The first to fourth channels CH1 to CH4 may output the data DATA to the first core TSV area 210C-1. The first to fourth channels CH1 to CH4 may respectively store the data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C-1. The fifth to eighth channels CH5 to CH8 may receive a command CMD and data DATA from the second core TSV area 220C-1. The fifth to eighth channels CH5 to CH8 may output the data DATA to the second core TSV area 220C-1. The fifth to eighth channels CH5 to CH8 may respectively store the data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as a second group of channels.

The first to fourth channels CH1 to CH4 may be disposed in a first edge area TOP of the memory device 12C-1. The fifth to eighth channels CH5 to CH8 may be disposed in a second edge area BOTTOM of the memory device 12C.

The first core TSV area 210C-1 may be electrically connected to the first base TSV area 121C-31, 121C-61 of the control device 11C-1. The first core TSV area 210C-1 may receive the command CMD and the data DATA from the first base TSV area 121C-31, 121C-61. The first core TSV area 210C-1 may receive the command CMD and the data DATA through a plurality of TSVs. The first core TSV area 210C-1 may output the command CMD and the data DATA to the first to fourth channels CH1 to CH4. The first core TSV area 210C-1 may receive the data DATA from the first to fourth channels CH1 to CH4 and output the data DATA to the first base TSV area 121C-31, 121C-61. The first core TSV area 210C-1 may be disposed in a central area CENTER. The first core TSV area 210C-1 may be disposed in a second direction D2 from the first edge area TOP. The second direction D2 may be set as a direction of from the first edge area TOP to the central area CENTER. The first edge area TOP may be set as an upper area of the memory device 12C-1 in a Y axis.

The second core TSV area 220C-1 may be electrically connected to the second base TSV area 122C-31, 122C-61 of the control device 11C-1. The second core TSV area 220C-1 may receive the command CMD and the data DATA from the second base TSV area 122C-31, 122C-61. The second core TSV area 220C-1 may receive the command CMD and the data DATA through a plurality of TSVs. The second core TSV area 220C-1 may output the command CMD and the data DATA to the fifth to eighth channels CH5 to CH8. The second core TSV area 220C-1 may receive the data DATA from the fifth to eighth channels CH5 to CH8 and output the data DATA to the second base TSV area 122C-31, 122C-61. The second core TSV area 220C-1 may be disposed in the central area CENTER. The second core TSV area 220C-1 may be disposed in a first direction D1 from the second edge area BOTTOM. The first direction D1 may be set as a direction from the second edge area BOTTOM to the central area CENTER. The second edge area BOTTOM may be set as a lower area of the memory device 12C-1 in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

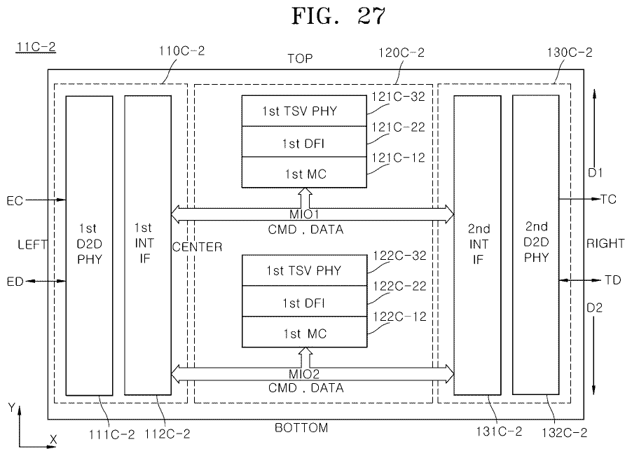

FIG. 27 is a block diagram illustrating a construction of the control device 11C-2 according to an embodiment of the present disclosure. As illustrated in FIG. 27, the control device 11C-2 may include a first area 110C-2, a second area 120C-2, and a third area 130C-2.

The first area 110C-2 may include a first physical area (1st D2D PHY) 111C-2 and a first internal interface area (1st INT IF) 112C-2.

The first physical area 111C-2 may generate a command CMD by receiving an external command EC from the process circuit (PRC CT in FIGS. 18 and 19). The first physical area 111C-2 may generate the command CMD by buffering or decoding the external command EC. The external command EC and the command CMD are each illustrated as only one signal, but may respectively include a plurality of bits. The first physical area 111C-2 may generate data DATA by receiving external data ED from the process circuit (PRC CT in FIGS. 18 and 19). The first physical area 111C-2 may generate the external data ED by receiving data DATA from the first internal interface area 112C-2. The first physical area 111C-2 may output the external data ED to the process circuit (PRC CT in FIGS. 18 and 19). The external data ED and the data DATA are each illustrated as only one signal, but may respectively include a plurality of bits.

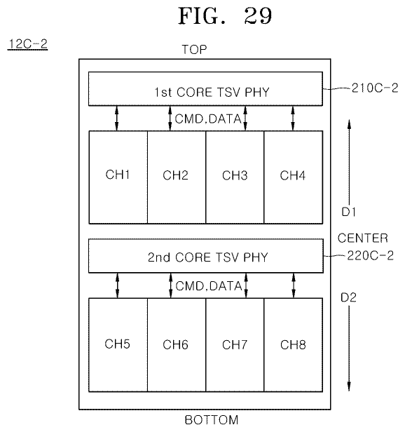

The first internal interface area 112C-2 may receive the command CMD and the data DATA from the first physical area 111C-2. The first internal interface area 112C-2 may output the command CMD and the data DATA that control an operation of the memory device (12C-2 in FIG. 26) to a first internal input and output line MIO1 by adjusting the input and output sequence of the command CMD and the data DATA. The first internal interface area 112C-2 may output the command CMD and the data DATA that control an operation of the memory device (12C-2 in FIG. 29) to a second internal input and output line MIO2 by adjusting the input and output sequence of the command CMD and the data DATA. The first internal input and output line MIO1 may be disposed in a central area CENTER of the control device 111C-2. The second internal input and output line MIO2 may be disposed in a second edge area BOTTOM of the control device 11C-2. The first internal interface area 112C-2, the first internal input and output line MIO1, and the second internal input and output line MIO2 may be implemented in a network-on-chip (NoC).

The first area 110C-2 may be set as an area that generates a command CMD and data DATA and inputs and outputs the command CMD and the data DATA. Heat may be generated when the first area 110C-2 inputs and outputs the command CMD and the data DATA. The first area 110C-12 may be disposed in a left area LEFT of the control device 11C-2 in an X axis.

The second area 120C-2 may include a first memory controller (1st MC) 121C-12, a first base interface area (1st DFI) 121C-22, a first base TSV area (1st TSV PHY) 121C-32, a second memory controller (2nd MC) 122C-12, a second base interface area (2nd DFI) 122C-22, and a second base TSV area (2nd TSV PHY) 122C-32 that control an operation of the memory device (12C-2 in FIG. 29). The first memory controller 121C-12, the first base interface area 121C-22, and the first base TSV area 121C-32 may be components that control an operation of a first group of channels (CH1 to CH4 in FIG. 29) included in a memory device (12C-2 in FIG. 29). The second memory controller 122C-12, the second base interface area 122C-22, and the second base TSV area 122C-32 may be components that control an operation of the second group of channels (CH5 to CH8 in FIG. 29) included in the memory device (12C-2 in FIG. 29). The first memory controller 121C-12, the first base interface area 121C-22, and the first base TSV area 121C-32, and the second memory controller 122C-12, the second base interface area 122C-22, and the second base TSV area 122C-32 may be implemented, respectively, with the memory controller 121C, the base interface area 122C, and the base TSV area 123C illustrated in FIG. 20.

The first memory controller 121C-12, the first base interface area 121C-22, the first base TSV area 121C-32, the second memory controller 122C-12, the second base interface area 122C-22, and the second base TSV area 122C-32 may be disposed in the horizontal direction of the control device 11C-2.

The first memory controller 121C-12 may be electrically connected to the first internal input and output line MIO1. The first memory controller 121C-12 may receive the command CMD and the data DATA that control an operation of the first group of channels (CH1 to CH4 in FIG. 29) included in the memory device (12C-2 in FIG. 29) through the first internal input and output line MIO1. The first memory controller 121C-12 may output the command CMD and the data DATA that control an operation of the first group of channels (CH1 to CH4 in FIG. 29) included in the memory device (12C-2 in FIG. 29). The first memory controller 121C-12 may receive the data DATA from the first base interface area 121C-22 and output the data DATA to the first internal input and output line MIO1.

The first base interface area 121C-22 may be electrically connected to the first memory controller 121C-12. The first base interface area 121C-22 may receive the command CMD and the data DATA from the first memory controller 121C-12. The first base interface area 121C-22 may output the command CMD and the data DATA to the first base TSV area 121C-32 by adjusting the input and output sequence of the command CMD and the data DATA. The first base interface area 121C-22 may receive the data DATA from the first base TSV area 121C-32 and output the data DATA to the first memory controller 121C-12.

The first base TSV area 121C-32 may be electrically connected to the first base interface area 121C-22. The first base TSV area 121C-32 may receive the command CMD and the data DATA from the first base interface area 121C-22. The first base TSV area 121C-32 may output the command CMD and the data DATA to a first core TSV area (1st CORE TSV PHY) (210C-2 in FIG. 29) included in the memory device (12C-2 in FIG. 29) through a plurality of TSVs. The first base TSV area 121C-32 may receive data DATA from the memory device (12C-2 in FIG. 29) and output the data DATA to the first base interface area 121C-22.

The first memory controller 121C-12, the first base interface area 121C-22, and the first base TSV area 121C-32 may be sequentially disposed in a first direction D1 from the central area CENTER of the control device 11C-2. The first direction D1 may be set as a direction from the central area CENTER to a first edge area TOP. The first edge area TOP may be set as an upper area of the control device 11C-2 in a Y axis.

The second memory controller 122C-12 may be electrically connected to the second internal input and output line MIO2. The second memory controller 122C-12 may receive the command CMD and the data DATA that control an operation of a second group of channels (CH5 to CH8 in FIG. 29) included in the memory device (12C-2 in FIG. 29) through the second internal input and output line MIO2. The second memory controller 122C-12 may output the command CMD and the data DATA that control an operation of the second group of channels (CH5 to CH8 in FIG. 29) included in the memory device (12C-2 in FIG. 29). The second memory controller 122C-12 may receive the data DATA from the second base interface area 122C-22 and output the data DATA to the second internal input and output line MIO2.

The second base interface area 122C-22 may be electrically connected to the second memory controller 122C-12. The second base interface area 122C-22 may receive the command CMD and the data DATA from the second memory controller 122C-12. The second base interface area 122C-22 may output the command CMD and the data DATA to the second base TSV area 122C-32 by adjusting the input and output sequence of the command CMD and the data DATA. The second base interface area 122C-22 may receive the data DATA from the second base TSV area 122C-32 and output the data DATA to the second memory controller 121C-22.

The second base TSV area 122C-32 may be electrically connected to the second base interface area 122C-22. The second base TSV area 122C-32 may receive the command CMD and the data DATA from the second base interface area 122C-22. The second base TSV area 122C-32 may output the command CMD and the data DATA to a second core TSV area (2nd CORE TSV PHY) (220C-2 in FIG. 29) included in the memory device (12C-2 in FIG. 29) through a plurality of TSVs. The second base TSV area 122C-32 may receive the data DATA from the memory device (12C-2 in FIG. 29) and output the data DATA to the second base interface area 122C-22.

The second memory controller 122C-12, the second base interface area 122C-22, and the second base TSV area 122C-32 may be sequentially disposed in the first direction D1 from the second edge area BOTTOM of the control device 11C-2. The first direction D1 may be set as a direction from the second edge area BOTTOM to the central area CENTER. The second edge area BOTTOM may be set as a lower area of the control device 11C-2 in the Y axis.

The second area 120C-2 may be set as an area that receives the command CMD and the data DATA from the first area 110C-2 and outputs the command CMD and the data DATA to the memory device (12C-2 in FIG. 29). The second area 120C-2 may be disposed in the central area CENTER of the control device 11C-2 in the X axis.

The third area 130C-2 may include a second internal interface area (2nd INT IF) 131C-2 and a second physical area (2nd D2D PHY) 132C-2.

The second internal interface area 131C-2 may receive the command CMD and the data DATA from the first internal input and output line MIO1. The second internal interface area 131C-2 may output the command CMD and the data DATA received through the first internal input and output line MIO1 to the second physical area 132C-2 by adjusting the input and output sequence of the command CMD and the data DATA. The second internal interface area 131C-2 may receive the command CMD and the data DATA from the second internal input and output line MIO2. The second internal interface area 131C-2 may output the command CMD and the data DATA received through the second internal input and output line MIO2 to the second physical area 132C-2 by adjusting the input and output sequence of the command CMD and the data DATA. The second internal interface area 131C-2 may be implemented in a network-on-chip (NoC).

The second physical area 132C-2 may receive the command CMD and the data DATA from the second internal interface area 131C-2. The second physical area 132C-2 may output the command CMD that is received as a transfer command TC. The second physical area 132C-2 may output the data DATA that are received as transfer data TD. The second physical area 132C-2 may output the transfer command TC and the transfer data TD to another HBM device and the process circuit (PRC CT in FIGS. 18 and 19).

The third area 130C-2 may be set as an area that receives the command CMD and the data DATA from the second area 120C-2. The third area 130C-2 may be set as an area that inputs and outputs the transfer command TC and the transfer data TD that are generated from the command CMD and the data DATA that are received. The third area 130C-2 may be set as an area that inputs and outputs the command CMD and the data DATA to and from another HBM device, a process circuit, or an external device. The third area 130C-2 may be disposed in a right area RIGHT of the control device 11C-2 in the X axis.

In FIG. 27, the first internal interface area 112C-2, the second internal interface area 131C-2, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C-2 in the X axis direction are disposed between the first internal interface area 112C-2 and the second internal interface area 131C-2 that are implemented in the longitudinal direction of the control device 11C-2 in the Y axis direction.

In the first form, the first memory controller 121C-12, the first base interface area 121C-22, and the first base TSV area 121C-32 may be sequentially disposed in the first direction D1 from the central area CENTER in which the first internal input and output line MIO1 is disposed. In the first form, the second memory controller 122C-12, the second base interface area 122C-22, and the second base TSV area 122C-32 may be sequentially disposed in the first direction D1 from the second edge area BOTTOM in which the second internal input and output line MIO2 is disposed.

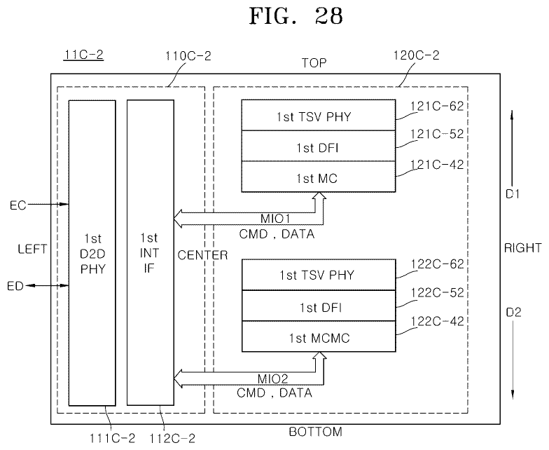

FIG. 28 is a block diagram illustrating a construction of the control device 11C according to an embodiment of the present disclosure. As illustrated in FIG. 28, a control device 11C-2 may include a first area 110C-2 and a second area 120C-2.

The first area 110C-2 may include a first physical area (1st D2D PHY) 111C-2 and a first internal interface area (1st INT IF) 112C-2.

The first physical area 111C-2 and the first internal interface area 112C-2 have the same constructions as the first physical area 111C-2 and the first internal interface area 112C-2 illustrated in FIG. 27, and thus detailed descriptions thereof are omitted.

A first internal input and output line MIO1 illustrated in FIG. 28 is connected between the first internal interface area 112C-2 and a first memory controller (1st MC) 121C-42 differently from the first internal input and output line MIO1 illustrated in FIG. 27, and may input and output a command CMD and data DATA. A second internal input and output line MIO2 illustrated in FIG. 28 is connected between the first internal interface area 112C-2 and a second memory controller (2nd MC) 122C-42 differently from the second internal input and output line MIO2 illustrated in FIG. 27, and may input and output a command CMD and data DATA. The first internal interface area 112C-2, the first internal input and output line MIO1 and the second internal input and output line MIO2 may be implemented in a network-on-chip (NoC).

The first area 110C-2 may be set as an area that generates a command CMD and data DATA and inputs and outputs the command CMD and the data DATA. Heat may be generated when the first area 110C-2 inputs and outputs the command CMD and the data DATA. The first area 110C-2 may be disposed in a left area LEFT of the control device 11C-2 in an X axis.

The second area 120C-2 may include the first memory controller 121C-42, a first base interface area (1st DFI) 121C-52, a first base TSV area (1st TSV PHY) 121C-62, the second memory controller 122C-42, a second base interface area (2nd DFI) 122C-52, and a second base TSV area (2nd TSV PHY) 122C-62 that control an operation of the memory device (12C-2 in FIG. 29).

The first memory controller 121C-42, the first base interface area 121C-52, the first base TSV area 121C-62, the second memory controller 122C-42, the second base interface area 122C-52, and the second base TSV area 122C-62 have the same constructions as the first memory controller 121C-12, the first base interface area 121C-22, the first base TSV area 121C-32, the second memory controller 122C-12, the second base interface area 122C-22, and the second base TSV area 122C-32 illustrated in FIG. 27, and thus detailed descriptions thereof are omitted.

The second area 120C-2 may be set as an area that receives the command CMD and the data DATA from the first area 110C-2 and outputs the command CMD and the data DATA to the memory device 12C-2. The second area 120C-2 may be disposed in a right area RIGHT of the control device 11C-2 in the X axis.

The first internal interface area 112C-2, the first internal input and output line MIO1, and the second internal input and output line MIO2 that are implemented with a network-on-chip (NoC), which are illustrated in FIG. 28, may be implemented in a second form. The second form means a form in which the first internal interface area 112C-2 that is implemented in the longitudinal direction of the control device 11C-2 in a Y axis direction and the first internal input and output line MIO1, the second internal input and output line MIO2 that are implemented in the transverse direction of the control device 11C-2 in the X axis direction are disposed.

In the second form, the first memory controller 121C-42, the first base interface area 121C-52, and the first base TSV area 121C-62 may be sequentially disposed in a first direction D1 from the central area CENTER in which the first internal input and output line MIO1 is disposed. In the second form, the second memory controller 122C-42, the second base interface area 122C-52, and the second base TSV area 122C-62 may be sequentially disposed in the first direction D1 from a second edge area BOTTOM in which the second internal input and output line MIO2 is disposed.

FIG. 29 is a block diagram illustrating a construction of the memory device 12C-2 according to an embodiment of the present disclosure.

The memory device 12C-2 may include the first to eighth channels CH1 to CH8, the first core TSV area 210C-2, and a second core TSV area (2nd CORE TSV PHY) 220C-2.

The first to eighth channels CH1 to CH8 may receive the command CMD and the data DATA by independently performing internal operations. The first to eighth channels CH1 to CH8 may respectively store the data DATA after the start of a write operation of an internal operation based on the command CMD. The first to eighth channels CH1 to CH8 may respectively output the data DATA after the start of a read operation of an internal operation based on the command CMD.

The first to fourth channels CH1 to CH4 may be electrically connected to the first core TSV area 210C-2. The first to fourth channels CH1 to CH4 may receive the command CMD and the data DATA from the first core TSV area 210C-2. The first to fourth channels CH1 to CH4 may output the data DATA to the first core TSV area 210C-2. The first to fourth channels CH1 to CH4 may respectively store the data DATA based on the command CMD after the start of a write operation of an internal operation. The first to fourth channels CH1 to CH4 may respectively output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C-2. The fifth to eighth channels CH5 to CH8 may receive a command CMD and data DATA from the second core TSV area 220C-2. The fifth to eighth channels CH5 to CH8 may output the data DATA to the second core TSV area 220C-2. The fifth to eighth channels CH5 to CH8 may respectively store the data DATA based on the command CMD after the start of a write operation of an internal operation. The fifth to eighth channels CH5 to CH8 may respectively output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the memory device 12C-2. The fifth to eighth channels CH5 to CH8 may be disposed in a second edge area BOTTOM of the memory device 12C-2.

The first core TSV area 210C-2 may be electrically connected to the first base TSV area 121C-32, 121C-62 of the control device 11C-2. The first core TSV area 210C-2 may receive the command CMD and the data DATA from the first base TSV area 121C-32, 121C-62. The first core TSV area 210C-2 may receive the command CMD and the data DATA through a plurality of TSVs. The first core TSV area 210C-2 may output the command CMD and the data DATA to the first to fourth channels CH1 to CH4. The first core TSV area 210-2 may receive the data DATA from the first to fourth channels CH1 to CH4 and output the data DATA to the first base TSV area 121C-32, 121C-62. The first core TSV area 210C-2 may be disposed in a first direction D1 from the central area CENTER. The first direction D1 may be set as a direction from the central area CENTER to a first edge area TOP. The first edge area TOP may be set as an upper area of the memory device 12C-2 in a Y axis.

The second core TSV area 220C-2 may be electrically connected to the second base TSV area 122C-32, 122C-62 of the control device 11C-2. The second core TSV area 220C-2 may receive the command CMD and the data DATA from the second base TSV area 122C-32, 122C-62. The second core TSV area 220C-2 may receive the command CMD and the data DATA through a plurality of TSVs. The second core TSV area 220C-2 may output the command CMD and the data DATA to the fifth to eighth channels CH5 to CH8. The second core TSV area 220C-2 may receive the data DATA from the fifth to eighth channels CH5 to CH8 and output the data DATA to the second base TSV area 122C-32, 122C-62. The second core TSV area 220C-2 may be disposed in the central area CENTER. The second core TSV area 220C-2 may be disposed in the first direction D1 from the second edge area BOTTOM. The first direction D1 may be set as a direction from the second edge area BOTTOM to the central area CENTER. The second edge area BOTTOM may be set as a lower area of the memory device 12C-2 in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

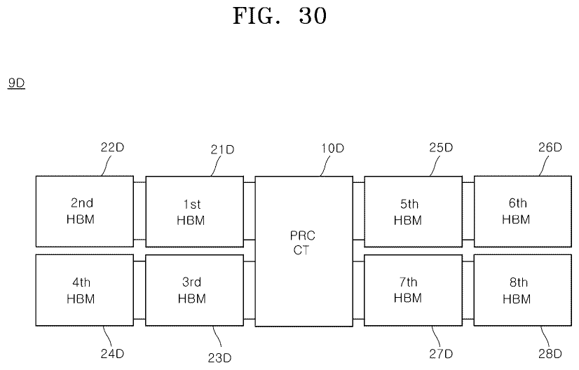

FIG. 30 is a block diagram illustrating a construction of a semiconductor system 9D according to an embodiment of the present disclosure. As illustrated in FIG. 30, the semiconductor system 9D may include a process circuit (PRC CT) 10D, a first HBM device (1^{st} HBM) 21D, a second HBM device (2^{nd} HBM) 22D, a third HBM device (3^{rd} HBM) 23D, a fourth HBM device (4^{th} HBM) 24D, a fifth HBM device (5^{th} HBM) 25D, a sixth HBM device (6^{th} HBM) 26D, a seventh HBM device (7^{th} HBM) 27D, and an eighth HBM device (8^{th} HBM) 28D.

The process circuit 10D may be electrically connected to the first HBM device 21D, the third HBM device 23D, the fifth HBM device 25D, and the seventh HBM device 27D. The process circuit 10D may control operations of the first HBM device 21D, the third HBM device 23D, the fifth HBM device 25D, and the seventh HBM device 27D. The process circuit 10D may perform an arithmetic operation by receiving data DATA from at least any one of the first HBM device 21D, the third HBM device 23D, the fifth HBM device 25D, and the seventh HBM device 27D.

The first HBM device 21D and the second HBM device 22D may be electrically connected. The third HBM device 23D and the fourth HBM device 24D may be electrically connected. The fifth HBM device 25D and the sixth HBM device 26D may be electrically connected. The seventh HBM device 27D and the eighth HBM device 28D may be electrically connected.

The first HBM device 21D and the second HBM device 22D may have physical areas included within the first HBM device 21D and the second HBM device 22D electrically connected, and may be connected to the process circuit 10D in common. The third HBM device 23D and the fourth HBM device 24D may have physical areas included within the third HBM device 23D and the fourth HBM device 24D electrically connected, and may be connected to the process circuit 10D in common. The fifth HBM device 25D and the sixth HBM device 26D may have physical areas included within the fifth HBM device 25D and the sixth HBM device 26D electrically connected, and may be connected to the process circuit 10D in common. The seventh HBM device 27D and the eighth HBM device 28D may have physical areas included within the seventh HBM device 27D and the eighth HBM device 28D electrically connected, and may be connected to the process circuit 10D in common.

The semiconductor system 9D illustrated in FIG. 30 is implemented so that two HBM devices are electrically connected to the process circuit 10D, but various numbers of HBM devices may be electrically connected to the process circuit 10D according to an embodiment.

The process circuit 10D may control operations of the first HBM device 21D and the second HBM device 22D that is electrically connected to the first HBM device 21D. The process circuit 10D may perform an arithmetic operation by receiving the data DATA from the first HBM device 21D and the second HBM device 22D. The process circuit 10D may control operations of the third HBM device 23D and the fourth HBM device 24D that is electrically connected to the third HBM device 23D. The process circuit 10D may perform an arithmetic operation by receiving the data DATA from the third HBM device 23D and the fourth HBM device 24D. The process circuit 10D may control operations of the fifth HBM device 25D and the sixth HBM device 26D that is electrically connected to the fifth HBM device 25D. The process circuit 10D may perform an arithmetic operation by receiving the data DATA from the fifth HBM device 25D and the sixth HBM device 26D. The process circuit 10D may control operations of the seventh HBM device 27D and the eighth HBM device 28D that is electrically connected to the seventh HBM device 27D. The process circuit 10D may perform an arithmetic operation by receiving the data DATA from the seventh HBM device 27D and the eighth HBM device 28D.

The process circuit 10D may be implemented with a graphics processing unit (GPU) and a neural processing unit (NPU).

The arithmetic operation may include a training operation and an inference operation. The training operation may be set as an operation of an artificial intelligence (AI) model learning a rule, a pattern, or a relation by optimizing weights and parameters from given data DATA. The inference operation may be set as an operation of an artificial intelligence (AI) model rapidly deriving results from new data by using weights learnt during the training operation.

The first HBM device 21D, the second HBM device 22D, the third HBM device 23D, the fourth HBM device 24D, the fifth HBM device 25D, the sixth HBM device 26D, the seventh HBM device 27D, and the eighth HBM device 23D may respectively store the data DATA and output the data DATA stored in the respective HBM device. The first HBM device 21D, the second HBM device 22D, the third HBM device 23D, the fourth HBM device 24D, the fifth HBM device 25D, the sixth HBM device 26D, the seventh HBM device 27D, and the eighth HBM device 23D may respectively be disposed at the boundary of a physical area D2D PHY. The first HBM device 21D, the second HBM device 22D, the third HBM device 23D, the fourth HBM device 24D, the fifth HBM device 25D, the sixth HBM device 26D, the seventh HBM device 27D, and the eighth HBM device 23D may be electrically connected to the process circuit 10D and different HBM devices through the physical area D2D PHY. The first HBM device 21D, the second HBM device 22D, the third HBM device 23D, the fourth HBM device 24D, the fifth HBM device 25D, the sixth HBM device 26D, the seventh HBM device 27D, and the eighth HBM device 23D may be shared by the process circuit 10D through the physical area D2D PHY.

The semiconductor system 9D according to an embodiment of the present disclosure can extend a data capacity that is used in an arithmetic operation because a plurality of HBM devices is electrically connected to different HBM devices and electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

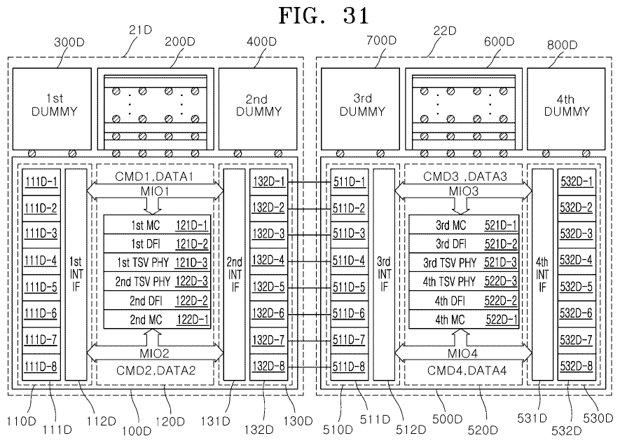

FIG. 31 is a block diagram illustrating a construction of the first HBM device 21D and the second HBM device 22D according to an embodiment of the present disclosure.

The first HBM device 21D may include a first control device 100D, a first memory device 200D, a first dummy die group (1^{st} DUMMY) 300D, and a second dummy die group (2^{nd} DUMMY) 400D.

The first control device 100D may generate a first command CMD1, first data DATA1, a second command CMD2, and second data DATA2. The first control device 100D may output the first command CMD1, the first data DATA1, the second command CMD2, and the second data DATA2 to the first memory device 200D. The first control device 100D may receive the first data DATA1 and the second data DATA2 from the first memory device 200D. The first control device 100D may be a base chip or a controller that controls an operation of the first memory device 200D.

The first control device 100D may include a first area 110D, a second area 120D, and a third area 130D. An upper part of the first area 110D may be set as a first predetermined area. An upper part of the second area 120D may be set as a second predetermined area. An upper part of the third area 130D may be set as a third predetermined area.

The first area 110D may be set as an area in which the first command CMD1, the first data DATA1, the second command CMD2, and the second data DATA2 are generated. The first area 110D may be set as an area in which the first command CMD1, the first data DATA1, the second command CMD2, and the second data DATA2 are input and output. When the first command CMD1, the first data DATA1, the second command CMD2, and the second data DATA2 are input to and output from the first area 110D, heat may be generated. The second area 120D may be set as an area in which the first command CMD1 and the first data DATA1 are received from the first area 110D and output to the first memory device 200D and the third area 130D and the first data DATA1 are received from the first memory device 200D and output to the first area 110D and the third area 130D. The second area 120D may be set as an area in which the second command CMD2 and the second data DATA2 are received from the first area 110D and output to the first memory device 200D and the third area 130D and the second data DATA2 are received from the first memory device 200D and output to the first area 110D and the third area 130D. The third area 130D may be set as an area in which the first command CMD1, the first data DATA1, the second command CMD2, and the second data DATA2 are received and the first command CMD1, the first data DATA1, the second command CMD2, and the second data DATA2 are input and output. The third area 130D may be set as an area in which the first command CMD1, the first data DATA1, the second command CMD2, and the second data DATA2 are input to and output from another HBM device, a process circuit, or an external device. When the first command CMD1, the first data DATA1, the second command CMD2, and the second data DATA2 are input to and output from the third area 130D, heat may be generated.

The first area 110D may include a first physical area 111D and a first internal interface area (1^{st} INT IF) 112D.

The first physical area 111D may include first to eighth physical layers 111D-1 to 111D-8. The first physical area 111D may generate the first command CMD1, the first data DATA1, the second command CMD2, and the second data DATA2 based on a signal input from the process circuit 10D through the first to eighth physical layers 111D-1 to 111D-8. As some of the first to eighth physical layers 111D-1 to 111D-8 are activated, the first physical area 111D may generate the first command CMD1, the first data DATA1, the second command CMD2, and the second data DATA2 based on a signal input from the process circuit 10D. At least two physical layers of the first to eighth physical layers 111D-1 to 111D-8 may be set as one group. For example, the first physical layer 111D-1, the second physical layer 111D-2, the third physical layer 111D-3 and the fourth physical layer 111D-4 may be set as a first group of physical layers. The fifth physical layer 111D-5, the sixth physical layer 111D-6, the seventh physical layer 111D-7, and the eighth physical layer 111D-8 may be set as a second group of physical layers. Furthermore, the first physical layer 111D-1, the third physical layer 111D-3, the fifth physical layer 111D-5 and the seventh physical layer 111D-7 may be set as a first group of physical layers. The second physical layer 111D-2, the fourth physical layer 111D-4, the sixth physical layer 111D-6, and the eighth physical layer 111D-8 may be set as a second group of physical layers. The first to eighth physical layers 111D-1 to 111D-8 may be a physical layer (PHY) that is responsible for the generation, transmission, reception, and physical connection of signals and data between an external device and the first control device 100D.

The first to eighth physical layers 111D-1 to 111D-8 may be selectively activated. The first to eighth physical layers 111D-1 to 111D-8 may be selectively activated under the control of the process circuit 10D. The first to eighth physical layers 111D-1 to 111D-8 may be selectively activated by the setting of a mode register set (MRS) included in the HBM device. The first to eighth physical layers 111D-1 to 111D-8 may be selectively activated by a device, such as IEEE1500 included in the HBM device. The first to eighth physical layers 111D-1 to 111D-8 may be selectively activated based on the bandwidth of data.

For example, the bandwidth of data when the first to fourth physical layers 111D-1 to 111D-4 are activated and the fifth to eighth physical layers 111D-5 to 111D-8 are deactivated may be set as a bandwidth that is ½ of the bandwidth of data when the first to eighth physical layers 111D-1 to 111D-8 are activated. The bandwidth of data when the first and second physical layers 111D-1 and 111D-2 are activated and the third to eighth physical layers 111D-3 to 111D-8 are deactivated may be set as a bandwidth that is ¼ of the bandwidth of data when the first to eighth physical layers 111D-1 to 111D-8 are activated.

The first physical area 111D may generate the first command CMD1, the first data DATA1, the second command CMD2, and the second data DATA2 based on a signal input from the process circuit 10D. The first physical area 111D may output the first command CMD1, the first data DATA1, the second command CMD2, and the second data DATA2 to the first internal interface area 112D. The first physical area 111D may receive the first data DATA1 and the second data DATA2 from the first internal interface area 112D and output the first data DATA1 and the second data DATA2 to the process circuit 10D.

The first internal interface area 112D may receive the first command CMD1, the first data DATA1, the second command CMD2, and the second data DATA2 from the first physical area 111D. The first internal interface area 112D may output the first command CMD1 and the first data DATA1 to a first internal input and output line MIO1 by adjusting the input and output sequence of the first command CMD1 and the first data DATA1. The first internal interface area 112D may output the second command CMD2 and the second data DATA2 to a second internal input and output line MIO2 by adjusting the input and output sequence of the second command CMD2 and the second data DATA2. The first internal interface area 112D may receive the first data DATA1 from the first internal input and output line MIO1 and output the first data DATA1 to the first physical area 111D. The first internal interface area 112D may receive the second data DATA2 from the second internal input and output line MIO2 and output the second data DATA2 to the first physical area 111D. The first internal interface area 112D may output the first command CMD1, the first data DATA1, the second command CMD2, and the second data DATA2 to the second area 120D and the third area 130D by adjusting the input and output sequence of the first command CMD1, the first data DATA1, the second command CMD2, and the second data DATA2. The first internal interface area 112D may be an interface that defines the timing and sequence of signals transmitted between the physical layer (PHY) and internal circuits and inputs and outputs the signals. The first internal interface area 112D and the first and second internal input and output lines MIO1 and MIO2 may be implemented as a network-on-chip (NoC). The network-on-chip (NoC) may be set as a transmission path that connects several internal circuits within a chip.

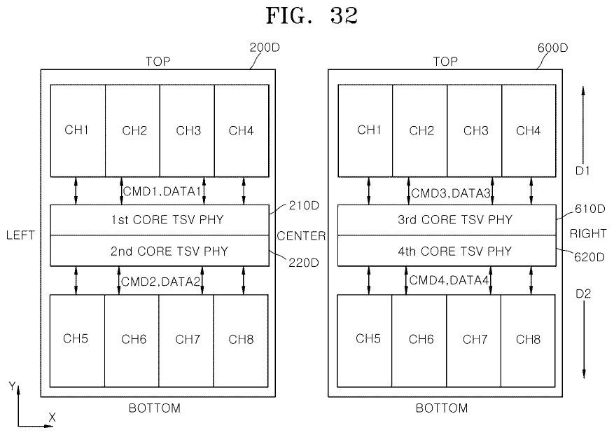

The second area 120D may include a first memory controller (1st MC) 121D-1, a first base interface area (1st DFI) 121D-2, a first base TSV area (1st TSV PHY) 121D-3, a second memory controller (2nd MC) 122D-1, a second base interface area (2nd DFI) 122D-2, and a second base TSV area (2nd TSV PHY) 122D-3 that control an operation of the first memory device 200D. The first memory controller 121D-1, the first base interface area 121D-2, and the first base TSV area 121D-3 may be components that control an operation of a first group of channels (CH1 to CH4 in FIG. 32) included in the first memory device 200D. The second memory controller 122D-1, the second base interface area 122D-2, and the second base TSV area 122D-3 may be components that control an operation of a second group of channels (CH5 to CH8 in FIG. 32) included in the first memory device 200D.

The first memory controller 121D-1, the first base interface area 121D-2, the first base TSV area 121D-3, the second memory controller 122D-1, the second base interface area 122D-2, and the second base TSV area 122D-3 may be disposed in the horizontal direction of the first control device 100D. The first memory controller 121D-1, the first base interface area 121D-2, and the first base TSV area 121D-3, and the second memory controller 122D-1, the second base interface area 122D-2, and the second base TSV area 122D-3 may be disposed at various locations of the second area 120D according to an embodiment.

The first memory controller 121D-1 may be electrically connected to the first internal input and output line MIO1. The first memory controller 121D-1 may receive the first command CMD1 and the first data DATA1 that control an operation of the first group of channels (CH1 to CH4 in FIG. 32) included in the first memory device 200D through the first internal input and output line MIO1. The first memory controller 121D-1 may output the first command CMD1 and the first data DATA1 that control an operation of the first group of channels (CH1 to CH4 in FIG. 32) included in the first memory device 200D. The first memory controller 121D-1 may receive the first data DATA1 from the first base interface area 121D-2 and output the first data DATA1 to the first internal input and output line MIO1.

The first base interface area 121D-2 may be electrically connected to the first memory controller 121D-1. The first base interface area 121D-2 may receive the first command CMD1 and the first data DATA1 from the first memory controller 121D-1. The first base interface area 121D-2 may output the first command CMD1 and the first data DATA1 to the first base TSV area 121D-3 by adjusting the input and output sequence of the first command CMD1 and the first data DATA1. The first base interface area 121D-2 may receive the first data DATA1 from the first base TSV area 121D-3 and output the first data DATA1 to the first memory controller 121D-1.

The first base TSV area 121D-3 may be electrically connected to the first base interface area 121D-2. The first base TSV area 121D-3 may receive the first command CMD1 and the first data DATA1 from the first base interface area 121D-2. The first base TSV area 121D-3 may output the first command CMD1 and the first data DATA1 to a first core TSV area (1^{st} CORE TSV PHY) (210D in FIG. 32) included in the first memory device 200D through a plurality of TSVs. The first base TSV area 121D-3 may receive the first data DATA1 from the first memory device 200D and output the first data DATA1 to the first base interface area 121D-2.

The second memory controller 122D-1 may be electrically connected to the second internal input and output line MIO2. The second memory controller 122D-1 may receive the second command CMD2 and the second data DATA2 that control an operation of the second group of channels (CH5 to CH8 in FIG. 32) included in the first memory device 200D through the second internal input and output line MIO2. The second memory controller 122D-1 may output the second command CMD2 and the second data DATA2 that control an operation of the second group of channels (CH5 to CH8 in FIG. 32) included in the first memory device 200D. The second memory controller 122D-1 may receive the second data DATA2 from the second base interface area 122D-2 and output the second data DATA2 to the second internal input and output line MIO2.

The second base interface area 122D-2 may be electrically connected to the second memory controller 122D-1. The second base interface area 122D-2 may receive the second command CMD2 and the second data DATA2 from the second memory controller 122D-1. The second base interface area 122D-2 may output the second command CMD2 and the second data DATA2 to the second base TSV area 122D-3 by adjusting the input and output sequence of the second command CMD2 and the second data DATA2. The second base interface area 122D-2 may receive the second data DATA2 from the second base TSV area 122D-3 and output the second data DATA2 to the second memory controller 122D-1.

The second base TSV area 122D-3 may be electrically connected to the second base interface area 122D-2. The second base TSV area 122D-3 may receive the second command CMD2 and the second data DATA2 from the second base interface area 122D-2. The second base TSV area 122D-3 may output the second command CMD2 and the second data DATA2 to a second core TSV area (2^{nd} CORE TSV PHY) (220D in FIG. 32) included in the first memory device 200D through a plurality of TSVs. The second base TSV area 122D-3 may receive the second data DATA2 from the first memory device 200D and output the second data DATA2 to the second base interface area 122D-2.

The third area 130D may include a second internal interface area (2^{nd} INT IF) 131D and a second physical area 132D.

The second internal interface area 131D may receive the first command CMD1 and the first data DATA1 from the first internal input and output line MIO1. The second internal interface area 131D may receive the second command CMD2 and the second data DATA2 from the second internal input and output line MIO2. The second internal interface area 131D may output the first command CMD1, the first data DATA1, the second command CMD2, and the second data DATA2 to the second physical area 132D by adjusting the input and output sequence of the first command CMD1, the first data DATA1, the second command CMD2, and the second data DATA2. The second internal interface area 131D may receive the first data DATA1 from the second physical area 132D and output the first data DATA1 to the first internal interface area 112D through the first internal input and output line MIO1. The second internal interface area 131D may receive the second data DATA2 from the second physical area 132D and output the second data DATA2 to the first internal interface area 112D through the second internal input and output line MIO2. The second internal interface area 131D may be an interface that defines the timing and sequence of signals transmitted between the physical layer (PHY) and internal circuits and inputs and outputs the signals. The second internal interface area 131D may be implemented as a network-on-chip (NoC).

The second physical area 132D may include ninth to sixteenth physical layers 132D-1 to 132D-8. The second physical area 132D may receive the first command CMD1, the first data DATA1, the second command CMD2, and the second data DATA2 from the second internal interface area 131D through the ninth to sixteenth physical layers 132D-1 to 132D-8. The second physical area 132D may output the first command CMD1, the first data DATA1, the second command CMD2, and the second data DATA2 to the second HBM device 22D and the process circuit 10D. The second physical area 132D may receive the third data DATA3 and the fourth data DATA4 from the second HBM device 22D. At least two physical layers, among the ninth to sixteenth physical layers 132D-1 to 132D-8, may be set as one group. For example, the ninth physical layer 132D-1, the tenth physical layer 132D-2, the eleventh physical layer 132D-3, and the twelfth physical layer 132D-4 may be set as a first group of physical layers. The thirteenth physical layer 132D-5, the fourteenth physical layer 132D-6, the fifteenth physical layer 132D-7, and the sixteenth physical layer 132D-8 may be set as a second group of physical layers. Furthermore, the ninth physical layer 132D-1, the eleventh physical layer 132D-3, the thirteenth physical layer 132D-5, and the fifteenth physical layer 132D-7 may be set as a first group of physical layers. The tenth physical layer 132D-2, the twelfth physical layer 132D-4, the fourteenth physical layer 132D-6, and the sixteenth physical layer 132D-8 may be set as a second group of physical layers. The ninth to sixteenth physical layers 132D-1 to 132D-8 may respectively be a physical layer (PHY) that is responsible for the generation, transmission, reception, and physical connection of signals and data between an external device, the first control device 100D, and another HBM device.

The ninth to sixteenth physical layers 132D-1 to 132D-8 may be selectively activated. The ninth to sixteenth physical layers 132D-1 to 132D-8 may be selectively activated under the control of the process circuit 10D. The ninth to sixteenth physical layers 132D-1 to 132D-8 may be selectively activated by the setting of a mode register set (MRS) included in the HBM device. The ninth to sixteenth physical layers 132D-1 to 132D-8 may be selectively activated by a device, such as IEEE1500 included in the HBM device. The ninth to sixteenth physical layers 132D-1 to 132D-8 may be selectively activated based on the bandwidth of data.

For example, the bandwidth of data when the ninth to twelfth physical layers 132D-1 to 132D-4 are activated and the thirteenth to sixteenth physical layers 132D-5 to 132D-8 are deactivated may be set as a bandwidth that is ½ of the bandwidth of data when the ninth to sixteenth physical layers 132D-1 to 132D-8 are activated. The bandwidth of data when the ninth and tenth physical layers 132D-1 and 132D-2 are activated and the eleventh to sixteenth physical layers 132D-3 to 132D-8 are deactivated may be set as a bandwidth that is ¼ of the bandwidth of data when the ninth to sixteenth physical layers 132D-1 to 132D-8 are activated.

The second physical area 132D may output the first command CMD1, the first data DATA1, the second command CMD2, and the second data DATA2 that are input from the second internal interface area 131D, to the second HBM device 22D. The second physical area 132D may generate the first data DATA1 and the second data DATA2 by receiving the third data DATA3 and the fourth data DATA4 from the second HBM device 22D. The second physical area 132D may output the first data DATA1 and the second data DATA2 to the second internal interface area 131D.

The third area 130D of the first control device 100D may be electrically connected to the fourth area 510D of a second control device 500D. The ninth to sixteenth physical layers 132D-1 to 132D-8 included in the third area 130D may be electrically connected to seventeenth to twenty-fourth physical layers 511D-1 to 511D-8 included in the fourth area 510D, respectively. When, for example, all of the physical layers (e.g., ninth to sixteenth physical layers 132D-1 to 132D-8) included in the third area 130D are deactivated, the connection of the first HBM device 21D to the second HBM device 22D is disconnected. When the connection of the first HBM device 21D to the second HBM device 22D is disconnected the bandwidth of data between the first and second HBM devices 21D and 22D is zero. In this way, in an embodiment, the semiconductor system 9D can reduce current consumption by selectively activating a plurality of physical layers (PHY) included in HBM devices based on the bandwidth of data.

The first memory device 200D may be vertically stacked on the second area 120D of the first control device 100D. The first memory device 200D may be disposed in the second predetermined area. The first memory device 200D may include a plurality of core dies that is vertically stacked. The first memory device 200D may receive the first command CMD1 and the first data DATA1 from the first base TSV area 121D-3. The first memory device 200D may perform an internal operation based on the first command CMD1 and the first data DATA1. The first memory device 200D may store the first data DATA1 in the plurality of core dies after the start of a write operation based on the first command CMD1. The first memory device 200D may output the first data DATA1 stored in the plurality of core dies to the first base TSV area 121D-3 after the start of a read operation based on the first command CMD1. The first memory device 200D may receive the second command CMD2 and the second data DATA2 from the second base TSV area 122D-3. The first memory device 200D may perform an internal operation based on the second command CMD2 and the second data DATA2. The first memory device 200D may store the second data DATA1 in the plurality of core dies after the start of a write operation based on the second command CMD2. The first memory device 200D may output the second data DATA2 in the plurality of core dies to the second base TSV area 122D-3 after the start of a read operation based on the second command CMD2.

The first dummy die group 300D may be vertically stacked on the first area 110D of the first control device 100D. The first dummy die group 300D may be disposed in the first predetermined area. The first dummy die group 300D may be implemented by stacking a plurality of dummy dies (not illustrated). The first dummy die group 300D may have the same height as the first memory device 200D. The plurality of dummy dies (not illustrated) included in the first dummy die group 300D may have the same height as the plurality of core dies (not illustrated) included in the first memory device 200D. The first dummy die group 300D may be one dummy die according to an embodiment. The first predetermined area in which the first dummy die group 300D is formed may be an empty space according to an embodiment. The first dummy die group 300D can discharge heat generated from the first area 110D of the first control device 100D. The plurality of dummy dies (not illustrated) included in the first dummy die group 300D may be connected through a plurality of TSVs and a plurality of micro bump pads so that heat can be easily discharged.

The second dummy die group 400D may be vertically stacked on the third area 130D of the first control device 100D. The second dummy die group 400D may be disposed in the third predetermined area. The second dummy die group 400D may be implemented by stacking a plurality of dummy dies (not illustrated). The second dummy die group 400D may have the same height as the first memory device 200D. The plurality of dummy dies (not illustrated) included in the second dummy die group 400D may have the same height as the plurality of core dies (not illustrated) included in the first memory device 200D. The second dummy die group 400D may be one dummy die according to an embodiment. The third predetermined area in which the second dummy die group 400D is formed may be an empty space according to an embodiment. The second dummy die group 400D can discharge heat generated from the third area 130D of the first control device 100D. The plurality of dummy dies (not illustrated) included in the second dummy die group 400D may be connected through a plurality of TSVs and a plurality of micro bump pads so that heat can be easily discharged.

The second HBM device 22D may include the second control device 500D, a second memory device 600D, a third dummy die group (3^{rd} DUMMY) 700D, and a fourth dummy die group (4^{th} DUMMY) 800D.

The second control device 500D may generate a third command CMD3, third data DATA3, a fourth command CMD4, and fourth data DATA4. The second control device 500D may output the third command CMD3, the third data DATA3, the fourth command CMD4, and the fourth data DATA4 to the third memory device 600D. The second control device 500D may receive the third data DATA3 and the fourth data DATA4 from the second memory device 600D. The second control device 500D may be a base chip or a controller that controls an operation of the second memory device 600D.

The second control device 500D may include the fourth area 510D, a fifth area 520D, and a sixth area 530D. An upper part of the fourth area 510D may be set as a fourth predetermined area. An upper part of the fifth area 520D may be set as a fifth predetermined area. An upper part of the sixth area 530D may be set as a sixth predetermined area.

The fourth area 510D may be set as an area in which the third command CMD3, the third data DATA3, the fourth command CMD4, and the fourth data DATA4 are generated. The fourth area 510D may be set as an area in which the third command CMD3, the third data DATA3, the fourth command CMD4, and the fourth data DATA4 are input and output. When the third command CMD3, the third data DATA3, the fourth command CMD4, and the fourth data DATA4 are input to and output from the fourth area 510D, heat may be generated. The fifth area 520D may be set as an area in which the third command CMD3 and the third data DATA3 are received from the fourth area 510D and output to the second memory device 600D and the sixth area 530D and the third data DATA3 are received from the second memory device 600D and output to the fourth area 510D and the sixth area 530D. The fifth area 520D may be set as an area in which the fourth command CMD4 and the fourth data DATA4 are received from the fourth area 510D and output to the second memory device 600D and the sixth area 530D and the fourth data DATA4 are received from the second memory device 600D and output to the fourth area 510D and the sixth area 530D. The sixth area 530D may be set as an area in which the third command CMD3, the third data DATA3, the fourth command CMD4, and the fourth data DATA4 are received and the third command CMD3, the third data DATA3, the fourth command CMD4, and the fourth data DATA4 are input and output. The sixth area 530D may be set as an area in which the third command CMD3, the third data DATA3, the fourth command CMD4, and the fourth data DATA4 are input to and output from another HBM device, a process circuit, or an external device. When the third command CMD3, the third data DATA3, the fourth command CMD4, and the fourth data DATA4 are input to and output from the sixth area 530D, heat may be generated.

The fourth area 510D may include a third physical area 511D and a third internal interface area (3^{rd} INT IF) 512D.

The third physical area 511D may include the seventeenth to twenty-fourth physical layers 511D-1 to 511D-8. The third physical area 511D may generate the third command CMD3, the third data DATA3, the fourth command CMD4, and the fourth data DATA4 based on the first command CMD1, the first data DATA1, the second command CMD2, and the second data DATA2 that are input from the first HBM device 21D through the seventeenth to twenty-fourth physical layers 511D-1 to 511D-8. The third physical area 511D may generate the third command CMD3, the third data DATA3, the fourth command CMD4, and the fourth data DATA4 based on the first command CMD1, the first data DATA1, the second command CMD2, and the second data DATA2 that are input from the first HBM device 21D as some of the seventeenth to twenty-fourth physical layers 511D-1 to 511D-8 are activated. At least two physical layers, among the seventeenth to twenty-fourth physical layers 511D-1 to 511D-8, may be set as one group. For example, the seventeenth physical layer 511D-1, the eighteenth physical layer 511D-2, the nineteenth physical layer 511D-3, and the twentieth physical layer 511D-4 may be set as a first group of physical layers. The twenty-first physical layer 511D-5, the twenty-second physical layer 511D-6, the twenty-third physical layer 511D-7, and the twenty-fourth physical layer 511D-8 may be set as a second group of physical layers. Furthermore, the seventeenth physical layer 511D-1, the nineteenth physical layer 511D-3, the twenty-first physical layer 511D-5, and the twenty-third physical layer 511D-7 may be set as a first group of physical layers. The eighteenth physical layer 511D-2, the twentieth physical layer 511D-4, the twenty-second physical layer 511D-6, and the twenty-fourth physical layer 511D-8 □ may be set as a second group of physical layers. The seventeenth to twenty-fourth physical layers 511D-1 to 511D-8 may respectively be a physical layer (PHY) that is responsible for the generation, transmission, reception, and physical connection of signals and data between the first control device 100D of the first HBM device 21D and the second control device 500D of the second HBM device 22D.

The seventeenth to twenty-fourth physical layers 511D-1 to 511D-8 may be selectively activated. The seventeenth to twenty-fourth physical layers 511D-1 to 511D-8 may be selectively activated under the control of the process circuit 10D. The seventeenth to twenty-fourth physical layers 511D-1 to 511D-8 may be selectively activated by the setting of a mode register set (MRS) included in the HBM device. The seventeenth to twenty-fourth physical layers 511D-1 to 511D-8 may be selectively activated by a device, such as IEEE1500 included in the HBM device. The seventeenth to twenty-fourth physical layers 511D-1 to 511D-8 may be selectively activated based on the bandwidth of data.

For example, the bandwidth of data when the seventeenth to twentieth physical layers 511D-1 to 511D-4 are activated and the twenty-first to twenty-fourth physical layers 511D-5 to 511D-8 are deactivated may be set as a bandwidth that is ½ of the bandwidth of data when the seventeenth to twenty-fourth physical layers 511D-1 to 511D-8 are activated. The bandwidth of data when the seventeenth and eighteenth physical layers 511D-1 and 511D-2 are activated and the nineteenth to twenty-fourth physical layers 511D-3 to 511D-8 are deactivated may be set as a bandwidth that is ¼ of the bandwidth of data when the seventeenth to twenty-fourth physical layers 511D-1 to 511D-8 are activated.

The third physical area 511D may generate the third command CMD3, the third data DATA3, the fourth command CMD4, and the fourth data DATA4 based on the first command CMD1, the first data DATA1, the second command CMD2, and the second data DATA2 that are input from the first HBM device 21D. The third physical area 511D may output the third command CMD3, the third data DATA3, the fourth command CMD4, and the fourth data DATA4 to the third internal interface area 512D. The third physical area 511D may receive the third data DATA3 and the fourth data DATA4 from the third internal interface area 512D and output the third data DATA3 and the fourth data DATA4 to the first HBM device 21D.

The fourth area 510D of the second control device 500D may be electrically connected to the third area 130D of the first control device 100D. The seventeenth to twenty-fourth physical layers 511D-1 to 511D-8 included in the fourth area 510D may be electrically connected to the ninth to sixteenth physical layers 132D-1 to 132D-8 included in the third area 130D, respectively.

The third internal interface area 512D may receive the third command CMD3, the third data DATA3, the fourth command CMD4, and the fourth data DATA4 from the third physical area 511D. The third internal interface area 512D may output the third command CMD3 and the third data DATA3 to a third internal input and output line MIO3 by adjusting the input and output sequence of the third command CMD3 and the third data DATA3. The third internal interface area 512D may output the fourth command CMD4 and the fourth data DATA4 to a fourth internal input and output line MIO4 by adjusting the input and output sequence of the fourth command CMD4 and the fourth data DATA4. The third internal interface area 512D may receive the third data DATA3 from the third internal input and output line MIO3 and output the third data DATA3 to the third physical area 511D. The third internal interface area 512D may receive the fourth data DATA4 from the fourth internal input and output line MIO4 and output the fourth data DATA4 to the third physical area 511D. The third internal interface area 512D may output the third command CMD3, the third data DATA3, the fourth command CMD4, and the fourth data DATA4 to the fifth area 520D and the sixth area 530D by adjusting the input and output sequence of the third command CMD3, the third data DATA3, the fourth command CMD4, and the fourth data DATA4. The third internal interface area 512D may be an interface that defines the timing and sequence of signals transmitted between the physical layer (PHY) and internal circuits and inputs and outputs the signals. The third internal interface area 512D and the third and fourth internal input and output lines MIO3 and MIO4 may be implemented as a network-on-chip (NoC). The network-on-chip (NoC) may be set as a transmission path that connects several internal circuits within a chip.

The fifth area 520D may include a third memory controller (3^{rd} MC) 521D-1, a third base interface area (3^{rd} DFI) 521D-2, a third base TSV area (3^{rd} TSV PHY) 521D-3, a fourth memory controller (4^{th} MC) 522D-1, a fourth base interface area (4^{th} DFI) 522D-2, and a fourth base TSV area (4^{th} TSV PHY) 522D-3 that control an operation of the second memory device 600D. The third memory controller 521D-1, the third base interface area 521D-2, and the third base TSV area 521D-3 may be components that control an operation of a first group of channels (CH1 to CH4 in FIG. 32) included in the second memory device 600D. The fourth memory controller 522D-1, the fourth base interface area 522D-2, and the fourth base TSV area 522D-3 may be components that control an operation of a second group of channels (CH5 to CH8 in FIG. 32) included in the second memory device 600D.

The third memory controller 521D-1, the third base interface area 521D-2, the third base TSV area 521D-3, the fourth memory controller 522D-1, the fourth base interface area 522D-2, and the fourth base TSV area 522D-3 may be disposed in the horizontal direction of the second control device 500D. The third memory controller 521D-1, the third base interface area 521D-2, and the third base TSV area 521D-3, and the fourth memory controller 522D-1, the fourth base interface area 522D-2, and the fourth base TSV area 522D-3 may be disposed at various locations of the fifth area 520D according to an embodiment.

The third memory controller 521D-1 may be electrically connected to the third internal input and output line MIO3. The third memory controller 521D-1 may receive the third command CMD3 and the third data DATA3 that control an operation of the first group of channels (CH1 to CH4 in FIG. 32) included in the second memory device 600D through the third internal input and output line MIO3. The third memory controller 521D-1 may output the third command CMD3 and the third data DATA3 that control an operation of the first group of channels (CH1 to CH4 in FIG. 32) included in the second memory device 600D. The third memory controller 521D-1 may receive the third data DATA3 from the third base interface area 521D-2 and output the third data DATA3 to the third internal input and output line MIO3.

The third base interface area 521D-2 may be electrically connected to the third memory controller 521D-1. The third base interface area 521D-2 may receive the third command CMD3 and the third data DATA3 from the third memory controller 521D-1. The third base interface area 521D-2 may output the third command CMD3 and the third data DATA3 to the third base TSV area 521D-3 by adjusting the input and output sequence of the third command CMD3 and the third data DATA3. The third base interface area 521D-2 may receive the third data DATA3 from the third base TSV area 521D-3 and output the third data DATA3 to the third memory controller 521D-1.

The third base TSV area 521D-3 may be electrically connected to the third base interface area 521D-2. The third base TSV area 521D-3 may receive the third command CMD3 and the third data DATA3 from the third base interface area 521D-2. The third base TSV area 521D-3 may output the third command CMD3 and the third data DATA3 to a third core TSV area (3^{rd} CORE TSV PHY) (610D in FIG. 32) included in the second memory device 600D through a plurality of TSVs. The third base TSV area 521D-3 may receive the third data DATA3 from the second memory device 600D and output the third data DATA3 to the third base interface area 521D-2.

The fourth memory controller 522D-1 may be electrically connected to the fourth internal input and output line MIO4. The fourth memory controller 522D-1 may receive the fourth command CMD4 and the fourth data DATA4 that control an operation of a second group of channels (CH5 to CH8 in FIG. 32) included in the second memory device 600D through the fourth internal input and output line MIO4. The fourth memory controller 522D-1 may output the fourth command CMD4 and the fourth data DATA4 that control an operation of the second group of channels (CH5 to CH8 in FIG. 32) included in the second memory device 600D. The fourth memory controller 522D-1 may receive the fourth data DATA4 from the fourth base interface area 522D-2 and output the fourth data DATA4 to the fourth internal input and output line MIO4.

The fourth base interface area 522D-2 may be electrically connected to the fourth memory controller 522D-1. The fourth base interface area 522D-2 may receive the fourth command CMD4 and the fourth data DATA4 from the fourth memory controller 522D-1. The fourth base interface area 522D-2 may output the fourth command CMD4 and the fourth data DATA4 to the fourth base TSV area 522D-3 by adjusting the input and output sequence of the fourth command CMD4 and the fourth data DATA4. The fourth base interface area 522D-2 may receive the fourth data DATA4 from the fourth base TSV area 522D-3 and output the fourth data DATA4 to the fourth memory controller 522D-1.

The fourth base TSV area 522D-3 may be electrically connected to the fourth base interface area 522D-2. The fourth base TSV area 522D-3 may receive the fourth command CMD4 and the fourth data DATA4 from the fourth base interface area 522D-2. The fourth base TSV area 522D-3 may output the fourth command CMD4 and the fourth data DATA4 to a fourth core TSV area (4^{th} CORE TSV PHY) (620D in FIG. 32) included in the second memory device 600D through a plurality of TSVs. The fourth base TSV area 522D-3 may receive the second data DATA2 from the second memory device 600D and output the second data DATA2 to the fourth base interface area 522D-2.

The sixth area 530D may include a fourth internal interface area (4^{th} INT IF) 531D and a fourth physical area 532D.

The fourth internal interface area 531D may receive the third command CMD3 and the third data DATA3 from the third internal input and output line MIO3. The fourth internal interface area 531D may receive the fourth command CMD4 and the fourth data DATA4 from the fourth internal input and output line MIO4. The fourth internal interface area 531D may output the third command CMD3, the third data DATA3, the fourth command CMD4, and the fourth data DATA4 to the fourth physical area 532D by adjusting the input and output sequence of the third command CMD3, the third data DATA3, the fourth command CMD4, and the fourth data DATA4. The fourth internal interface area 531D may receive the third data DATA3 from the fourth physical area 532D and output the third data DATA3 to the third internal interface area 512D through the third internal input and output line MIO3. The fourth internal interface area 531D may receive the fourth data DATA4 from the fourth physical area 532D and output the fourth data DATA4 to the third internal interface area 512D through the fourth internal input and output line MIO4. The fourth internal interface area 531D may be an interface that defines the timing and sequence of signals transmitted between the physical layer (PHY) and internal circuits and inputs and outputs the signals. The fourth internal interface area 531D may be implemented as a network-on-chip (NoC).

The fourth physical area 532D may include twenty-fifth to thirty-second physical layers 532D-1 to 532D-8. The fourth physical area 532D may receive the third command CMD3, the third data DATA3, the fourth command CMD4, and the fourth data DATA4 from the fourth internal interface area 531D through the twenty-fifth to thirty-second physical layers 532D-1 to 532D-8. The fourth physical area 532D may output the third command CMD3, the third data DATA3, the fourth command CMD4, and the fourth data DATA4 to an external device. The fourth physical area 532D may receive data from the external device. At least two physical layers, among the twenty-fifth to thirty-second physical layers 532D-1 to 532D-8, may be set as one group. For example, the twenty-fifth physical layer 532D-1, the twenty-sixth physical layer 532D-2, the twenty-seventh physical layer 532D-3, and the twenty-eighth physical layer 532D-4 may be set as a first group of physical layers. The twenty-ninth physical layer 532D-5, the thirtieth physical layer 532D-6, the thirty-first physical layer 532D-7, and the thirty-second physical layer 532D-8 may be set as a second group of physical layers. Furthermore, the twenty-fifth physical layer 532D-1, the twenty-seventh physical layer 532D-3, the twenty-ninth physical layer 532D-5, and the thirty-first physical layer 532D-7 may be set as a first group of physical layers. The twenty-sixth physical layer 532D-2, the twenty-eighth physical layer 532D-4, the thirtieth physical layer 532D-6, and the thirty-second physical layer 532D-8 may be set as a second group of physical layers. The twenty-fifth to thirty-second physical layers 532D-1 to 532D-8 may respectively be a physical layer (PHY) that is responsible for the generation, transmission, reception, and physical connection of signals and data between an external device, the first control device 100D, and another HBM device.

The twenty-fifth to thirty-second physical layers 532D-1 to 532D-8 may be selectively activated. The twenty-fifth to thirty-second physical layers 532D-1 to 532D-8 may be selectively activated under the control of the process circuit 10D. The twenty-fifth to thirty-second physical layers 532D-1 to 532D-8 may be selectively activated by the setting of a mode register set (MRS) included in the HBM device. The twenty-fifth to thirty-second physical layers 532D-1 to 532D-8 may be selectively activated by a device, such as IEEE1500 included in the HBM device. The twenty-fifth to thirty-second physical layers 532D-1 to 532D-8 may be selectively activated based on the bandwidth of data.

For example, the bandwidth of data when the twenty-fifth to twenty-eighth physical layers 532D-1 to 532D-4 are activated and the twenty-ninth to thirty-second physical layers 532D-5 to 532D-8 are deactivated may be set as a bandwidth that is ½ of the bandwidth of data when the twenty-fifth to thirty-second physical layers 532D-1 to 532D-8 are activated. The bandwidth of data when the twenty-fifth and twenty-sixth physical layers 532D-1 and 532D-2 are activated and the twenty-seventh to thirty-second physical layers 532D-3 to 532D-8 are deactivated may be set as a bandwidth that is ¼ of the bandwidth of data when the twenty-fifth to thirty-second physical layers 532D-1 to 532D-8 are activated.

The fourth physical area 532D may output the third command CMD3, the third data DATA3, the fourth command CMD4, and the fourth data DATA4 that are input from the fourth internal interface area 531D, to an external device or still another HBM device. The fourth physical area 532D may generate the third data DATA3 and the fourth data DATA4 by receiving fifth data and sixth data from an external device or still another HBM device. The fourth physical area 532D may output the third data DATA3 and the fourth data DATA4 to the fourth internal interface area 531D.

The second memory device 600D may be vertically stacked on the fifth area 520D of the second control device 500D. The second memory device 600D may be disposed in the fifth predetermined area. The second memory device 600D may include a plurality of core dies that is vertically stacked. The second memory device 600D may receive the third command CMD3 and the third data DATA3 from the third base TSV area 521D-3. The second memory device 600D may perform an internal operation based on the third command CMD3 and the third data DATA3. The second memory device 600D may store the third data DATA3 in the plurality of core dies after the start of a write operation based on the third command CMD3. The second memory device 600D may output the third data DATA3 stored in the plurality of core dies to the third base TSV area 521D-3 after the start of a read operation based on the third command CMD3. The second memory device 600D may receive the fourth command CMD4 and the fourth data DATA4 from the fourth base TSV area 522D-3. The second memory device 600D may perform an internal operation based on the fourth command CMD4 and the fourth data DATA4. The second memory device 600D may store the fourth data DATA4 in the plurality of core dies after the start of a write operation based on the fourth command CMD4. The second memory device 600D may output the fourth data DATA4 stored in the plurality of core dies to the fourth base TSV area 522D-3 after the start of a read operation based on the fourth command CMD4.

The third dummy die group 700D may be vertically stacked on the fourth area 510D of the second control device 500D. The third dummy die group 700D may be disposed in the fourth predetermined area. The third dummy die group 700D may be implemented by stacking a plurality of dummy dies (not illustrated). The third dummy die group 700D may have the same height as the second memory device 600D. The plurality of dummy dies (not illustrated) included in the third dummy die group 700D may have the same height as the plurality of core dies (not illustrated) included in the second memory device 600D. The third dummy die group 700D may be one dummy die according to an embodiment. The fourth predetermined area in which the third dummy die group 700D is formed may be an empty space according to an embodiment. The third dummy die group 700D can discharge heat generated from the fourth area 510D of the second control device 500D. The plurality of dummy dies (not illustrated) included in the third dummy die group 700D may be connected through a plurality of TSVs and a plurality of micro bump pads so that heat can be easily discharged.

The fourth dummy die group 800D may be vertically stacked on the sixth area 530D of the second control device 500D. The fourth dummy die group 800D may be disposed in the sixth predetermined area. The fourth dummy die group 800D may be implemented by stacking a plurality of dummy dies (not illustrated). The fourth dummy die group 800D may have the same height as the second memory device 600D. The plurality of dummy dies (not illustrated) included in the fourth dummy die group 800D may have the same height as the plurality of core dies (not illustrated) included in the second memory device 600D. The fourth dummy die group 800D may be one dummy die according to an embodiment. The sixth predetermined area in which the fourth dummy die group 800D is formed may be an empty space according to an embodiment. The fourth dummy die group 800D can discharge heat generated from the sixth area 530D of the second control device 500D. The plurality of dummy dies (not illustrated) included in the fourth dummy die group 800D may be connected through a plurality of TSVs and a plurality of micro bump pads so that heat can be easily discharged.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

FIG. 32 is a block diagram illustrating a construction of the first memory device 200D and the second memory device 600D according to an embodiment of the present disclosure.

The first memory device 200D may include the first to eighth channels CH1 to CH8, the first core TSV area 210D, and the second core TSV area 220D.

The first to eighth channels CH1 to CH8 may receive the first command CMD1, the first data DATA1, the second command CMD2, and the second data DATA2 by independently performing internal operations. The first to eighth channels CH1 to CH8 may store the first data DATA1 and the second data DATA2 after the start of a write operation of an internal operation based on the first command CMD1 and the second command CMD2. The first to eighth channels CH1 to CH8 may output the first data DATA1 and the second data DATA2 after the start of a read operation of an internal operation based on the first command CMD1 and the second command CMD2.

The first to fourth channels CH1 to CH4 may be electrically connected to the first core TSV area 210D. The first to fourth channels CH1 to CH4 may receive the first command CMD1 and the first data DATA1 from the first core TSV area 210D. The first to fourth channels CH1 to CH4 may output the first data DATA1 to the first core TSV area 210D. The first to fourth channels CH1 to CH4 may respectively store the first data DATA1 after the start of a write operation of an internal operation based on the first command CMD1. The first to fourth channels CH1 to CH4 may respectively output the first data DATA1 after the start of a read operation of an internal operation based on the first command CMD1. The first to fourth channels CH1 to CH4 may be set as a first group of channels.

The fifth to eighth CH5 to CH8 may be electrically connected to the second core TSV area 220D. The fifth to eighth CH5 to CH8 may respectively receive the second command CMD2 and the second data DATA2 from the second core TSV area 220D. The fifth to eighth CH5 to CH8 may output the second data DATA2 to the second core TSV area 220D. The fifth to eighth CH5 to CH8 may respectively store the second data DATA2 after the start of a write operation of an internal operation based on the second command CMD2. The fifth to eighth CH5 to CH8 may respectively output the second data DATA2 after the start of a read operation of an internal operation based on the second command CMD2. The fifth to eighth CH5 to CH8 may be set as a second group of channels.

The first to fourth channels CH1 to CH4 may be disposed in a first edge area TOP of the first memory device 200D. The fifth to eighth CH5 to CH8 may be disposed in a second edge area BOTTOM of the first memory device 200D. The first edge area TOP may be disposed in a first direction D1 from a central area CENTER of the first memory device 200D. The second edge area BOTTOM may be disposed in a second direction D2 from the central area CENTER of the first memory device 200D. The first edge area TOP may be set as an upper area of the first memory device 200D in a Y axis. The second edge area BOTTOM may be set as a lower area of the first memory device 200D in the Y axis.

The first core TSV area 210D may be electrically connected to the first base TSV area 121D-3 of the first control device 100D. The first core TSV area 210D may receive the first command CMD1 and the first data DATA1 from the first base TSV area 121D-3. The first core TSV area 210D may receive the first command CMD1 and the first data DATA1 through a plurality of TSVs. The first core TSV area 210D may output the first command CMD1 and the first data DATA1 to the first to fourth channels CH1 to CH4. The first core TSV area 210D may receive the first data DATA1 from the first to fourth channels CH1 to CH4 and output the first data DATA1 to the first base TSV area 121D-3. The first core TSV area 210D may be disposed in the central area CENTER.

The second core TSV area 220D may be electrically connected to the second base TSV area 122D-3 of the first control device 100D. The second core TSV area 220D may receive the second command CMD2 and the second data DATA2 from the second base TSV area 122D-3. The second core TSV area 220D may receive the second command CMD2 and the second data DATA2 through a plurality of TSVs. The second core TSV area 220D may output the second command CMD2 and the second data DATA2 to the fifth to eighth CH5 to CH8. The second core TSV area 220D may receive the second data DATA2 from the fifth to eighth CH5 to CH8 and output the second data DATA2 to the second base TSV area 122D-3. The second core TSV area 220D may be disposed in the central area CENTER.

The first to eighth channels CH1 to CH8, the first core TSV area 210D, and the second core TSV area 220D included in the first memory device 200D may be disposed at various locations according to an embodiment.

The first memory device 200D may be disposed in a left area LEFT in an X axis.

The second memory device 600D may include the first to eighth channels CH1 to CH8, the third core TSV area 610D, and the fourth core TSV area 620D.

The first to eighth channels CH1 to CH8 may receive the third command CMD3, the third data DATA3, the fourth command CMD4, and the fourth data DATA4 by independently performing internal operations. The first to eighth channels CH1 to CH8 may respectively store the third data DATA3 and the fourth data DATA4 after the start of a write operation of an internal operation based on the third command CMD3 and the fourth command CMD4. The first to eighth channels CH1 to CH8 may respectively output the third data DATA3 and the fourth data DATA4 after the start of a read operation of an internal operation based on the third command CMD3 and the fourth command CMD4.

The first to fourth channels CH1 to CH4 may be electrically connected to the third core TSV area 610D. The first to fourth channels CH1 to CH4 may respectively receive the third command CMD3 and the third data DATA3 from the third core TSV area 610D. The first to fourth channels CH1 to CH4 may output the third data DATA3 to the third core TSV area 610D. The first to fourth channels CH1 to CH4 may respectively store the third data DATA3 after the start of a write operation of an internal operation based on the third command CMD3. The first to fourth channels CH1 to CH4 may respectively output the third data DATA3 after the start of a read operation of an internal operation based on the third command CMD3. The first to fourth channels CH1 to CH4 may be set as a first group of channels.

The fifth to eighth CH5 to CH8 may be electrically connected to the fourth core TSV area 620D. The fifth to eighth CH5 to CH8 may receive the fourth command CMD4 and the fourth data DATA4 from the fourth core TSV area 620D. The fifth to eighth CH5 to CH8 may output the fourth data DATA4 to the fourth core TSV area 620D. The fifth to eighth CH5 to CH8 may respectively store the fourth data DATA4 after the start of a write operation of an internal operation based on the fourth command CMD4. The fifth to eighth CH5 to CH8 may respectively output the fourth data DATA4 after the start of a read operation of an internal operation based on the fourth command CMD4. The fifth to eighth CH5 to CH8 may be set as a second group of channels.

The first to fourth channels CH1 to CH4 may be disposed in a first edge area TOP of the second memory device 600D. The fifth to eighth CH5 to CH8 may be disposed in a second edge area BOTTOM of the second memory device 600D. The first edge area TOP may be disposed in the first direction D1 from a central area CENTER of the second memory device 600D. The second edge area BOTTOM may be disposed in the second direction D2 from the central area CENTER of the second memory device 600D. The first edge area TOP may be set as an upper area of the second memory device 600D in the Y axis. The second edge area BOTTOM may be set as a lower area of the second memory device 600D in the Y axis.

The third core TSV area 610D may be electrically connected to the third base TSV area 521D-3 of the second control device 500D. The third core TSV area 610D may receive the third command CMD3 and the third data DATA3 from the third base TSV area 521D-3. The third core TSV area 610D may receive the third command CMD3 and the third data DATA3 through a plurality of TSVs. The third core TSV area 610D may output the third command CMD3 and the third data DATA3 to the first to fourth channels CH1 to CH4. The third core TSV area 610D may receive the third data DATA3 from the first to fourth channels CH1 to CH4 and output the third data DATA3 to the third base TSV area 521D-3. The third core TSV area 610D may be disposed in the central area CENTER.

The fourth core TSV area 620D may be electrically connected to the fourth base TSV area 522D-3 of the second control device 500D. The fourth core TSV area 620D may receive the fourth command CMD4 and the fourth data DATA4 from the fourth base TSV area 522D-3. The fourth core TSV area 620D may receive the fourth command CMD4 and the fourth data DATA4 through a plurality of TSVs. The fourth core TSV area 620D may output the fourth command CMD4 and the fourth data DATA4 to the fifth to eighth CH5 to CH8. The fourth core TSV area 620D may receive the fourth data DATA4 from the fifth to eighth CH5 to CH8 and output the fourth data DATA4 to the fourth base TSV area 522D-3. The fourth core TSV area 620D may be disposed in the central area CENTER.

The first to eighth channels CH1 to CH8, the third core TSV area 610D, and the fourth core TSV area 620D included in the second memory device 600D may be disposed at various locations according to an embodiment.

The second memory device 600D may be disposed in a right area RIGHT in the X axis.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

The third HBM device 23D and the fourth HBM device 24D illustrated in FIG. 30 have the same constructions and perform the same operations as the first HBM device 21D and the second HBM device 22D, respectively, and thus detailed descriptions thereof are omitted. The fifth HBM device 25D and the sixth HBM device 26D illustrated in FIG. 30 have the same constructions and perform the same operations as the first HBM device 21D and the second HBM device 22D, respectively, and thus detailed descriptions thereof are omitted. The seventh HBM device 27D and the eighth HBM device 28D illustrated in FIG. 30 have the same constructions and perform the same operations as the first HBM device 21D and the second HBM device 22D, respectively, and thus detailed descriptions thereof are omitted.

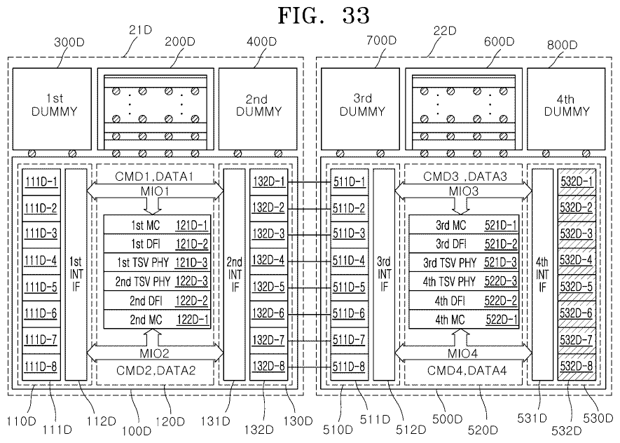

FIG. 33 is a diagram for describing operations of the first HBM device 21D and the second HBM device 22D according to an embodiment of the present disclosure. The operations of the first HBM device 21D and the second HBM device 22D are described with reference to FIG. 33. In this case, a case in which the twenty-fifth to thirty-second physical layers 532D-1 to 532D-8 included in the fourth physical area 532D are deactivated is described as follows as an example.

First, an operation of the first HBM device 21D is described as follows.

The first physical area 111D of the first control device 100D inputs and outputs the first command CMD1, the first data DATA1, the second command CMD2, and the second data DATA2 when the first to eighth physical layers 111D-1 to 111D-8 are activated.

The first internal interface area 112D of the first control device 100D receives the first command CMD1, the first data DATA1, the second command CMD2, and the second data DATA2 from the first physical area 111D. The first internal interface area 112D inputs and outputs the first command CMD1, the first data DATA1, the second command CMD2, and the second data DATA2 through the first and second internal input and output lines MIO1 and MIO2.

The first memory controller 121D-1, first base interface area 121D-2, and first base TSV area 121D-3 of the first control device 100D input and output the first command CMD1 and the first data DATA1 through the first internal input and output line MIO1. The second memory controller 122D-1, the second base interface area 122D-2, and the second base TSV area 122D-3 input and output the second command CMD2 and the second data DATA2 through the second internal input and output line MIO2.

The first memory device 200D disposed in the second predetermined area inputs and outputs the first data DATA1 by performing an internal operation based on the first command CMD1. The first memory device 200D inputs and outputs the second data DATA2 by performing an internal operation based on the second command CMD2.

The second internal interface area 131D of the first control device 100D inputs and outputs the first command CMD1, the first data DATA1, the second command CMD2, and the second data DATA2 through the first and second internal input and output lines MIO1 and MIO2.

The second physical area 132D of the first control device 100D inputs and outputs the first command CMD1, the first data DATA1, the second command CMD2, and the second data DATA2 when the ninth to sixteenth physical layers 132D-1 to 132D-8 are activated.

The first dummy die group 300D disposed in the first predetermined area discharges heat generated from the first area 110D of the first control device 100D.

The second dummy die group 400D disposed in the third predetermined area discharges heat generated from the third area 130D of the first control device 100D.

That is, the first HBM device 21D inputs and outputs the first data DATA1 and the second data DATA2 respectively having a first bandwidth when the first to eighth physical layers 111D-1 to 111D-8 and the ninth to sixteenth physical layers 132D-1 to 132D-8 are activated.

Next, an operation of the second HBM device 22D is described as follows.

The third physical area 511D of the second control device 500D receives the first command CMD1, the first data DATA1, the second command CMD2, and the second data DATA2 through the ninth to sixteenth physical layers 132D-1 to 132D-8 when the seventeenth to twenty-fourth physical layers 511D-1 to 511D-8 are activated. The third physical area 511D generates the third command CMD3, the third data DATA3, the fourth command CMD4, and the fourth data DATA4 based on the first command CMD1, the first data DATA1, the second command CMD2, and the second data DATA2 when the seventeenth to twenty-fourth physical layers 511D-1 to 511D-8 are activated. The third physical area 511D inputs and outputs the third command CMD3, the third data DATA3, the fourth command CMD4, and the fourth data DATA4 through the seventeenth to twenty-fourth physical layers 511D-1 to 511D-8.

The third internal interface area 512D of the second control device 500D receives the third command CMD3, the third data DATA3, the fourth command CMD4, and the fourth data DATA4 from the third physical area 511D. The third internal interface area 512D inputs and outputs the third command CMD3, the third data DATA3, the fourth command CMD4, and the fourth data DATA4 through the third and fourth internal input and output lines MIO3 and MIO4.

The third memory controller 521D-1, third base interface area 521D-2, and third base TSV area 521D-3 of the second control device 500D input and output the third command CMD3 and the third data DATA1 through the third internal input and output line MIO3. The fourth memory controller 522D-1, the fourth base interface area 522D-2, and the fourth base TSV area 522D-3 input and output the fourth command CMD4 and the fourth data DATA4 through the fourth internal input and output line MIO4.

The second memory device 600D disposed in the fifth predetermined area inputs and outputs the third data DATA3 by performing an internal operation based on the third command CMD3. The second memory device 600D inputs and outputs the fourth data DATA4 by performing an internal operation based on the fourth command CMD4.

The fourth internal interface area 531D of the second control device 500D inputs and outputs the third command CMD3, the third data DATA3, the fourth command CMD4, and the fourth data DATA4 through the third and fourth internal input and output lines MIO3 and MIO4.

The twenty-fifth to thirty-second physical layers 532D-1 to 532D-8 of the fourth physical area 532D of the second control device 500D are deactivated.

The third dummy die group 700D disposed in the fourth predetermined area discharges heat generated from the fourth area 510D of the second control device 500D.

The fourth dummy die group 800D disposed in the sixth predetermined area discharges heat generated from the sixth area 530D of the second control device 500D when inputting and outputting data as the second HBM device 22D is electrically connected to another HBM device and the twenty-fifth to thirty-second physical layers 532D-1 to 532D-8 of the fourth physical area 532D are activated.

That is, the second HBM device 22D inputs and outputs the third data DATA3 and the fourth data DATA4 respectively having a first bandwidth when the seventeenth to twenty-fourth physical layers 511D-1 to 511D-8 are activated.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

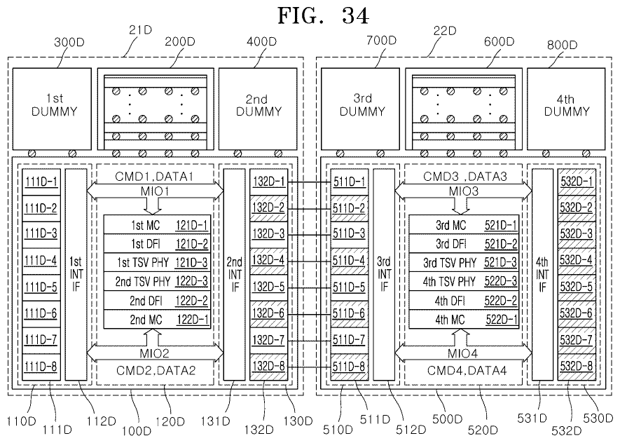

FIG. 34 is a diagram for describing operations of the first HBM device 21D and the second HBM device 22D according to an embodiment of the present disclosure. The operations of the first HBM device 21D and the second HBM device 22D are described with reference to FIG. 34. In this case, a case in which some physical layers, among the first and second groups of physical layers included in the second physical area 132D, some physical layers, among the third and fourth groups of physical layers included in the third physical area 511D, and the twenty-fifth to thirty-second physical layers 532D-1 to 532D-8 included in the fourth physical area 532D are deactivated is described as follows as an example.

First, an operation of the first HBM device 21D is described as follows.

The first physical area 111D of the first control device 100D inputs and outputs the first command CMD1, the first data DATA1, the second command CMD2, and the second data DATA2 when the first to eighth physical layers 111D-1 to 111D-8 are activated.

The first internal interface area 112D of the first control device 100D receives the first command CMD1, the first data DATA1, the second command CMD2, and the second data DATA2 from the first physical area 111D. The first internal interface area 112D inputs and outputs the first command CMD1, the first data DATA1, the second command CMD2, and the second data DATA2 through the first and second internal input and output lines MIO1 and MIO2.

The first memory controller 121D-1, first base interface area 121D-2, and first base TSV area 121D-3 of the first control device 100D input and output the first command CMD1 and the first data DATA1 through the first internal input and output line MIO1. The second memory controller 122D-1, the second base interface area 122D-2, and the second base TSV area 122D-3 input and output the second command CMD2 and the second data DATA2 through the second internal input and output line MIO2.

The first memory device 200D disposed in the second predetermined area inputs and outputs the first data DATA1 by performing an internal operation based on the first command CMD1. The first memory device 200D inputs and outputs the second data DATA2 by performing an internal operation based on the second command CMD2.

The second internal interface area 131D of the first control device 100D inputs and outputs the first command CMD1, the first data DATA1, the second command CMD2, and the second data DATA2 through the first and second internal input and output lines MIO1 and MIO2.

The second physical area 132D of the first control device 100D inputs and outputs the first command CMD1, the first data DATA1, the second command CMD2, and the second data DATA2 as some physical layers 132D-1 and 132D-3, among the first group of physical layers, are activated, some physical layers 132D-5 and 132D-7, among the second group of physical layers, are activated, some physical layers 132D-2 and 132D-4, among the first group of physical layers, are deactivated, and some physical layers 132D-6 and 132D-8, among the second group of physical layers, are deactivated.

The first dummy die group 300D disposed in the first predetermined area discharges heat generated from the first area 110D of the first control device 100D.

The second dummy die group 400D disposed in the third predetermined area discharges heat generated from the third area 130D of the first control device 100D.

That is, the first HBM device 21D inputs and outputs the first data DATA1 and the second data DATA2 respectively having a second bandwidth as the first to eighth physical layers 111D-1 to 111D-8, some physical layers 132D-1 and 132D-3, among the first group of physical layers, are activated, and some physical layers 132D-5 and 132D-7, among the second group of physical layers, are activated. The second bandwidth is set as a bandwidth that is ½ of the first bandwidth described with reference to FIG. 33.

Next, an operation of the second HBM device 22D is described as follows.

The third physical area 511D of the second control device 500D receives the first command CMD1, the first data DATA1, the second command CMD2, and the second data DATA2 as some physical layers 511D-1 and 511D-3, among the third group of physical layers, are activated, some physical layers 511D-5 and 511D-7, among the fourth group of physical layers, are activated, some physical layers 511D-2 and 511D-4, among the third group of physical layers, are deactivated, and some physical layers 511D-6 and 511D-8, among the fourth group of physical layers, are deactivated. The third physical area 511D generates the third command CMD3, the third data DATA3, the fourth command CMD4, and the fourth data DATA4, based on the first command CMD1, the first data DATA1, the second command CMD2, and the second data DATA2, as some physical layers 511D-1 and 511D-3, among the third group of physical layers, are activated and some physical layers 511D-5 and 511D-7, among the fourth group of physical layers, are activated. The third physical area 511D inputs and outputs the third command CMD3, the third data DATA3, the fourth command CMD4, and the fourth data DATA4 through some physical layers 511D-1 and 511D-3, among the third group of physical layers, and some physical layers 511D-5 and 511D-7, among the fourth group of physical layers.

The third internal interface area 512D of the second control device 500D receives the third command CMD3, the third data DATA3, the fourth command CMD4, and the fourth data DATA4 from the third physical area 511D. The third internal interface area 512D inputs and outputs the third command CMD3, the third data DATA3, the fourth command CMD4, and the fourth data DATA4 through the third and fourth internal input and output lines MIO3 and MIO4.

The third memory controller 521D-1, third base interface area 521D-2, and third base TSV area 521D-3 of the second control device 500D input and output the third command CMD3 and the third data DATA1 through the third internal input and output line MIO3. The fourth memory controller 522D-1, the fourth base interface area 522D-2, and the fourth base TSV area 522D-3 input and output the fourth command CMD4 and the fourth data DATA4 through the fourth internal input and output line MIO4.

The second memory device 600D disposed in the fifth predetermined area inputs and outputs the third data DATA3 by performing an internal operation based on the third command CMD3. The second memory device 600D inputs and outputs the fourth data DATA4 by performing an internal operation based on the fourth command CMD4.

The fourth internal interface area 531D of the second control device 500D inputs and outputs the third command CMD3, the third data DATA3, the fourth command CMD4, and the fourth data DATA4 through the third and fourth internal input and output lines MIO3 and MIO4.

The twenty-fifth to thirty-second physical layers 532D-1 to 532D-8 of the fourth physical area 532D of the second control device 500D are deactivated.

The third dummy die group 700D disposed in the fourth predetermined area discharges heat generated from the fourth area 510D of the second control device 500D.

The fourth dummy die group 800D disposed in the sixth predetermined area discharges heat generated from the sixth area 530D of the second control device 500D when inputting and outputting data as the second HBM device 22D is electrically connected to another HBM device and the twenty-fifth to thirty-second physical layers 532D-1 to 532D-8 of the fourth physical area 532D are activated.

That is, the second HBM device 22D inputs and outputs the third data DATA3 and the fourth data DATA4 respectively having a second bandwidth as some physical layers 511D-1 and 511D-3, among the third group of physical layers, are activated and some physical layers 511D-5 and 511D-7, among the fourth group of physical layers, are activated. The second bandwidth is set as a bandwidth that is ½ of the first bandwidth described with reference to FIG. 33.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

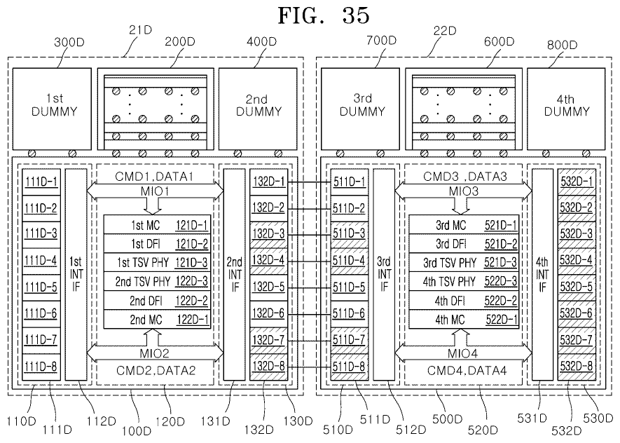

FIG. 35 is a diagram for describing operations of the first HBM device 21D and the second HBM device 22D according to an embodiment of the present disclosure. The operations of the first HBM device 21D and the second HBM device 22D are described with reference to FIG. 35. In this case, a case in which some physical layers, among the first and second groups of physical layers included in the second physical area 132D, some physical layers, among the third and fourth groups of physical layers included in the third physical area 511D, and the twenty-fifth to thirty-second physical layers 532D-1 to 532D-8 included in the fourth physical area 532D are deactivated is described as follows as an example.

First, an operation of the first HBM device 21D is described as follows.

The first physical area 111D of the first control device 100D inputs and outputs the first command CMD1, the first data DATA1, the second command CMD2, and the second data DATA2 when the first to eighth physical layers 111D-1 to 111D-8 are activated.

The first internal interface area 112D of the first control device 100D receives the first command CMD1, the first data DATA1, the second command CMD2, and the second data DATA2 from the first physical area 111D. The first internal interface area 112D inputs and outputs the first command CMD1, the first data DATA1, the second command CMD2, and the second data DATA2 through the first and second internal input and output lines MIO1 and MIO2.

The first memory controller 121D-1, first base interface area 121D-2, and first base TSV area 121D-3 of the first control device 100D input and output the first command CMD1 and the first data DATA1 through the first internal input and output line MIO1. The second memory controller 122D-1, the second base interface area 122D-2, and the second base TSV area 122D-3 input and output the second command CMD2 and the second data DATA2 through the second internal input and output line MIO2.

The first memory device 200D disposed in the second predetermined area inputs and outputs the first data DATA1 by performing an internal operation based on the first command CMD1. The first memory device 200D inputs and outputs the second data DATA2 by performing an internal operation based on the second command CMD2.

The second internal interface area 131D of the first control device 100D inputs and outputs the first command CMD1, the first data DATA1, the second command CMD2, and the second data DATA2 through the first and second internal input and output lines MIO1 and MIO2.

The second physical area 132D of the first control device 100D inputs and outputs the first command CMD1, the first data DATA1, the second command CMD2, and the second data DATA2 as some physical layers 132D-1 and 132D-2, among the first group of physical layers, are activated, some physical layers 132D-5 and 132D-6, among the second group of physical layers, are activated, some physical layers 132D-3 and 132D-4, among the first group of physical layers, are deactivated, and some physical layers 132D-7 and 132D-8, among the second group of physical layers, are deactivated.

The first dummy die group 300D disposed in the first predetermined area discharges heat generated from the first area 110D of the first control device 100D.

The second dummy die group 400D disposed in the third predetermined area discharges heat generated from the third area 130D of the first control device 100D.

That is, the first HBM device 21D inputs and outputs the first data DATA1 and the second data DATA2 respectively having a second bandwidth as the first to eighth physical layers 111D-1 to 111D-8 and some physical layers 132D-1, 132D-2, 132D-5, and 132D-6, among the first group of physical layers, are activated. The second bandwidth is set as a bandwidth that is ½ of the first bandwidth described with reference to FIG. 33.

Next, an operation of the second HBM device 22D is described as follows.

The third physical area 511D of the second control device 500D receives the first command CMD1, the first data DATA1, the second command CMD2, and the second data DATA2 as some physical layers 511D-1 and 511D-2, among the third group of physical layers, are activated, some physical layers 511D-5 and 511D-6, among the fourth group of physical layers, are activated, some physical layers 511D-3 and 511D-4, among the third group of physical layers, are deactivated, and some physical layers 511D-7 and 511D-8, among the fourth group of physical layers, are deactivated. The third physical area 511D generates the third command CMD3, the third data DATA3, the fourth command CMD4, and the fourth data DATA4, based on the first command CMD1, the first data DATA1, the second command CMD2, and the second data DATA2, as some physical layers 511D-1 and 511D-2, among the third group of physical layers, are activated and some physical layers 511D-5 and 511D-6, among the fourth group of physical layers, are activated. The third physical area 511D inputs and outputs the third command CMD3, the third data DATA3, the fourth command CMD4, and the fourth data DATA4 through some physical layers 511D-1 and 511D-2, among the third group of physical layers, and some physical layers 511D-5 and 511D-6, among the fourth group of physical layers.

The third internal interface area 512D of the second control device 500D receives the third command CMD3, the third data DATA3, the fourth command CMD4, and the fourth data DATA4 from the third physical area 511D. The third internal interface area 512D inputs and outputs the third command CMD3, the third data DATA3, the fourth command CMD4, and the fourth data DATA4 through the third and fourth internal input and output lines MIO3 and MIO4.

The third memory controller 521D-1, third base interface area 521D-2, and third base TSV area 521D-3 of the second control device 500D input and output the third command CMD3 and the third data DATA1 through the third internal input and output line MIO3. The fourth memory controller 522D-1, the fourth base interface area 522D-2, and the fourth base TSV area 522D-3 input and output the fourth command CMD4 and the fourth data DATA4 through the fourth internal input and output line MIO4.

The second memory device 600D disposed in the fifth predetermined area inputs and outputs the third data DATA3 by performing an internal operation based on the third command CMD3. The second memory device 600D inputs and outputs the fourth data DATA4 by performing an internal operation based on the fourth command CMD4.

The fourth internal interface area 531D of the second control device 500D inputs and outputs the third command CMD3, the third data DATA3, the fourth command CMD4, and the fourth data DATA4 through the third and fourth internal input and output lines MIO3 and MIO4.

The twenty-fifth to thirty-second physical layers 532D-1 to 532D-8 of the fourth physical area 532D of the second control device 500D are deactivated.

The third dummy die group 700D disposed in the fourth predetermined area discharges heat generated from the fourth area 510D of the second control device 500D.

The fourth dummy die group 800D disposed in the sixth predetermined area discharges heat generated from the sixth area 530D of the second control device 500D when inputting and outputting data as the second HBM device 22D is electrically connected to another HBM device and the twenty-fifth to thirty-second physical layers 532D-1 to 532D-8 of the fourth physical area 532D are activated.

That is, the second HBM device 22D inputs and outputs the third data DATA3 and the fourth data DATA4 respectively having a second bandwidth as some physical layers 511D-1 and 511D-2, among the third group of physical layers, are activated and some physical layers 511D-5 and 511D-6, among the fourth group of physical layers, are activated. The second bandwidth is set as a bandwidth that is ½ of the first bandwidth described with reference to FIG. 33.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

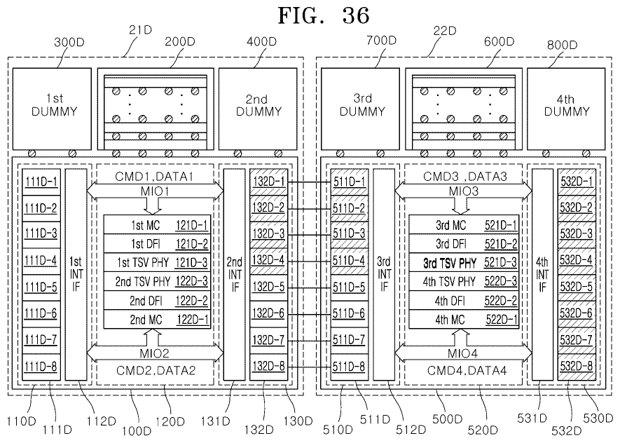

FIG. 36 is a diagram for describing operations of the first HBM device 21D and the second HBM device 22D according to an embodiment of the present disclosure. The operations of the first HBM device 21D and the second HBM device 22D are described with reference to FIG. 36. In this case, a case in which the first group of physical layers included in the second physical area 132D, the third group of physical layers included in the third physical area 511D, and the twenty-fifth to thirty-second physical layers 532D-1 to 532D-8 included in the fourth physical area 532D are deactivated is described as follows as an example.

First, an operation of the first HBM device 21D is described as follows.

The first physical area 111D of the first control device 100D inputs and outputs the first command CMD1, the first data DATA1, the second command CMD2, and the second data DATA2 when the first to eighth physical layers 111D-1 to 111D-8 are activated.

The first internal interface area 112D of the first control device 100D receives the first command CMD1, the first data DATA1, the second command CMD2, and the second data DATA2 from the first physical area 111D. The first internal interface area 112D inputs and outputs the first command CMD1, the first data DATA1, the second command CMD2, and the second data DATA2 through the first and second internal input and output lines MIO1 and MIO2.

The first memory controller 121D-1, first base interface area 121D-2, and first base TSV area 121D-3 of the first control device 100D input and output the first command CMD1 and the first data DATA1 through the first internal input and output line MIO1. The second memory controller 122D-1, the second base interface area 122D-2, and the second base TSV area 122D-3 input and output the second command CMD2 and the second data DATA2 through the second internal input and output line MIO2.

The first memory device 200D disposed in the second predetermined area inputs and outputs the first data DATA1 by performing an internal operation based on the first command CMD1. The first memory device 200D inputs and outputs the second data DATA2 by performing an internal operation based on the second command CMD2.

The second internal interface area 131D of the first control device 100D inputs and outputs the first command CMD1, the first data DATA1, the second command CMD2, and the second data DATA2 through the first and second internal input and output lines MIO1 and MIO2.

The second physical area 132D of the first control device 100D inputs and outputs the first command CMD1, the first data DATA1, the second command CMD2, and the second data DATA2 as the second group of physical layers 132D-5, 132D-6, 132D-7, and 132D-8 is activated and the first group of physical layers 132D-1, 132D-2, 132D-3, and 132D-4 is deactivated.

The first dummy die group 300D disposed in the first predetermined area discharges heat generated from the first area 110D of the first control device 100D.

The second dummy die group 400D disposed in the third predetermined area discharges heat generated from the third area 130D of the first control device 100D.

That is, the first HBM device 21D inputs and outputs the first data DATA1 and the second data DATA2 respectively having a second bandwidth as the first to eighth physical layers 111D-1 to 111D-8 and the second group of physical layers 132D-5, 132D-6, 132D-7, and 132D-8 are activated. The second bandwidth is set as a bandwidth that is ½ of the first bandwidth described with reference to FIG. 33.

Next, an operation of the second HBM device 22D is described as follows.

The third physical area 511D of the second control device 500D receives the first command CMD1, the first data DATA1, the second command CMD2, and the second data DATA2 as the fourth group of physical layers 511D-5, 511D-6, 511D-7, and 511D-8 is activated and the third group of physical layers 511D-1, 511D-2, 511D-3, and 511D-4 is deactivated. The third physical area 511D generates the third command CMD3, the third data DATA3, the fourth command CMD4, and the fourth data DATA4, based on the first command CMD1, the first data DATA1, the second command CMD2, and the second data DATA2, as the fourth group of physical layers 511D-5, 511D-6, 511D-7, and 511D-8 is activated. The third physical area 511D inputs and outputs the third command CMD3, the third data DATA3, the fourth command CMD4, and the fourth data DATA4 through the fourth group of physical layers 511D-5, 511D-6, 511D-7, and 511D-8.

The third internal interface area 512D of the second control device 500D receives the third command CMD3, the third data DATA3, the fourth command CMD4, and the fourth data DATA4 from the third physical area 511D. The third internal interface area 512D inputs and outputs the third command CMD3, the third data DATA3, the fourth command CMD4, and the fourth data DATA4 through the third and fourth internal input and output lines MIO3 and MIO4.

The third memory controller 521D-1, third base interface area 521D-2, and third base TSV area 521D-3 of the second control device 500D input and output the third command CMD3 and the third data DATA1 through the third internal input and output line MIO3. The fourth memory controller 522D-1, the fourth base interface area 522D-2, and the fourth base TSV area 522D-3 input and output the fourth command CMD4 and the fourth data DATA4 through the fourth internal input and output line MIO4.

The second memory device 600D disposed in the fifth predetermined area inputs and outputs the third data DATA3 by performing an internal operation based on the third command CMD3. The second memory device 600D inputs and outputs the fourth data DATA4 by performing an internal operation based on the fourth command CMD4.

The fourth internal interface area 531D of the second control device 500D inputs and outputs the third command CMD3, the third data DATA3, the fourth command CMD4, and the fourth data DATA4 through the third and fourth internal input and output lines MIO3 and MIO4.

The twenty-fifth to thirty-second physical layers 532D-1 to 532D-8 of the fourth physical area 532D of the second control device 500D are deactivated.

The third dummy die group 700D disposed in the fourth predetermined area discharges heat generated from the fourth area 510D of the second control device 500D.

The fourth dummy die group 800D disposed in the sixth predetermined area discharges heat generated from the sixth area 530D of the second control device 500D when inputting and outputting data as the second HBM device 22D is electrically connected to another HBM device and the twenty-fifth to thirty-second physical layers 532D-1 to 532D-8 of the fourth physical area 532D are activated.

That is, the second HBM device 22D inputs and outputs the third data DATA3 and the fourth data DATA4 respectively having a second bandwidth as the fourth group of physical layers 511D-5, 511D-6, 511D-7, and 511D-8 is activated. The second bandwidth is set as a bandwidth that is ½ of the first bandwidth described with reference to FIG. 33.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

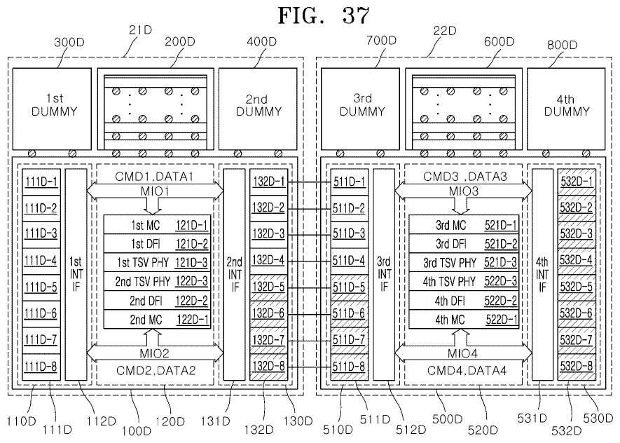

FIG. 37 is a diagram for describing operations of the first HBM device 21D and the second HBM device 22D according to an embodiment of the present disclosure. The operations of the first HBM device 21D and the second HBM device 22D are described with reference to FIG. 37. In this case, a case in which the second group of physical layers included in the second physical area 132D, the fourth group of physical layers included in the third physical area 511D, and the twenty-fifth to thirty-second physical layers 532D-1 to 532D-8 included in the fourth physical area 532D are deactivated is described as follows as an example.

First, an operation of the first HBM device 21D is described as follows.

The first physical area 111D of the first control device 100D inputs and outputs the first command CMD1, the first data DATA1, the second command CMD2, and the second data DATA2 when the first to eighth physical layers 111D-1 to 111D-8 are activated.

The first internal interface area 112D of the first control device 100D receives the first command CMD1, the first data DATA1, the second command CMD2, and the second data DATA2 from the first physical area 111D. The first internal interface area 112D inputs and outputs the first command CMD1, the first data DATA1, the second command CMD2, and the second data DATA2 through the first and second internal input and output lines MIO1 and MIO2.

The first memory controller 121D-1, first base interface area 121D-2, and first base TSV area 121D-3 of the first control device 100D input and output the first command CMD1 and the first data DATA1 through the first internal input and output line MIO1. The second memory controller 122D-1, the second base interface area 122D-2, and the second base TSV area 122D-3 input and output the second command CMD2 and the second data DATA2 through the second internal input and output line MIO2.

The first memory device 200D disposed in the second predetermined area inputs and outputs the first data DATA1 by performing an internal operation based on the first command CMD1. The first memory device 200D inputs and outputs the second data DATA2 by performing an internal operation based on the second command CMD2.

The second internal interface area 131D of the first control device 100D inputs and outputs the first command CMD1, the first data DATA1, the second command CMD2, and the second data DATA2 through the first and second internal input and output lines MIO1 and MIO2.

The second physical area 132D of the first control device 100D inputs and outputs the first command CMD1, the first data DATA1, the second command CMD2, and the second data DATA2 as the first group of physical layers 132D-1, 132D-2, 132D-3, and 132D-4 is activated and the second group of physical layers 132D-5, 132D-6, 132D-7, and 132D-8 is deactivated.

The first dummy die group 300D disposed in the first predetermined area discharges heat generated from the first area 110D of the first control device 100D.

The second dummy die group 400D disposed in the third predetermined area discharges heat generated from the third area 130D of the first control device 100D.

That is, the first HBM device 21D inputs and outputs the first data DATA1 and the second data DATA2 respectively having a second bandwidth as the first to eighth physical layers 111D-1 to 111D-8 and the first group of physical layers 132D-1, 132D-2, 132D-3, and 132D-4 are activated. The second bandwidth is set as a bandwidth that is ½ of the first bandwidth described with reference to FIG. 33.

Next, an operation of the second HBM device 22D is described as follows.

The third physical area 511D of the second control device 500D receives the first command CMD1, the first data DATA1, the second command CMD2, and the second data DATA2 as the third group of physical layers 511D-1, 511D-2, 511D-3, and 511D-4 is activated and the fourth group of physical layers 511D-5, 511D-6, 511D-7, and 511D-8 is deactivated. The third physical area 511D generates the third command CMD3, the third data DATA3, the fourth command CMD4, and the fourth data DATA4, based on the first command CMD1, the first data DATA1, the second command CMD2, and the second data DATA2, as the third group of physical layers 511D-1, 511D-2, 511D-3, and 511D-4 is activated. The third physical area 511D inputs and outputs the third command CMD3, the third data DATA3, the fourth command CMD4, and the fourth data DATA4 through the third group of physical layers 511D-1, 511D-2, 511D-3, and 511D-4.

The third internal interface area 512D of the second control device 500D receives the third command CMD3, the third data DATA3, the fourth command CMD4, and the fourth data DATA4 from the third physical area 511D. The third internal interface area 512D inputs and outputs the third command CMD3, the third data DATA3, the fourth command CMD4, and the fourth data DATA4 through the third and fourth internal input and output lines MIO3 and MIO4.

The third memory controller 521D-1, third base interface area 521D-2, and third base TSV area 521D-3 of the second control device 500D input and output the third command CMD3 and the third data DATA1 through the third internal input and output line MIO3. The fourth memory controller 522D-1, the fourth base interface area 522D-2, and the fourth base TSV area 522D-3 input and output the fourth command CMD4 and the fourth data DATA4 through the fourth internal input and output line MIO4.

The second memory device 600D disposed in the fifth predetermined area inputs and outputs the third data DATA3 by performing an internal operation based on the third command CMD3. The second memory device 600D inputs and outputs the fourth data DATA4 by performing an internal operation based on the fourth command CMD4.

The fourth internal interface area 531D of the second control device 500D inputs and outputs the third command CMD3, the third data DATA3, the fourth command CMD4, and the fourth data DATA4 through the third and fourth internal input and output lines MIO3 and MIO4.

The twenty-fifth to thirty-second physical layers 532D-1 to 532D-8 of the fourth physical area 532D of the second control device 500D are deactivated.

The third dummy die group 700D disposed in the fourth predetermined area discharges heat generated from the fourth area 510D of the second control device 500D.

The fourth dummy die group 800D disposed in the sixth predetermined area discharges heat generated from the sixth area 530D of the second control device 500D when inputting and outputting data as the second HBM device 22D is electrically connected to another HBM device and the twenty-fifth to thirty-second physical layers 532D-1 to 532D-8 of the fourth physical area 532D are activated.

That is, the second HBM device 22D inputs and outputs the third data DATA3 and the fourth data DATA4 respectively having a second bandwidth as the third group of physical layers 511D-1, 511D-2, 511D-3, and 511D-4 is activated. The second bandwidth is set as a bandwidth that is ½ of the first bandwidth described with reference to FIG. 33.

As described above, the semiconductor system 9D according to an embodiment of the present disclosure can extend a data capacity that is used in an arithmetic operation because a plurality of HBM devices is electrically connected to different HBM devices and a plurality of HBM devices is electrically connected to the process circuit. In an embodiment, the semiconductor system 9D can rapidly perform an arithmetic operation by increasing the number of HBM devices electrically connected to the process circuit and performing the arithmetic operation. In an embodiment, the semiconductor system 9D can variously set the bandwidth of data by selectively activating a plurality of physical layers (PHY) included in HBM devices. In an embodiment, the semiconductor system 9D can reduce current consumption by selectively activating a plurality of physical layers (PHY) included in HBM devices based on the bandwidth of data.

What is claimed is:

1. A semiconductor system comprising:
a first high bandwidth memory (HBM) device comprising first, second, and third areas and comprising a first physical area disposed in the first area and a second physical area disposed in the third area;
a second HBM device comprising fourth, fifth, and sixth areas and comprising a third physical area disposed in the fourth area and a fourth physical area disposed in the sixth area; and
a process circuit electrically connected to the first physical area,
wherein the second physical area of the first HBM device and the third physical area of the second HBM device are electrically connected, the fourth physical area is deactivated, a first predetermined area is formed vertically to the first area, a third predetermined area is formed vertically to the third area, and a fourth predetermined area is formed vertically to the fourth area.

2. The semiconductor system of claim 1, wherein a dummy die group comprising a plurality of dummy dies is vertically stacked is disposed, respectively, in the first predetermined area, a second predetermined area, and the third predetermined area.

3. The semiconductor system of claim 1, wherein one dummy die is disposed, respectively, in the first predetermined area, a second predetermined area, and the third predetermined area.

4. The semiconductor system of claim 1, wherein the first predetermined area, a second predetermined area, and the third predetermined area are respectively set as an empty space.

5. The semiconductor system of claim 1, wherein:
the first physical area inputs and outputs first and second data through a first group of physical layers,
the second physical area inputs and outputs the second data through second and third groups of physical layers that are selectively activated, and
the third physical area inputs and outputs the second data through fourth and fifth groups of physical layers that are selectively activated.

6. The semiconductor system of claim 1, wherein:
the first area further comprises a first internal interface area,
the second area inputs and outputs first data to and from a first memory device through a second internal input and output line that is electrically connected to the first internal interface area, and
the second area inputs and outputs second data through the second internal input and output line that is electrically connected to the first internal interface area.

7. The semiconductor system of claim 1, wherein:
the third area further comprises a second internal interface area, and
the third area inputs and outputs second data through a second internal input and output line that is electrically connected to the second internal interface area.

8. The semiconductor system of claim 1, wherein the first HBM device comprises:
a first control device configured to input and output first data through a first internal input and output line that is electrically connected to a first internal interface area included in the first area and configured to input and output second data through a second internal input and output line that is electrically connected between the first internal interface area and a third internal interface area included in the third area; and
a first memory device stacked on an upper part of the second area and configured to input and output the first data.

9. The semiconductor system of claim 8, wherein:
the first internal interface area and the first and second internal input and output lines are connected substantially orthogonal to one another, and
a second internal interface area and the first and second internal input and output lines are connected substantially orthogonal to one another.

10. The semiconductor system of claim 1, wherein the second HBM device comprises:
a second control device configured to generate third data from second data in a third internal interface area included in the fourth area, configured to input and output the third data through a third internal input and output line that is electrically connected to the third internal interface area, and configured to generate the second data from the third data in the third internal interface area and to output the second data to the third area; and
a second memory device stacked on an upper part of the fifth area and configured to input and output the third data.

11. The semiconductor system of claim 10, wherein the third internal interface area and the third internal input and output line are connected substantially orthogonal to one another.

12. A semiconductor system comprising:
a first high bandwidth memory (HBM) device comprising first, second, and third areas are formed and comprising a first physical area comprising a first group of physical layers and a second group of physical layers and a second physical area comprising a third group of physical layers and a fourth group of physical layers;
a second HBM device comprising fourth, fifth, and sixth areas are formed and comprising a third physical area comprising a fifth group of physical layers and a sixth group of physical layers and a fourth physical area comprising a seventh group of physical layers and an eighth group of physical layers; and
a process circuit electrically connected to the first physical area,
wherein the first to eighth groups of physical layers are selectively activated, a first predetermined area is formed vertically to the first area, a third predetermined area is formed vertically to the third area, a fourth predetermined area is formed vertically to the fourth area, and a sixth predetermined area is formed vertically to the sixth area.

13. The semiconductor system of claim 12, wherein:
the first physical area is disposed in the first area,
the second physical area is disposed in the third area,
the third physical area is disposed in the fourth area, and
the fourth physical area is disposed in the sixth area.

14. The semiconductor system of claim 12, wherein a dummy die group comprising a plurality of dummy dies is vertically stacked is disposed, respectively, in the first predetermined area, a second predetermined area, the third predetermined area, and the sixth predetermined area.

15. The semiconductor system of claim 12, wherein one dummy die is disposed, respectively, in the first predetermined area, a second predetermined area, the third predetermined area, and the sixth predetermined area.

16. The semiconductor system of claim 12, wherein the first predetermined area, a second predetermined area, the third predetermined area, and the sixth predetermined area are respectively set as an empty space.

17. The semiconductor system of claim 12, wherein the first HBM device comprises:
a first control device configured to input and output first data through a first internal input and output line that is electrically connected to a first internal interface area included in the first area and configured to input and output second data through a second internal input and output line that is electrically connected between the first internal interface area and a third internal interface area included in the third area; and
a first memory device stacked on an upper part of the second area and configured to input and output the first data.

18. The semiconductor system of claim 12, wherein the second HBM device comprises:
a second control device configured to generate third data and fourth data from first data and second data in a third internal interface area included in the fourth area, configured to input and output the third data through a third internal input and output line that is electrically connected to the third internal interface area, configured to input and output the fourth data through a fourth internal input and output line that is electrically connected between the third internal interface area and a fourth internal interface area included in the sixth area, and configured to generate the first data and the second data from the third data and the fourth data in the third internal interface area and to output the first data and the second data to the third area; and
a second memory device stacked on an upper part of the fifth area and configured to input and output the third data.

19. The semiconductor system of claim 12, wherein when the seventh group of physical layers and the eighth group of physical layers included in the sixth area are activated, the second HBM device electrically connected to a third HBM device and inputs and outputs a third data and a fourth data.

20. The semiconductor system of claim 12, wherein when the seventh group of physical layers and the eighth group of physical layers included in the sixth area are deactivated, a connection of the second HBM device to a third HBM device is disconnected.
